(19) United States
(12) Patent Application Publication
(10) Pub. No.: US 2012/0214100 A1
(43) Pub. Date: Aug. 23, 2012

(54) RESIST COMPOSITION AND PATTERNING PROCESS USING THE SAME

(75) Inventors: Tomohiro Kobayashi, Jyoetsu (JP); Youichi Ohsawa, Jyoetsu (JP); Yuji Harada, Jyoetsu (JP); Yuki Suka, Jyoetsu (JP)

(73) Assignee: SHIN-ETSU CHEMICAL CO., LTD., Tokyo (JP)

(21) Appl. No.: 13/396,081

(22) Filed: Feb. 14, 2012

(30) Foreign Application Priority Data
Feb. 21, 2011 (JP) 2011-034748

(51) Int. Cl. G03F 7/20; G03F 7/027

(52) U.S. Cl. 430/285.1; 430/325

(57) ABSTRACT

There is disclosed a resist composition, wherein the composition is used in a lithography and comprises at least: a polymer (A) that becomes a base resin whose alkaline-solubility changes by an acid, a photo acid generator (B) generating a sulfonic acid represented by the following general formula (1) by responding to a high energy beam, and a polymer additive (C) represented by the following general formula (2). There can be provided a resist composition showing not only excellent lithography properties but also a high receding contact angle, and in addition, being capable of suppressing a blob defect in both the immersion exposures using and not using a top coat; and a patterning process using the same.

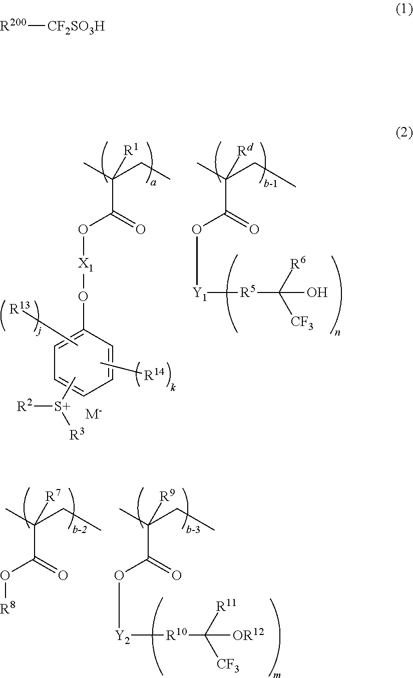

### BACKGROUND OF THE INVENTION

1. Field of the Invention

The present invention relates to a resist composition used for microfabrication in manufacturing process of a semiconductor device and so on, for example, for a lithography using an ArF excimer laser of a 193 nm wavelength as a light source, especially for an immersion photolithography in which water is inserted between a projection lens and a wafer, and to a resist patterning process using the same.

2. Description of the Related Art

Conventionally, optical exposure has been widely used using g-line (436 nm) or i-line (365 nm) of a mercury-vapor lamp as a light source for lithography when a resist pattern is formed. As a mean for further miniaturization, shifting to a shorter wavelength of an exposing light was assumed to be effective. As a result, in a mass production process after DRAM (Dynamic Random Access Memory) with 64-megabits (0.25 μm or less of a processing dimension) in 1990s, a KrF excimer laser (248 nm), a shorter wavelength than an i-line (365 nm), was used in place of an i-line as an exposure light source.

However, in production of DRAM with an integration of 256 M, 1 G and higher which require further miniaturized process technologies (process dimension of 0.2 μm or less), a light source with a further short wavelength is required, and thus a photo lithography using an ArF excimer laser (193 nm) has been investigated seriously since about a decade ago.

At first, an ArF lithography was planned to be applied to a device starting from a 180-nm node device, but a KrF excimer laser lithography lived long to a mass production of a 130-nm node device, and thus a full-fledged application of an ArF lithography will start from a 90-nm node. Further, a study of a 65-nm node device by combining with a lens having an increased NA till 0.9 is now underway.

Further shortening of wavelength of an exposure light is progressing towards the next 45-nm node device, and for that an F₂ lithography with a 157-nm wavelength became a candidate. However, there are many problems in an F₂ lithography; an increase in cost of a scanner due to the use of a large quantity of expensive CaF₂ single crystals for a projector lens, extremely poor sustainability of a soft pellicle, which leads to a change of an optical system due to introduction of a hard pellicle, a decrease in an etching resistance of a resist film, and the like. Because of these problems, it was proposed to postpone an F₂ lithography and to introduce an ArF immersion lithography earlier (Proc. SPIE Vol. 4690, xxix).

In an ArF immersion lithography, a proposal was made to impregnate water between a projection lens and a wafer; and this technology has been put into a practical use. Because refraction index of water at 193 nm is 1.44, patterning can be done even with a lens having NA of 1.0 or higher, wherein theoretically NA can be increased to 1.35. Resolution is improved in proportion to increase of NA; and thus, it is suggested that a 45-nm node may be possible by combination of 1.2 or higher of NA with a strong, super resolution technology (refer to Proc. SPIE, Vol. 5040, p. 724).

However, in an immersion lithography, many problems caused by presence of water on a resist film have been pointed out. Namely, such problems as pattern deformation, due to elution (leaching out) of a photo acid generator in a resist composition, an acid generated by photo-irradiation, and an amine compound added to a resist film as a quencher, into the water that is contacted with these substances, and pattern fall due to swelling of a photoresist film by water have been mentioned.

Especially as to the problem of leaching out of a resist composition into water, a study on it was initiated originally from a view point of avoiding fouling to a projection lens of an exposure instrument, and then, a standard as to a leaching amount thereof has been proposed from a plurality of exposure instrument manufacturers.

In any of ArF immersion exposure instruments currently prevailing in a market, entirety of a substrate coated with a resist film is not immersed in water, but a system in which water is kept partly between a projection lens and wafer and exposure is done with scanning a stage having a wafer put thereon at the rate of 300 to 550 mm per second is employed. Because of such a high speed scanning, water cannot be kept between a projection lens and a wafer, thereby causing a problem of a remaining liquid droplet on a photoresist surface after scanning. It is assumed that this remaining liquid droplet causes poor patterning.

To solve this problem, suggestion was made that arranging a top coat, formed of a perfluoroalkyl compound, between a resist film and water might be effective (refer to “2^{nd} Immersion Work Shop, Jul. 11, 2003, Resist and Cover Material Investigation for Immersion Lithography”).

By forming these top coats, direct contact of a photoresist film with water can be avoided so that leaching out of a photoresist composition into water may be suppressed.

To solve the problem of a remaining liquid droplet by improving water-keeping capacity during the time of high speed scanning, increase of hydrophobicity on a coated film is effective; and it is known that use of the afore-mentioned top coat is also effective in this problem due to hydrophobicity of a perfluoroalkyl compound.

A specific physical parameter relating to the water-keeping capacity is a dynamic contact angle; and it is shown that a high receding contact angle at the time when a water droplet is moved on a coated film is especially effective (refer to “Defectivity data taken with a full-field immersion exposure tool”, Nakano et al., 2^{nd} International Symposium on Immersion Lithography, 12-15/September, 2005). Measurement of the receding contact angle can be made with a sliding down method in which a substrate is tilted and an aspiration method in which water is aspirated, while the sliding down method is generally used.

In addition, a top coat soluble in an alkaline developer has been proposed (refer to Japanese Patent Laid-Open Publication No. 2005-264131); this can be simultaneously removed by dissolution in a step of development of a photoresist film, thereby not requiring an additional step to remove the top coat and a removing unit dedicated exclusively to it, and thus, it can be said that this is a breakthrough technology.

Further in addition, a proposal has been made regarding a method wherein a compound having a partial structure that is alkaline-soluble and hydrophobic, such as a fluorinated alcohol, is added to a resist composition (refer to Japanese Patent Laid-Open Publication No. 2006-48029); in this method, the added hydrophobic compound is eccentrically located on a resist surface during formation of a resist film so that a similar effect to the case of using the resist top coat composition can be expected, and thus, this method is advantageous in terms of cost because steps associated with forming and removal of the top coat are not necessary.

However, there appeared a new problem by use of the top coat and the additive that are hydrophobic as mentioned above; namely, a defect caused by a residue remained on a resist film after development, called a blob, is drawing an attention. This is assumed to be caused by reattachment of a top coat composition or a resist composition separated out during rinsing after development onto the resist film; and this occurs eminently if hydrophobicity of surface of the resist film after development is high. In an immersion exposure using a top coat, a highly hydrophobic top coat is remained on surface of the resist film even after development because of mixed dissolution of the top coat with the resist film (this is called “mixing”) thereby causing the blob defect on the resist film. In the case of an immersion exposure not using the top coat by using a hydrophobic additive, the blob defect appears when the additive is not sufficiently removed by dissolution during development.

On the other hand, although resolution has been improved significantly by an immersion exposure, an effect of contrast deterioration due to acid diffusion becomes further serious in a resist composition as miniaturization progresses further. This is caused by approaching of a pattern size to an acid diffusion length whereby lowering of mask fidelity and deterioration of pattern rectangularity are invited. Accordingly, to fully enjoy the fruits owing to a shift to a shorter wavelength of a light source and to a higher NA, increase of a dissolution contrast or suppression of an acid diffusion is necessary ever than before in the material.

To utilize surface modification by the additive as mentioned above also for improvement of resolution, an attempt has been made to add, in addition to a base resin, a small amount of a polymer having concurrently a fluorine atom and a specific functional group. For example, in Japanese Patent Laid-Open Publication. No. 2009-031767, a polymer additive having a fluorine atom and an amino group is proposed. In this proposal, it is described that concentration of the amino group on the surface layer is so high that an excess acid on the surface layer is effectively neutralized thereby leading to improvement of pattern rectangularity. However, there is a risk that pattern fall of a narrow line may become eminent, because, due to hydrophilicity of the amino group, water is penetrated inside the pattern during rinsing after development thereby leading to water-swelling. In this proposal, also mentioned is an effect of avoiding mixing with the top coat so as to solve the problem of the blob defect; however, in this case, it is difficult to increase the receding contact angle because the surface is made hydrophilic by introduction of the amino group, and thus, there is a risk of a remaining liquid droplet in an immersion exposure not using the top coat.

As to the approach to improve the resist resolution performance by introduction of an acid-quenching mechanism, a proposal is made to use a salt-exchange reaction of a salt of a weak acid with a strong acid, other than the method to utilize a neutralization reaction by a basic nitrogen-containing compound typically represented by the afore-mentioned amines; and for example, in Japanese Patent No. 3912767, a resist composition concurrently using a compound that generates an alkanesulfonic acid substituted with a fluorine atom at its α-position and an onium salt of an unfluorinated alkanesulfonic acid, thereby giving a small sparse-dense dependency of a line-and-space, has been proposed. Although a detail of this effect is not described, it is supposed that this is based on a phenomenon that a strong acid (fluorine-containing sulfonic acid) generated by photo-exposure reacts with a salt of a weak acid (onium salt of the unfluorinated alkanesulfonic acid) thereby exchanging to a weak acid (unfluorinated alkanesulfonic acid) and a salt of a strong acid (onium salt of the fluorine-containing sulfonic acid). The weak acid generated by the salt-exchanging reaction has an extremely weak reactivity in a deprotection reaction and a crosslinking reaction of a base resin; and thus, the salt of a weak acid can practically function as an acid-quencher. In particular, in the case that the salt of a weak acid is photo-decomposable, the quenching capacity thereof is lost in the exposed area so that increase of dissolution contrast may be expected.

On the other hand, a quencher of the salt of a weak acid mentioned above has a problem of poor pattern rectangularity because the quenching capacity thereof is lost on the resist surface layer, which receives a large amount of light (there are risks of causing a tapered shape in a positive-type resist and a negative profile in a negative-type resist).

### SUMMARY OF THE INVENTION

The present invention was made in view of the problems mentioned above, and has an object to provide; a resist composition showing not only excellent lithography properties, specifically, showing improved pattern rectangularity, LWR (Line Width Roughness), and fall resistance, but also a high receding contact angle, and in addition, being capable of suppressing a blob defect in both the immersion exposures using and not using a top coat; and a patterning process using the same.

In order to solve the foregoing problems, the present invention provides a resist composition, wherein the composition is used in a lithography and comprises at least:

a polymer (A) that becomes a base resin whose alkaline-solubility changes by an acid,

a photo acid generator (B) generating a sulfonic acid represented by the following general formula (1) by responding to a high energy beam, and

a polymer additive (C) represented by the following general formula (2);

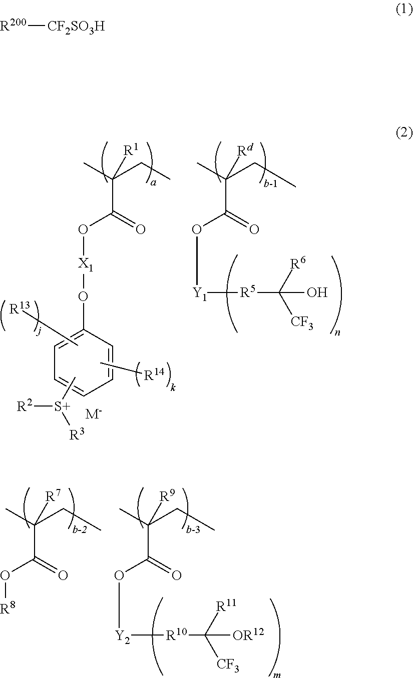

wherein R²⁰⁰ represents a halogen atom; or a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group;

wherein, each of R¹, R⁴, R⁷, and R⁹ independently represents a hydrogen atom or a methyl group. X₁ represents a linear or a branched alkylene group having 1 to 10 carbon atoms. Each of R² and R³ independently represents any of linear, branched, and cyclic substituted or unsubstituted alkyl, alkenyl, and oxoalkyl groups having 1 to 10 carbon atoms and optionally containing a heteroatom; or any of substituted or unsubstituted aryl, aralkyl, and aryl oxoalkyl groups having 6 to 20 carbon atoms; or R² and R³ may be bonded to form a ring together with a sulfur atom in the formula. R⁵ and R¹⁰ represent a linear, a branched, or a cyclic alkylene group having 1 to 20 carbon atoms, wherein one or plurality of the hydrogen atoms in these groups may be substituted with a fluorine atom. R⁶ represents any of a hydrogen atom, a fluorine atom, a methyl group, a trifluoromethyl group, and a difluoromethyl group; or R⁵ and R⁶ may form an aliphatic ring having 5 to 12 carbon atoms together with the carbon atom to which these groups are bonded, wherein these rings may contain an ether bond, a fluorine-substituted alkylene group, or a trifluoromethyl group. Similarly, R¹¹ represents any of a hydrogen atom, a fluorine atom, a methyl group, a trifluoromethyl group, and a difluoromethyl group; or R¹⁰ and R¹¹ may form an aliphatic ring having 5 to 12 carbon atoms together with the carbon atom to which these groups are bonded, wherein these rings may contain an ether bond, a fluorine-substituted alkylene group, or a trifluoromethyl group. Each of n and m independently represents 1 or 2. In the case of n=1 and m=1, each of Y₁ and Y₂ independently represents a single bond, or a linear, a branched, or a cyclic alkylene group having 1 to 10 carbon atoms and optionally containing a carbonyl group, an ether bond, and an ester bond; and in the case of n=2 and m=2, Y₁ and Y₂ represent a trivalent connecting group having a form that one hydrogen atom is removed from the alkylene group shown by Y₁ and Y₂ of the case of n=1 and m=1 mentioned above. R⁸ represents a linear, a branched, or a cyclic alkyl group, having 1 to 20 carbon atoms, substituted by at least one fluorine atom, and optionally containing an ether bond, an ester bond, or a sulfonamide group. R¹² represents an acid-labile group. Each of R¹³ and R¹⁴ independently represents a linear or a branched alkyl group having 1 to 5 carbon atoms and optionally containing a heteroatom. Each of j and k independently represents 0 or 1. M⁻ represents any of an alkane sulfonate ion represented by the following general formula (3), an arene sulfonate ion represented by the following general formula (4), and a carboxylate ion represented by the following general formula (5). Numbers “a”, (b-1), (b-2), and (b-3) satisfy 0<a<1.0, 0≦(b-1)<1.0, 0≦(b-2)<1.0, 0≦(b-3)<1.0, 0<(b-1)+(b-2)+(b-3)<1.0, and 0.5≦a+(b-1)+(b-2)+(b-3)≦1.0;

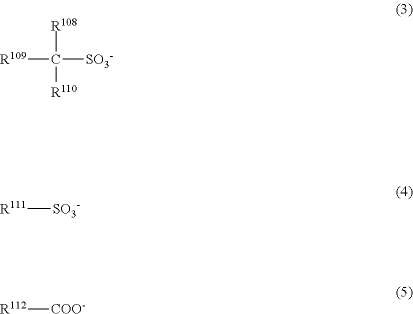

wherein, each of R¹⁰⁸, R¹⁰⁹, and R¹¹⁰ independently represents a hydrogen atom or a halogen atom excluding a fluorine atom; or any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group. Further, two or more of R¹⁰⁸, R¹⁰⁹, and R¹¹⁰ may be bonded with each other to form a ring;

wherein, R¹¹¹ represents an aryl group having 1 to 20 carbon atoms. One or plurality of the hydrogen atoms of the aryl group may be substituted with a halogen atom, a hydroxyl group, a carboxyl group, an amino group, or a cyano group, and further with a linear, a branched, or a cyclic alkyl group having 1 to 20 carbon atoms; and

wherein, R¹¹² represents any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group.

By using the resist composition as mentioned above, it is possible to improve lithography properties, specifically not only to improve pattern rectangularity, LWR, and fall resistance, but also to show a high receding contact angle with which an immersion exposure not using a top coat may be possible, and in addition, to suppress a blob defect in both the immersion exposures using and not using a top coat.

In this case, it is preferable that the photo acid generator (B) generates a sulfonic acid represented by any of the following general formula (6), the following general formula (7), and the following general formula (8);

R²⁰¹—CF₂SO₃H (6)

Rf—CH(OCOR²⁰²)—CF₂SO₃H (7)

R²⁰³—OOC—CF₂SO₃H (8)

wherein R²⁰¹ represents a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group, excluding a perfluoroalkyl group;

Rf represents a hydrogen atom or a CF₃ group. R²⁰² represents a linear, a branched, or a cyclic substituted or unsubstituted alkyl group having 1 to 20 carbon atoms, or a substituted or an unsubstituted aryl group having 6 to 14 carbon atoms;

R²⁰³ represents a linear, a branched, or a cyclic substituted or unsubstituted alkyl group having 1 to 20 carbon atoms, or a substituted or an unsubstituted aryl group having 6 to 14 carbon atoms.

As mentioned above, from a viewpoint to lower an environmental burden, it is preferable that the photo acid generator (B) generates a sulfonic acid having a structure represented by any of the above general formula (6), the above general formula (7), and the above general formula (8); and from a viewpoint of a lithography performance, it is particularly preferable that the acid generator generate a sulfonic acid having a structure represented by the above general formula (7) or the above general formula (8).

In addition, the composition may be any of a positive-type resist composition and a negative-type resist composition.

In the case of a positive-type resist composition, it is preferable that the polymer (A) as the base resin contains a repeating unit having a structure containing an acid-labile group, and further, a repeating unit having a structure containing a lactone ring.

In the case of the positive-type resist composition as mentioned above, if the polymer (A) as the base resin contains a repeating unit having a structure containing an acid-labile group, the acid-labile group is released by an acid generated from the acid generator during the time of exposure thereby changing the exposed resist area so as to be dissolvable into a developer, so that a pattern of an extremely high precision can be obtained. In addition, if the polymer (A) as the base resin contains a repeating unit having a lactone ring as an adhesive group, a high adhesion with a substrate can be realized.

In addition, it is preferable that the composition further contains any one or more of an organic solvent, a basic compound, a crosslinking agent, and a surfactant.

If the organic solvent is further blended thereinto as mentioned above, for example, a coating property of the resist composition to a substrate and so on can be improved; if the basic compound is blended thereinto, an acid diffusion within a resist film can be suppressed thereby enabling to improve resolution further; and if the surfactant is blended thereinto, a coating property of the resist composition may be further improved or controlled.

Meanwhile, in the case of the negative-type resist composition, a crosslinking agent may also be blended thereinto; with this, a crosslinking reaction within a resist film by baking and so on after application to a substrate and so on can be facilitated so that a profile and the like of a resist pattern may be made better.

The present invention provides a patterning process, wherein the process is to form a pattern onto a substrate and includes at least a step of forming a resist film by applying the resist composition onto the substrate, a step of exposing to a high energy beam after heat treatment, and a step of developing by using a developer.

It is natural that development may be conducted after heat treatment following exposure, and other various processes, such as an etching process, a resist removing process, and a washing process, may be performed.

In this case, it is preferable that wavelength of the high energy beam is made in the range between 180 and 250 nm.

In the patterning process using the resist composition of the present invention, exposure by the high energy beam having wavelength in the range between 180 and 250 nm is the most suitable to obtain an intended fine pattern.

In addition, a step of exposing to the high energy beam mentioned above can be carried out by an immersion exposure intervened with a liquid, wherein the liquid is inserted between a projection lens and the substrate formed with the resist film. In this case, a top coat may be formed on the resist film; and in addition, water may be used as the liquid.

In the patterning process using the resist composition of the present invention, especially in the case of an immersion exposure using water, patterning can be done excellently and a blob defect can be prevented from occurring even when a top coat is formed in the immersion exposure as mentioned above.

As mentioned above, the present invention can provide a resist composition having excellent lithography properties, specifically, not only excellent pattern rectangularity, LWR, and fall resistance, but also a high receding contact angle with which an immersion exposure not using a top coat is possible, and in addition, a less blob defect in both the immersion exposures using and not using a top coat.

### DESCRIPTION OF THE PREFERRED EMBODIMENTS

Hereinafter, the preferred embodiments of the present invention will be explained, but the present invention is not limited to them.

As mentioned above, in a conventional resist composition, there has been a problem of damaging pattern rectangularity, occurring poor patterns such as, a pattern form change and a pattern fall, a residual defect called a blob defect, and the like.

Inventors of the present invention carried out an extensive investigation to solve the problems mentioned above; and as a result, the inventors found that a resist composition, containing, in addition to a polymer (A) that becomes a base resin whose alkaline-solubility changes by an acid, a photo acid generator (B) generating a sulfonic acid having a specific structure, and a polymer having a specific structure (polymer additive) (C), showed (1) excellent lithography properties, specifically, excellent pattern rectangularity, LWR, and fall resistance, and at the same time, (2) a high receding contact angle with which an immersion exposure not using a top coat is possible, and further, (3) a suppressed blob defect in both the immersion exposures using and not using a top coat, and thereby completing the present invention.

The resist composition of the present invention is a resist composition, wherein the composition is used in a lithography and comprises at least:

a polymer (A) that becomes a base resin whose alkaline-solubility changes by an acid,

a photo acid generator (B) generating an alkane sulfonic acid, substituted with a fluorine atom at its α-position, represented by the following general formula (1) by responding to a high energy beam, and

a polymer additive (C), having fluoroalkyl group and sulfonium salt, represented by the following general formula (2); wherein an anion part of the sulfonium salt is a sulfonate ion or carboxylate ion represented by any of the following general formula (3), the following general formula (4), and the following general formula (5).

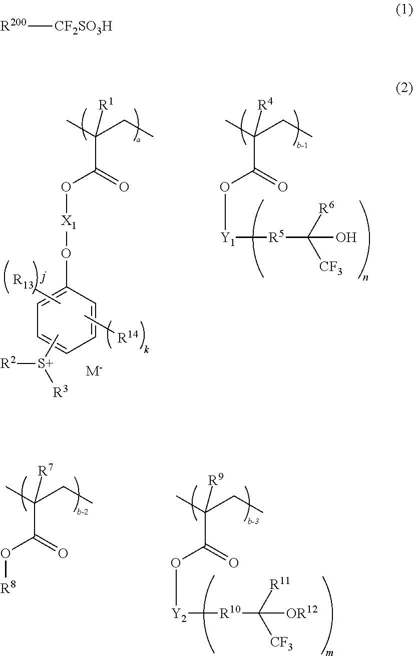

wherein R²⁰⁰ represents a halogen atom; or a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group;

wherein, each of R¹, R⁴, R⁷, and R⁹ independently represents a hydrogen atom or a methyl group. X₁ represents a linear or a branched alkylene group having 1 to 10 carbon atoms. Each of R² and R³ independently represents any of linear, branched, and cyclic substituted or unsubstituted alkyl, alkenyl, and oxoalkyl groups having 1 to 10 carbon atoms and optionally containing a heteroatom; or any of substituted or unsubstituted aryl, aralkyl, and aryl oxoalkyl groups having 6 to 20 carbon atoms; or R² and R³ may be bonded to form a ring together with a sulfur atom in the formula. R⁵ and R¹⁰ represent a linear, a branched, or a cyclic alkylene group having 1 to 20 carbon atoms, wherein one or plurality of the hydrogen atoms in these groups may be substituted with a fluorine atom. R⁶ represents any of a hydrogen atom, a fluorine atom, a methyl group, a trifluoromethyl group, and a difluoromethyl group; or R⁵ and R⁶ may form an aliphatic ring having 5 to 12 carbon atoms together with the carbon atom to which these groups are bonded, wherein these rings may contain an ether bond, a fluorine-substituted alkylene group, or a trifluoromethyl group. Similarly, R¹¹ represents any of a hydrogen atom, a fluorine atom, a methyl group, a trifluoromethyl group, and a difluoromethyl group; or R¹⁰ and R¹¹ may form an aliphatic ring having 5 to 12 carbon atoms together with the carbon atom to which these groups are bonded, wherein these rings may contain an ether bond, a fluorine-substituted alkylene group, or a trifluoromethyl group. Each of n and m independently represents 1 or 2. In the case of n=1 and m=1, each of Y₁ and Y₂ independently represents a single bond, or a linear, a branched, or a cyclic alkylene group having 1 to 10 carbon atoms and optionally containing a carbonyl group, an ether bond, and an ester bond; and in the case of n=2 and m=2, Y₁ and Y₂ represent a trivalent connecting group having a form that one hydrogen atom is removed from the alkylene group shown by Y₁ and Y₂ of the case of n=1 and m=1 mentioned above. R⁸ represents a linear, a branched, or a cyclic alkyl group, having 1 to 20 carbon atoms, substituted by at least one fluorine atom, and optionally containing an ether bond, an ester bond, or a sulfonamide group. R¹² represents an acid-lahile group. Each of R¹³ and R¹⁴ independently represents a linear or a branched alkyl group having 1 to 5 carbon atoms and optionally containing a heteroatom. Each of j and k independently represents 0 or 1. M⁻ represents any of an alkane sulfonate ion represented by the following general formula (3), an arene sulfonate ion represented by the following general formula (4), and a carboxylate ion represented by the following general formula (5). Numbers “a”, (b-1), (b-2), and (b-3) satisfy 0<a<1.0, 0≦(b-1)<1.0, 0≦(b-2)<1.0, 0≦(b-3)<1.0, 0<(b-1)+(b-2)+(b-3)<1.0, and 0.5≦a+(b-1)+(b-2)+(b-3)≦1.0.

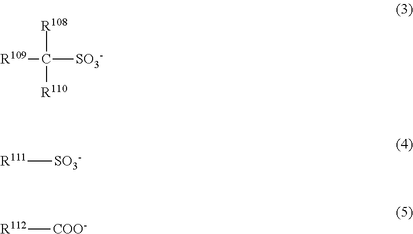

Wherein, each of R¹⁰⁸, R¹⁰⁹, and R¹¹⁰ independently represents a hydrogen atom or a halogen atom excluding a fluorine atom; or any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group. Further, two or more of R¹⁰⁸, R¹⁰⁹, and R¹¹⁰ may be bonded with each other to form a ring;

wherein, R¹¹¹ represents an aryl group having 1 to 20 carbon atoms. One or plurality of the hydrogen atoms of the aryl group may be substituted with a halogen atom, a hydroxyl group, a carboxyl group, an amino group, or a cyano group, and further with a linear, a branched, or a cyclic alkyl group having 1 to 20 carbon atoms; and wherein, R¹¹² represents any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group.

The sulfonium salt contained in the polymer additive (C) quenches a strong acid generated from the photo acid generator (B) by a salt-exchange reaction; and it is assumed that, because the polymer additive (C) tends to be distributed relatively more in surface layer of the resist film than the polymer (A) that becomes the base resin, an excessive acid especially in the surface layer can be effectively quenched thereby improving pattern rectangularity. In addition, it is assumed that, because the polymer additive (C) loses an acid-quenching capacity in an exposed area, a dissolution rate contrast, which is dependent on an exposure dose amount, is improved so that lithography properties of a fine pattern, specifically critical resolution and LWR, may be improved.

Attempts to introduce a sulfonium salt, as the photo acid generator, into a polymer main chain have been made for a long time (for example, refer to Japanese Patent Laid-Open Publication No. H04-230645, Japanese Patent Laid-Open Publication No. 2006-171656, and U.S. Pat. No. 5,130,392 and so on); the object of the attempts resides in that an acid generated therefrom acts as a strongly acidic catalyst in an acidic decomposition reaction of an acid-labile group in a positive-type resist polymer, or in a reaction between a negative-type resist polymer with an acidic crosslinking agent. On the other hand, the object of using a photo acid-generating group to generate a weak acid (such as a carboxylic acid, an arene sulfonic acid, and an alkane sulfonic acid whose a-position is not fluorinated) contained in the polymer additive (C) of the present invention is to realize a function as a quencher to capture a strong acid (fluorine-containing sulfonic acid) generated from the photo acid generator (B).

In the case that a top coat is coated on a photoresist upper layer in a step of an immersion lithography, in order to satisfy both an alkaline-solubility and a water-repellent property, a polymer containing an a-trifluoromethyl hydroxyl group, as a base, dissolved in a solvent not dissolving a resist film, selected from a higher alcohol having four or more carbon atoms, an ether, an alkane, a fluorine atom, and the like, is suitably used as the top coat composition. The polymer additive (C) of the present invention containing a fluoroalkyl group and a sulfonium salt has a low solubility in the afore-mentioned solvents used for the top coat thereby forming a barrier layer to prevent inter-mixing between the top coat and the resist film from occurring. It is assumed that, because of this, the hydrophobic top coat composition does not remain on surface layer of the resist film after development, and thus it was possible to prevent a blob defect from occurring.

It is assumed that, because of hydrophobicity of the fluoroalkyl group contained in the polymer additive (C) of the present invention, the resist composition of the present invention showed a high receding contact angle thereby applicable also to the immersion exposure not using the top coat, and at the same time, because the surface layer was dissolved during development by dissolution facilitation ability—into an alkaline developer—of a weak acid generated from a sulfonium salt contained in the polymer additive (C) of the present invention thereby removing the hydrophobic polymer additive (C), it was possible to prevent a blob defect from occurring in both the immersion exposures using and not using the top coat.

Hereinafter, each component of the present invention will be explained.

Firstly, the polymer (A) that becomes a base resin whose alkaline-solubility changes by an acid contained in the resist composition of the present invention will be explained in detail.

In the case of aiming to provide a positive-type resist, it is preferable that the polymer (A) has a property of increasing an alkaline-solubility by an acid and contains at least a repeating unit having a structure containing an acid-labile group, or more preferably contain further a repeating unit having a structure containing a lactone ring as an adhesive group.

When the positive-type resist composition as mentioned above is used, because the polymer (A) that becomes the base resin has a repeating unit containing an acid-labile group, the acid-labile group is released by an acid generated from the acid generator at the time of photo-exposure thereby changing the exposed resist area so as to be soluble into a developer; and as a result, a pattern of a high precision can be obtained. Because the polymer (A) that becomes the base resin has a repeating unit containing a lactone ring as an adhesive group, a high adhesion with a substrate can be realized.

In the case of aiming to provide a negative-type resist, it is preferable that the polymer (A) has a property of decreasing an alkaline-solubility by an acid and contains an alkaline-soluble repeating unit having at least a hydroxyl group and/or a carboxyl group.

A mechanism to decrease an alkaline-solubility is not particularly restricted; and thus, included are, for example, a mechanism wherein the alkaline-soluble repeating unit is protected by an acid generated from an acid generator at the time of photo-exposure thereby becoming insoluble into a developer, a mechanism wherein an intramolecular or an intermolecular crosslinking reaction by an acid-catalyzed dehydration condensation of the hydroxyl group and the carboxyl group mentioned above is utilized, and a mechanism wherein a crosslinking agent, in addition to an acid generator, is included as a component of the resist composition to effect an acid-catalyzed crosslinking reaction between the base resin and the crosslinking agent thereby decreasing an alkaline-solubility.

As to the polymer (A) that becomes the resist base resin, any polymer may be used provided that an alkaline-solubility thereof can be changed by an acid; and as an illustrative example of it, a (meth)acrylate resin having a structure represented by the following formula (R-1) having a polystyrene-equivalent weight-average molecular weight of 1,000 to 100,000, or preferably 3,000 to 30,000, as measured by GPC, can be mentioned, though not limited to them.

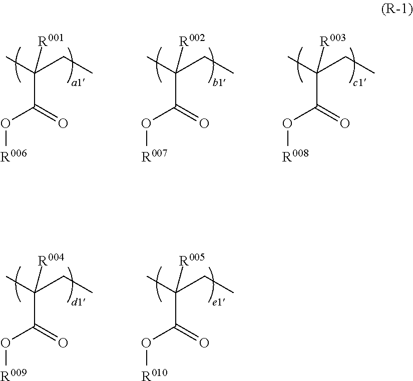

In the above formulae, each of R⁰⁰¹ to R⁰⁰⁵ independently represents a hydrogen atom or a methyl group.

R⁰⁰⁶ represents a hydrogen atom or a monovalent hydrocarbon group comprising at least one group selected from a fluorine-containing substituent having 1 to 15 carbon atoms, carboxyl group, hydroxyl group, and an oxygen atom. Specific examples thereof may include: a hydrogen atom, carboxyethyl, carboxybutyl, carboxycyclopentyl, carboxycyclohexyl, carboxynorbornyl, carboxyadamantyl, hydroxyethyl, hydroxybutyl, hydroxycyclopentyl, hydroxycyclohexyl, hydroxynorbornyl, hydroxyadamantyl, hydroxyhexafluoroisopropylcyclohexyl, di(hydroxyhexafluoroisopropyl)cyclohexyl.

R⁰⁰⁷ represents a monovalent hydrocarbon group containing a partial structure of lactone ring having 3 to 15 carbon atoms, and optionally containing an oxygen atom. Specific examples thereof include 2-oxooxolane-3-yl, 2-oxooxolane-4-yl, 4,4-dimethyl-2-oxooxolane.

R⁰⁰⁸ represents a linear, a branched, or a cyclic alkyl group having 1 to 20 carbon atoms and optionally containing an ester bond, an ether bond, or a carbonyl group. One or more of hydrogen atoms of these alkyl groups is substituted with a fluorine atom. Specific examples thereof include methyl group, ethyl group, propyl group, isopropyl group, n-butyl group, sec-butyl group, cyclopentyl group, cyclohexyl group, adamantyl group, methoxyethyl group, methoxycarbonylmethyl group, and the like.

R⁰⁰⁹ represents an aryl group having 6 to 20 carbon atoms and these alkyl groups in which one or more of hydrogen atoms may be substituted with a hydroxyl group, a carboxyl group, an alkyl group, an alkoxyl group, an alkoxyalkyl group, and a fluorine-containing substituent having 1 to 15 carbon atoms. Specific examples thereof include a phenyl group, a naphthyl group, a hydroxyphenyl group, a hydroxynaphthyl group, a carboxyphenyl group, a methoxyphenyl group, a tert-butylphenyl group, tert-butoxyphenyl group.

R⁰¹⁰ represents an acid-labile group, and details thereof are described later.

a1′, b1′, c1′, d1′, and e1′ represent a number of 0 or more and less than 1, and preferably satisfy a1′+b1′+c1′+d1′+e1′=1.

Many kinds of the acid-labile group of R⁰¹⁰ can be used; and specific example of it includes an alkoxyalkyl group represented by the following general formula (L1) and tertiary alkyl groups represented by the following general formulae (L2) to (L8), though not limited to them. The acid-labile groups having structures represented by (L2) to (L5) are particularly preferable.

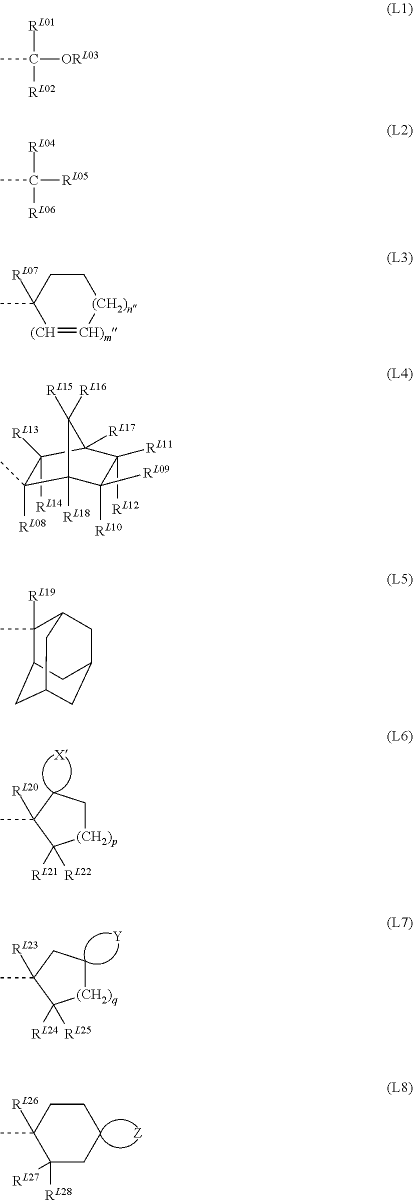

In the above formulae, the dotted lines show bonding arms. R^{L01} and R^{L02} represent a hydrogen atom, or a linear, a branched, or a cyclic alkyl group having 1 to 18, or preferably 1 to 10 carbon atoms; specific example of them includes a methyl group, an ethyl group, a propyl group, an isopropyl group, a n-butyl group, a sec-butyl group, a tert-butyl group, a cyclopentyl group, a cyclohexyl group, a 2-ethylhexyl group, a n-octyl group, and an adamantly group. R^{L03} represents a monovalent hydrocarbon group having 1 to 18 or preferably 1 to 10 carbon atoms and optionally containing a heteroatom such as an oxygen atom; wherein, a linear, a branched, or a cyclic alkyl group, or those having a part of hydrogen atoms thereof substituted with a hydroxyl group, an alkoxyl group, an oxo group, an amino group, an alkyl amino group, and the like can be mentioned, and specifically, the groups similar to the foregoing R^{L01} and R^{L02} as the liner, the branched, or the cyclic alkyl group, and the groups shown below and the like as the substituted alkyl groups can be mentioned.

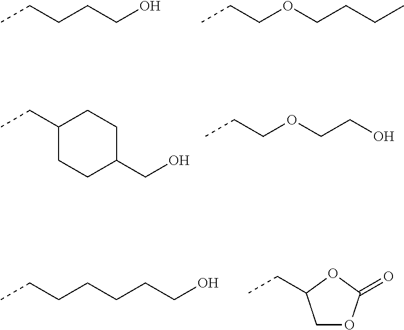

R^{L01} and R^{L02}, R^{L01} and R^{L03}, and R^{L02} and R^{L03} may be bonded with each other to form a ring together with the carbon atom or the oxygen atom to which these groups are bonded; and when the ring is formed, each of R^{L01}, R^{L02}, and R^{L03} represents a linear or a branched alkylene group having 1 to 18, or preferably 1 to 10 carbon atoms.

Each of R^{L04}, R^{L05}, and R^{L06} independently represents a linear, a branched, or a cyclic alkyl group having 1 to 15 carbon atoms. Specific examples thereof include methyl group, ethyl group, propyl group, isopropyl group, n-butyl group, sec-butyl group, tert-butyl group, cyclopentyl group, cyclohexyl group, 2-ethyl hexyl group, n-octyl group, 1-adamantyl group, 2-adamantyl group, and the like.

R^{L07} represents a linear, a branched, or a cyclic optionally-substituted alkyl group having 1 to 10 carbon atoms, or an optionally-substituted aryl group having 6 to 20 carbon atoms; and specific example of the optionally-substituted alkyl group includes a linear, a branched, or a cyclic alkyl group, such as a methyl group, an ethyl group, a propyl group, an isopropyl group, a n-butyl group, a sec-butyl group, a tert-butyl group, a tert-amyl group, a n-pentyl group, a n-hexyl group, a cyclopentyl group, a cyclohexyl group, and a bicyclo[2.2.1]heptyl group; those having a part of hydrogen atoms thereof substituted with a hydroxyl group, an alkoxyl group, a carboxyl group, an alkoxy carbonyl group, an oxo group, an amino group, an alkylamino group, a cyano group, a mercapto group, an alkylthio group, a sulfo group, and the like; or those having a part of a methylene group thereof substituted with an oxygen atom or a sulfur atom; and specific example of the optionally-substituted aryl group includes a phenyl group, a methylphenyl group, a naphthyl group, an anthryl group, a phenanthryl group, and a pyrenyl group. Here, m″ represents 0 or 1, n″ represents any of 0, 1, 2, and 3, and m″ and n″ satisfy 2m″+n′=2 or 3.

R^{L08} represents a linear, a branched, or a cyclic optionally-substituted alkyl group having 1 to 10 carbon atoms, or an optionally-substituted aryl group having 6 to 20 carbon atoms; specific example thereof includes groups similar to those of R^{L07}. Each of R^{L09} to R^{L18} independently represents a hydrogen atom or a monovalent hydrocarbon group having 1 to 15 carbon atoms; and specific examples thereof include a linear, a branched, or a cyclic alkyl group such as a methyl group, an ethyl group, a propyl group, an isopropyl group, a n-butyl group, a sec-butyl group, a tert-butyl group, a tert-amyl group, a n-pentyl group, a n-hexyl group, a n-octyl group, a n-nonyl group, a n-decyl group, a cyclopentyl group, a cyclohexyl group, a cyclopentylmethyl group, a cyclopentylethyl group, a cyclopentylbutyl group, a cyclohexylmethyl group, a cyclohexylethyl group, and a cyclohexylbutyl group; and those having a part of hydrogen atoms thereof substituted with a hydroxyl group, an alkoxyl group, a carboxyl group, an alkoxy carbonyl group, an oxo group, an amino group, an alkylamino group, a cyano group, a mercapto group, an alkylthio group, a sulfo group, and the like. R^{L09} to R^{L18} may be bonded with each other to form a ring (for example, between R^{L09} and R^{L10}, between R^{L09} and R^{L11}, between R^{L10} and R^{L12}, between R^{L11} and R^{L12}, between R^{L13} and R^{L14}, between R^{L15} and R^{L16}, and so on); and in this case, they represent a divalent hydrocarbon group having 1 to 15 carbon atoms, specifically the foregoing monovalent hydrocarbons from which one hydrogen atom is removed. R^{L09} to R^{L18} may be bonded between neighboring carbons to form a double bond with no intervention therebetween (for example, between R^{L09} and R^{L11}, between R^{L11} and R^{L17}, between R^{L15} and R^{L17}, and so on).

R^{L19} represents a linear, a branched, or a cyclic optionally-substituted alkyl group having 1 to 10 carbon atoms or an optionally-substituted aryl group having 6 to 20 carbon atoms; and specific example thereof includes groups similar to those of R^{L07}.

R^{L20} represents a linear, a branched, or a cyclic optionally-substituted alkyl group having 1 to 10 carbon atoms or an optionally-substituted aryl group having 6 to 20 carbon atoms; and specific example thereof includes groups similar to those of R^{L07}.

X′ represents a divalent group forming, together with the carbon atom to which X′ is bonded, a cyclopentane, a cyclohexane, or a norbornane ring, which may be substituted or unsubstituted. Each of R^{L21} and R^{L22} independently represents a hydrogen atom, or a linear, a branched, or a cyclic monovalent hydrocarbon group having 1 to 10 carbon atoms, or R^{L21} and R^{L22} may be bonded with each other to form, together with the carbon atom to which they are bonded, a cyclopentane or a cyclohexane ring, which may be substituted or unsubstituted. Here, p represents 1 or 2.

R^{L23} represents a linear, a branched, or a cyclic optionally-substituted alkyl group having 1 to 10 carbon atoms or an optionally-substituted aryl group having 6 to 20 carbon atoms; and specific example thereof includes groups similar to those of R^{L07}.

Y represents a divalent group forming, together with the carbon atom to which Y is bonded, a cyclopentane, a cyclohexane, or a norbornane ring, which may be substituted or unsubstituted. Each of R^{L24} and R^{L25} independently represents a hydrogen atom, or a linear, a branched, or a cyclic monovalent hydrocarbon group having 1 to 10 carbon atoms, or R^{L24} and R^{L25} may be bonded with each other and represent a divalent group forming, together with the carbon atom to which these groups are bonded, a cyclopentane or a cyclohexane ring, which may be substituted or unsubstituted. Here, q represents 1 or 2.

R^{L26} represents a linear, a branched, or a cyclic optionally-substituted alkyl group having 1 to 10 carbon atoms or an optionally-substituted aryl group having 6 to 20 carbon atoms; and specific example thereof includes groups similar to those of R^{L07}.

Z represents a divalent group forming, together with the carbon atom to which Z is bonded, a cyclopentane, a cyclohexane, or a norbornane ring, which may be substituted or unsubstituted. Each of R^{L27} and R^{L28} independently represents a hydrogen atom, or a linear, a branched, or a cyclic monovalent hydrocarbon group having 1 to 10 carbon atoms, or R^{L27} and R^{L28} may be bonded with each other to form, together with the carbon atom to which they are bonded, a cyclopentane or a cyclohexane ring, which may be substituted or unsubstituted.

Among the acid-labile group represented by the general formula (L1), specific examples of the linear or the branched one are shown below.

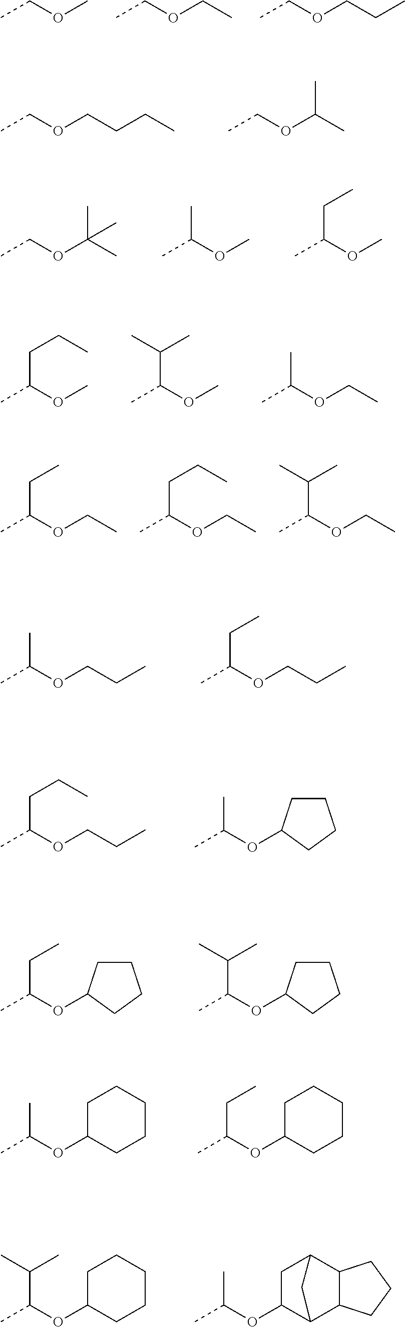

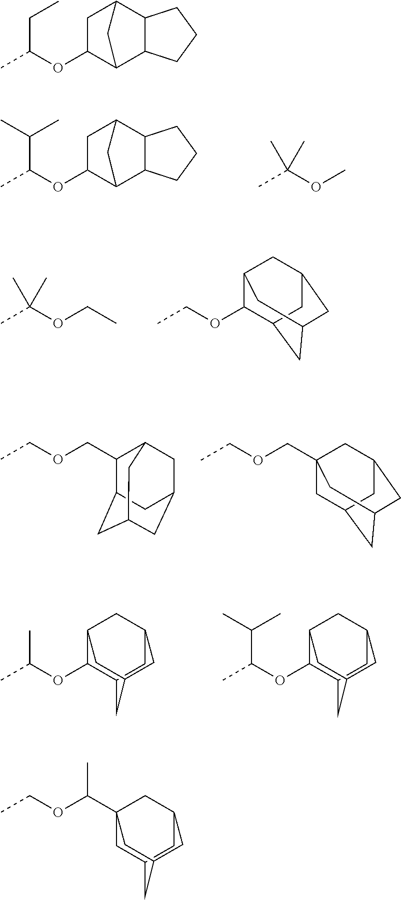

Among the acid-labile group represented by the general formula (L1), specific examples of the cyclic one include tetrahydrofuran-2-yl group, 2-methyltetrahydrofuran-2-yl group, tetrahydropyran-2-yl group, 2-methyltetrahydropyran-2-yl group, and the like.

Specific examples of the acid-labile group represented by the general formula (L2) include tert-butyl group, tert-amyl group, and the following groups.

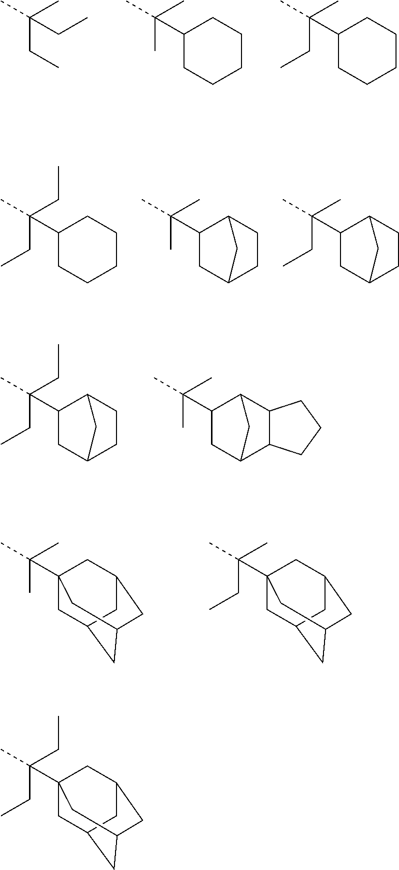

Specific examples of the acid-labile group represented by the general formula (L3) include 1-methyl cyclopentyl, 1-ethyl cyclopentyl, 1-n-propyl cyclopentyl, 1-isopropyl cyclopentyl, 1-n-butylcyclopentyl, 1-sec-butylcyclopentyl, 1-cyclohexyl cyclopentyl, 1-(4-methoxy-n-butyl)cyclopentyl, 1-(bicyclo[2.2.1]heptane-2-yl)cyclopentyl, 1-(7-oxabicyclo[2.2.1]heptane-2-yl)cyclopentyl, 1-methyl cyclohexyl, 1-ethyl cyclohexyl, 3-methyl-1-cyclopentene-3-yl, 3-ethyl-1-cyclopentene-3-yl, 3-methyl-1-cyclohexene-3-yl, 3-ethyl-1-cyclohexene-3-yl, and the like.

Most preferred examples of the acid labile group of the above-mentioned formula (L4) are groups represented by the following formulae (L4-1) to (L4-4).

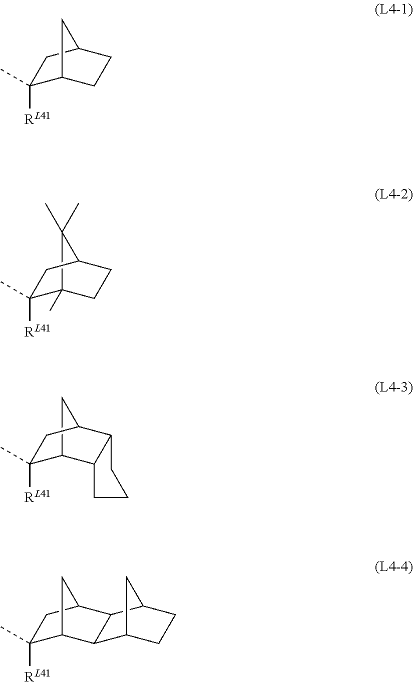

In the above general formulae (L4-1) to (L4-4), the dotted lines show bonding sites and bonding directions. Each R^{L41} independently represents a monovalent hydrocarbon group such as a linear, a branched, or a cyclic alkyl group having 1 to 10 carbon atoms; and specific example of it includes a methyl group, an ethyl group, a propyl group, an isopropyl group, a n-butyl group, a sec-butyl group, a Cert-butyl group, a tert-amyl group, a n-pentyl group, a n-hexyl group, a cyclopentyl group, a cyclohexyl group, and the like.

In the above general formulae (L4-1) to (L4-4), their enantiomers and diastereomers can exist, and the above general formulae (L4-1) to (L4-4) represent all of these stereoisomers. These stereoisomers may be used singly or as a mixture thereof; and when they are used as the mixture, these formulae represent the mixtures as well.

For example, the above general formula (L4-3) represents one kind or a mixture of two kinds selected from the group represented by the following general formulae (L4-3-1) and (L4-3-2);

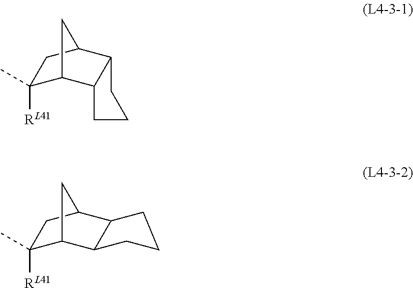

wherein, R^{L41} represents the same meaning as before.

For example, the above general formula (L4-4) represents one kind or a mixture of two or more kinds selected from the group represented by the following general formulae (L4-4-1) to (L4-4-4);

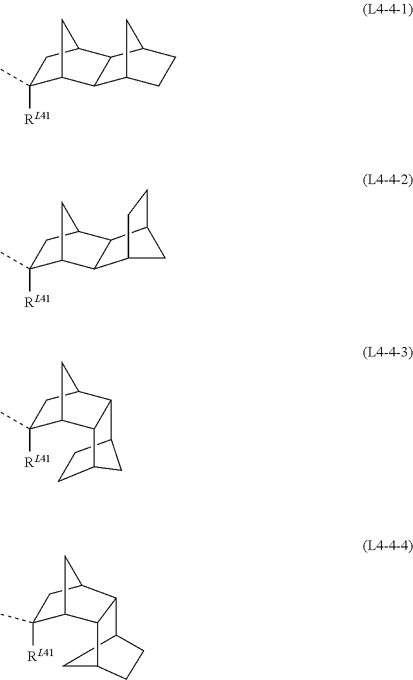

wherein, R^{L41} represents the same meaning as before.

Meanwhile, when each bonding direction of the above general formulae (L4-1) to (L4-4), (L4-3-1), (L4-3-2), and (L4-4-1) to (L4-4-4) is an exo-position to the respective bicyclo[2.2.1]heptane rings, a high reactivity can be realized in the acid-catalyzed elimination reaction (refer to Japanese Patent Laid-Open Publication No. 2000-336121). In preparation of a monomer containing a tertiary exo-alkyl group having these bicyclo[2.2.1]heptane skeletons as a substituent group, there is a case that a monomer substituted with an endo-alkyl group represented by the following general formulae (L4-1-endo) to (L4-4-endo) is included; in this case, the exo ratio is preferably 50% or more, or more preferably 80% or more, in order to realize a high reactivity;

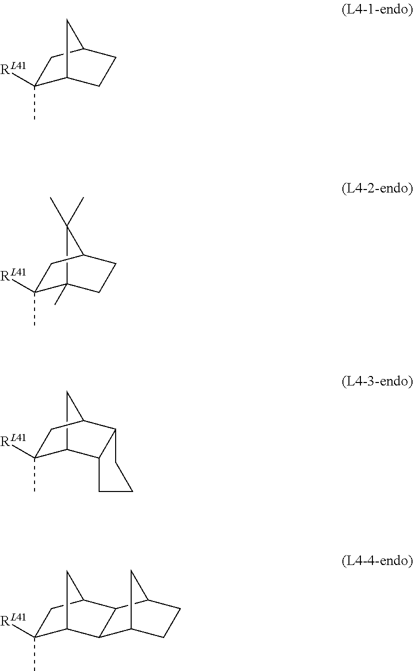

wherein, R^{L41} represents the same meaning as before.

Specific examples of the acid labile groups of the formula (L4) may include the following groups.

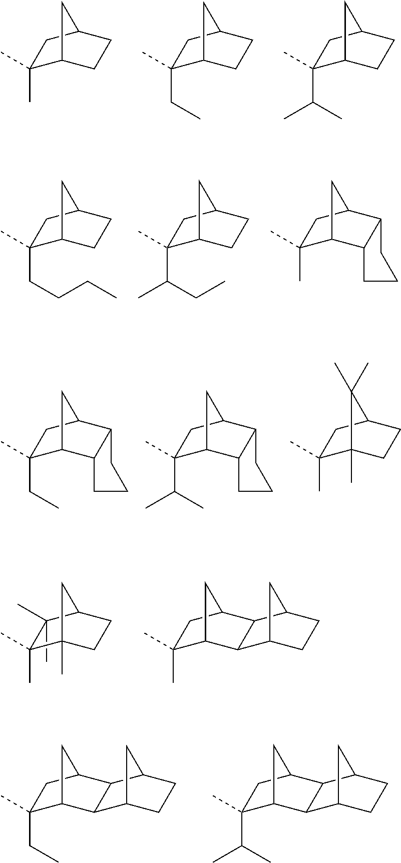

Specific examples of the acid-labile group represented by the general formula (L5) may include the following groups.

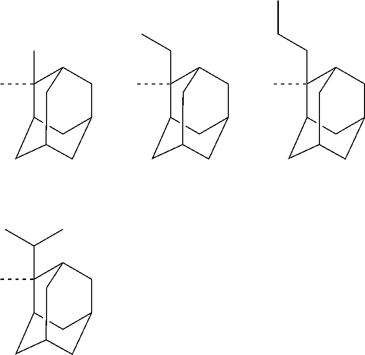

Specific examples of the acid-labile group represented by the general formula (L6) may include the following groups.

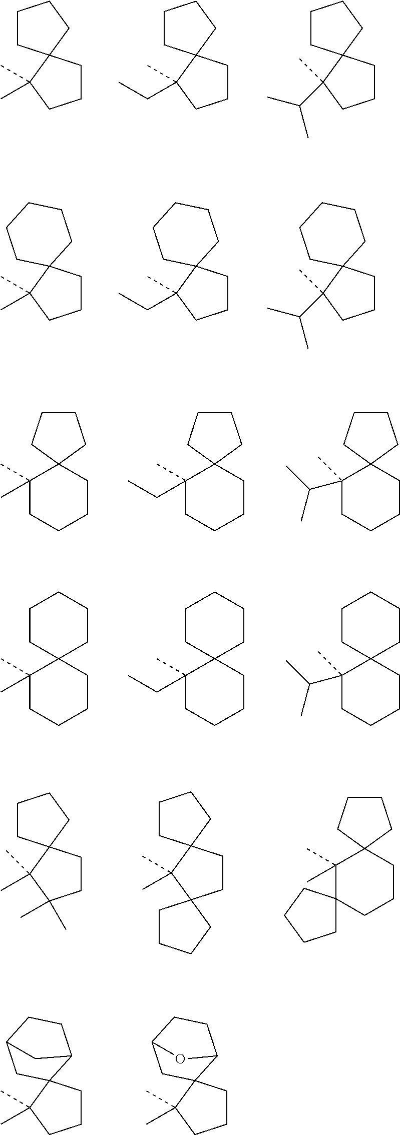

Specific examples of the acid-labile group represented by the general formula (L7) may include the following groups.

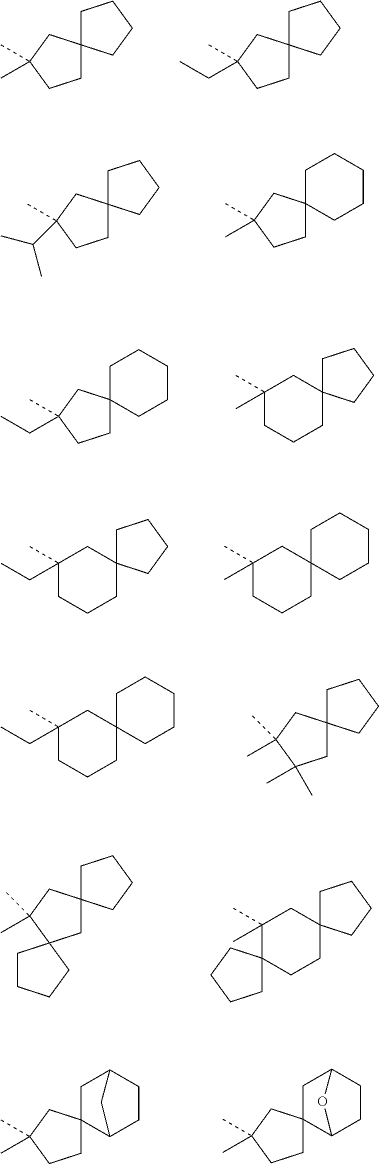

Specific examples of the acid-labile group represented by the general formula (L8) may include the following groups.

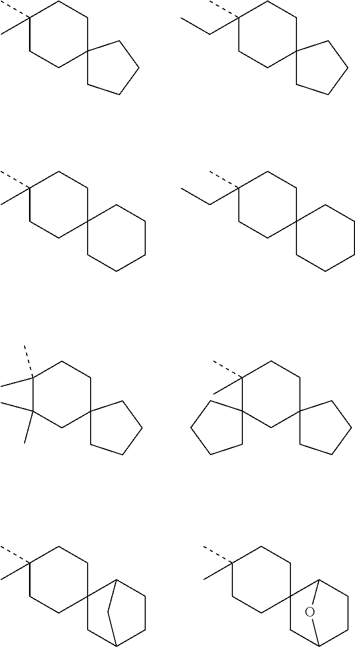

Meanwhile, in the negative-type resist composition, the base resin not containing the foregoing acid-labile group, namely the resin with e1′ being 0 in the case of the above formula (R-1), is preferably used, though not limited to it.

In the above formula (R-1), specific example of the repeating unit introduced with the composition ratio a1′ includes the following, though not limited to them.

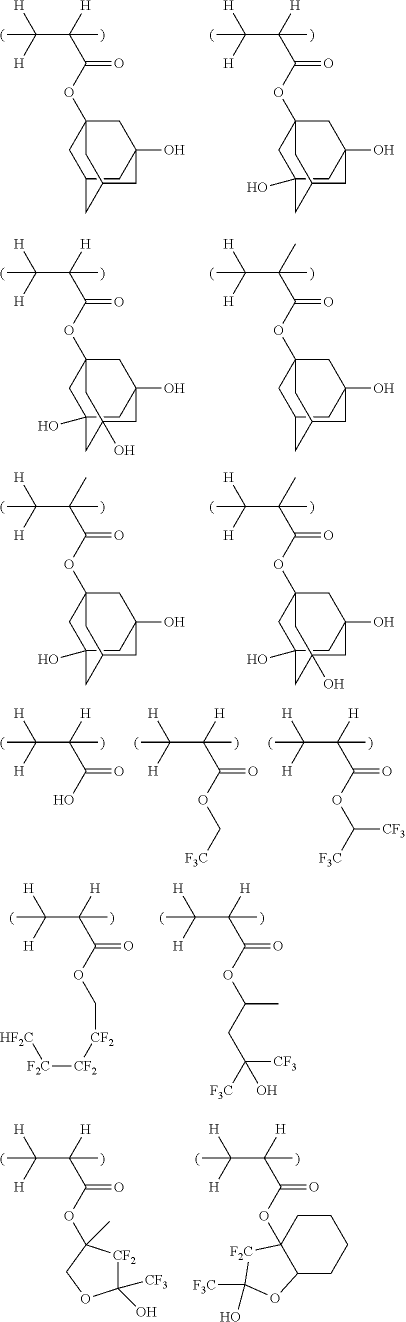

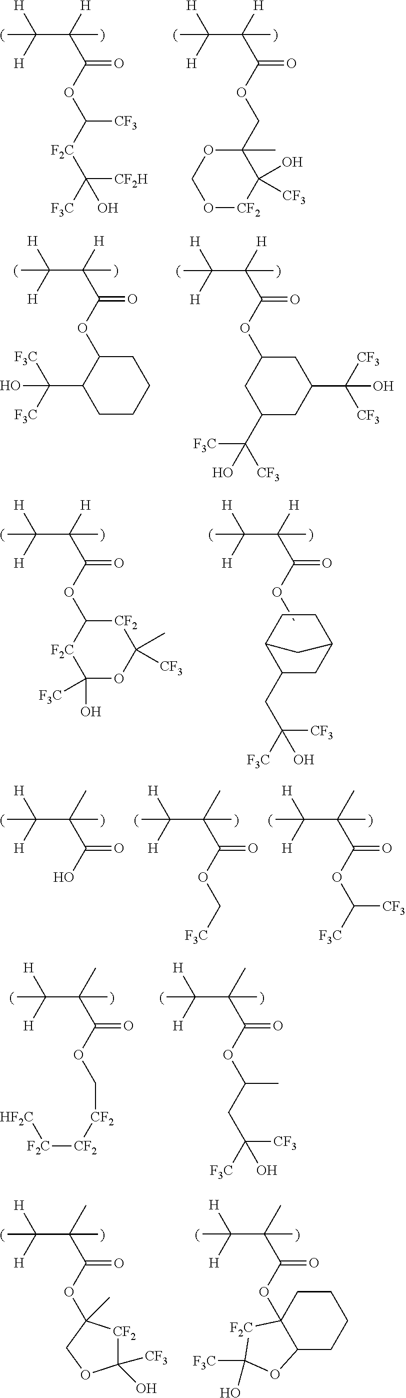

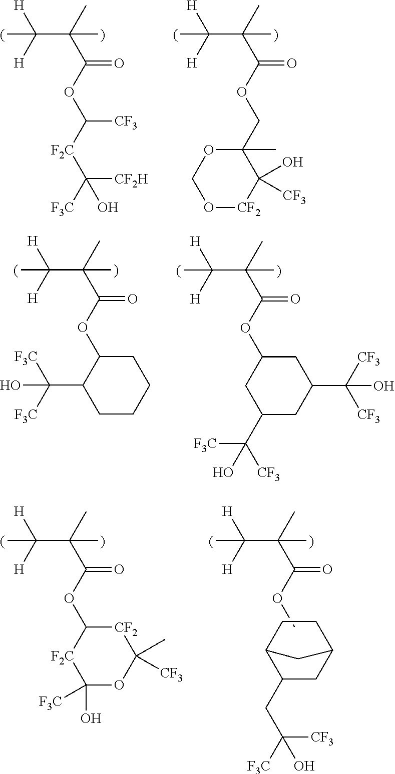

In the above formula (R-1), specific example of the repeating unit introduced with the composition ratio b1′ includes the followings, though not limited to them.

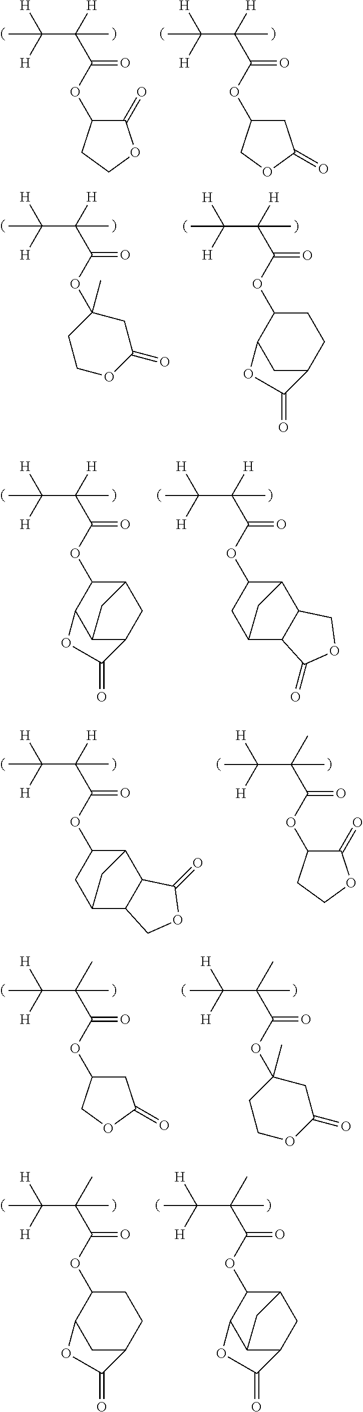

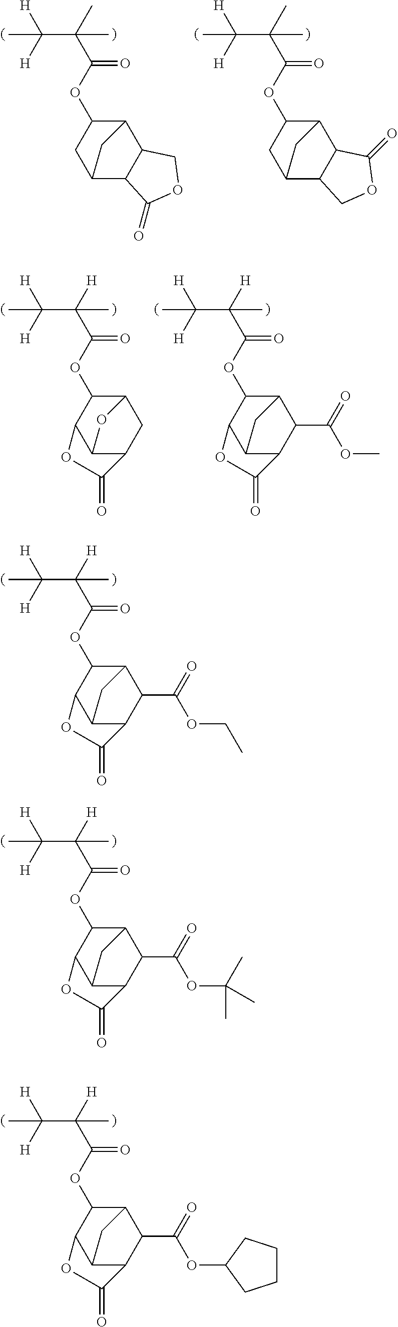

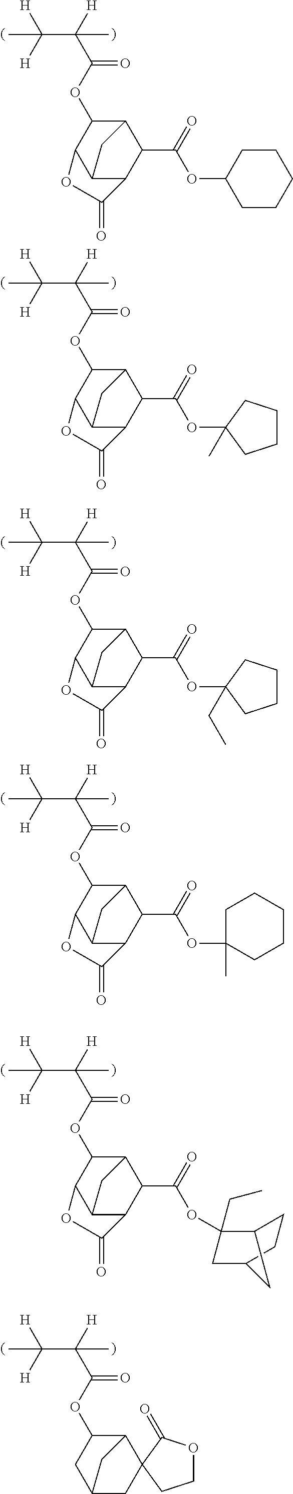

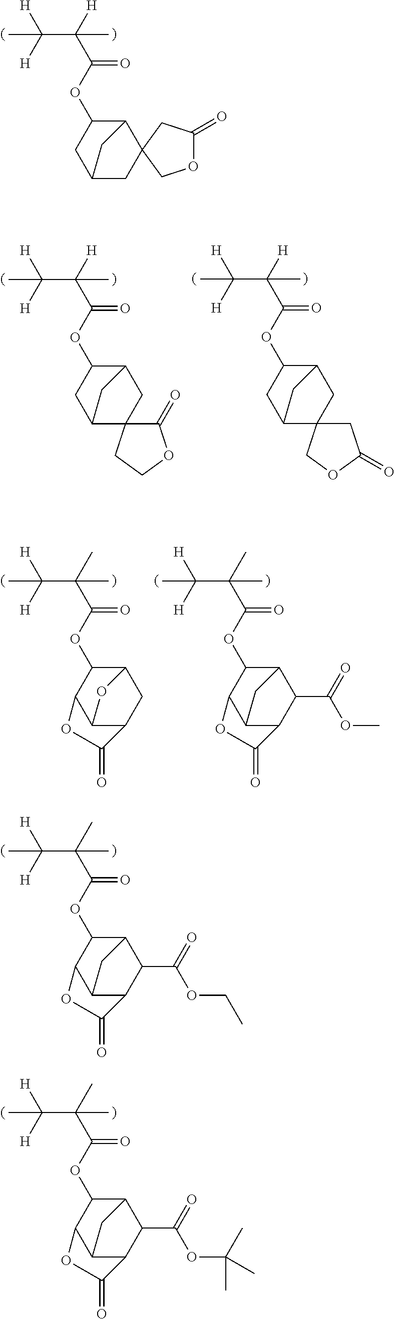

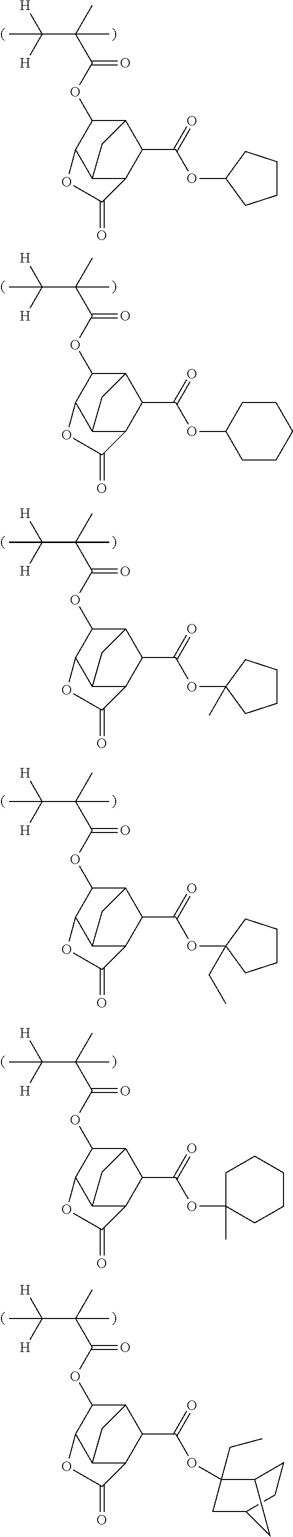

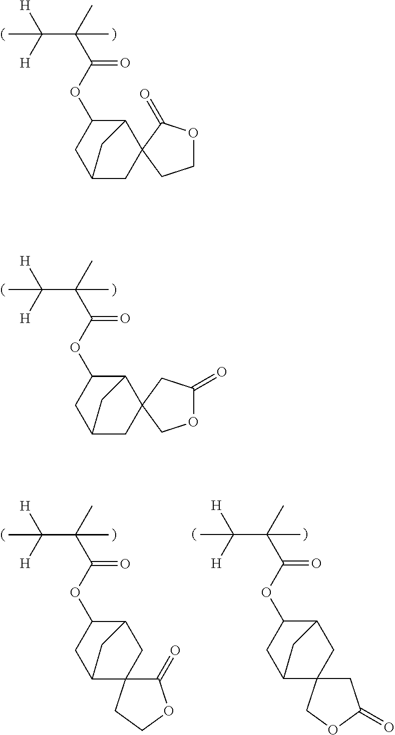

In the above formula (R-1), specific example of the repeating unit introduced with the composition ratio c1′ includes the followings, though not limited to them.

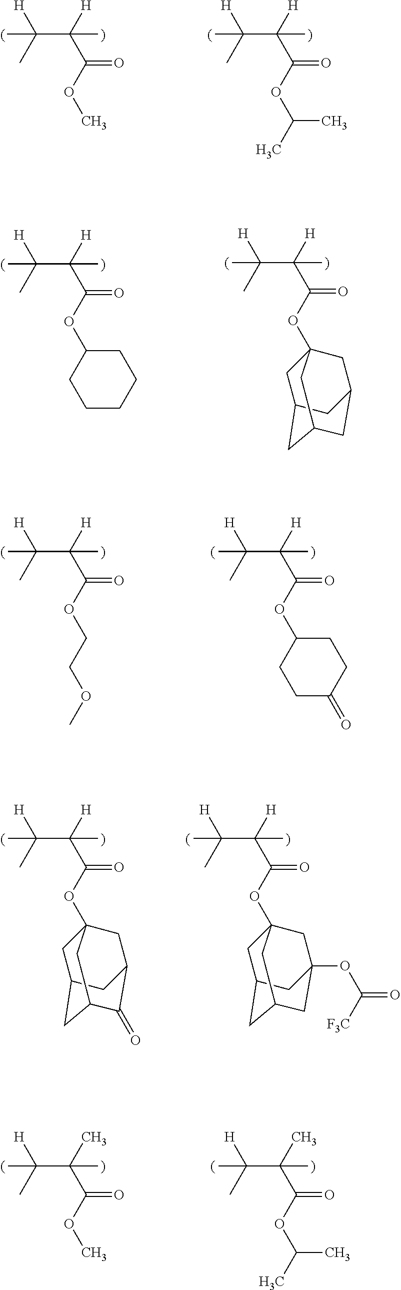

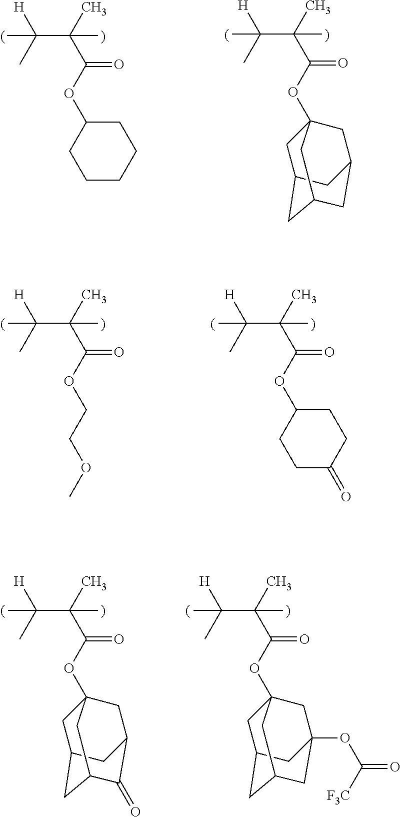

In the above formula (R-1), specific example of the repeating unit introduced with the composition ratio d1′ includes the followings, though not limited to them.

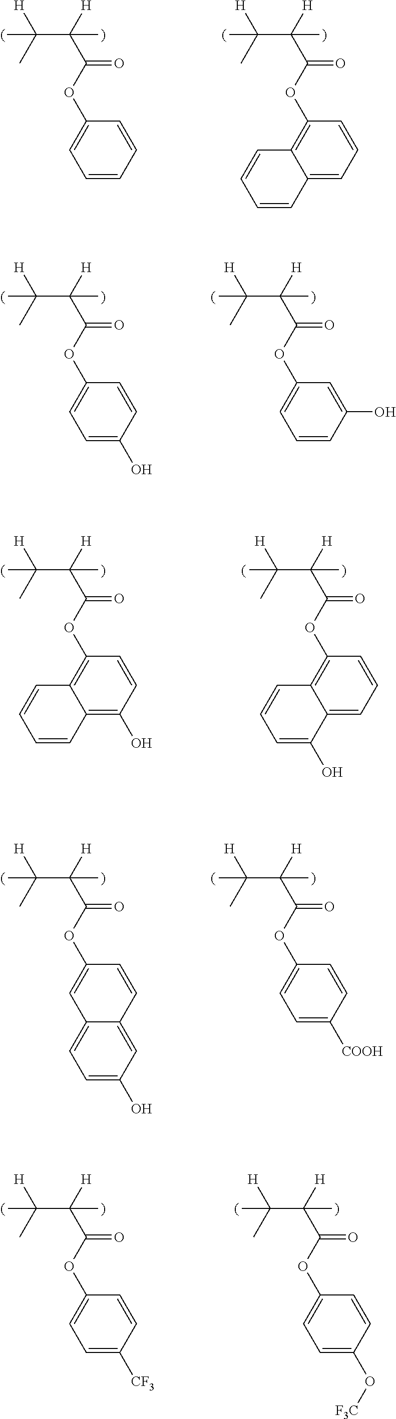

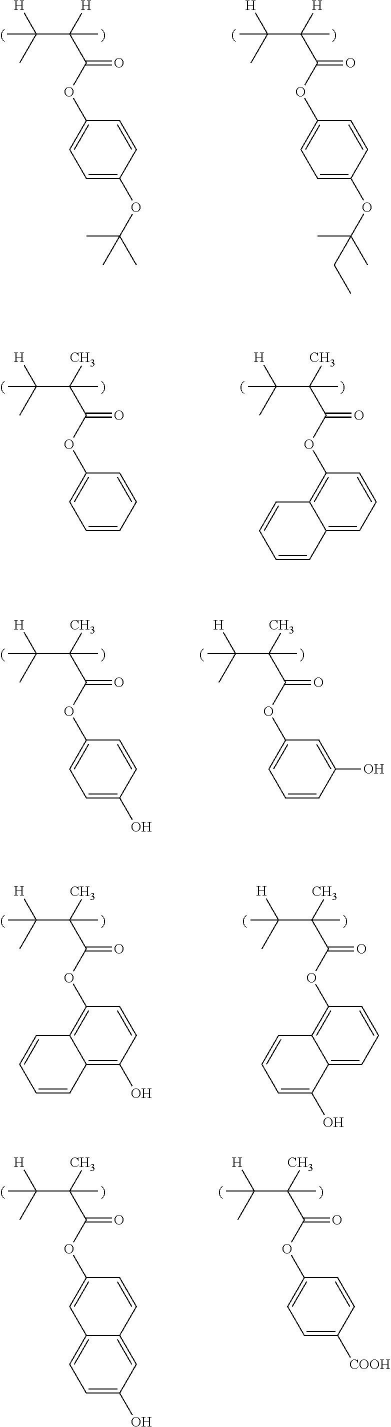

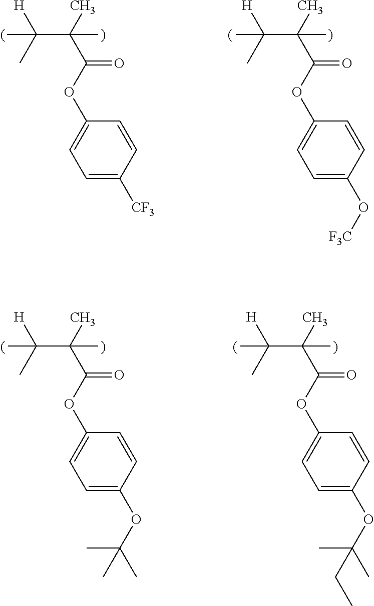

In the above formula (R-1), the repeating unit introduced with the composition ratio e1′ is the repeating unit containing an acid-labile group; and specific example thereof includes the followings, though not limited to them.

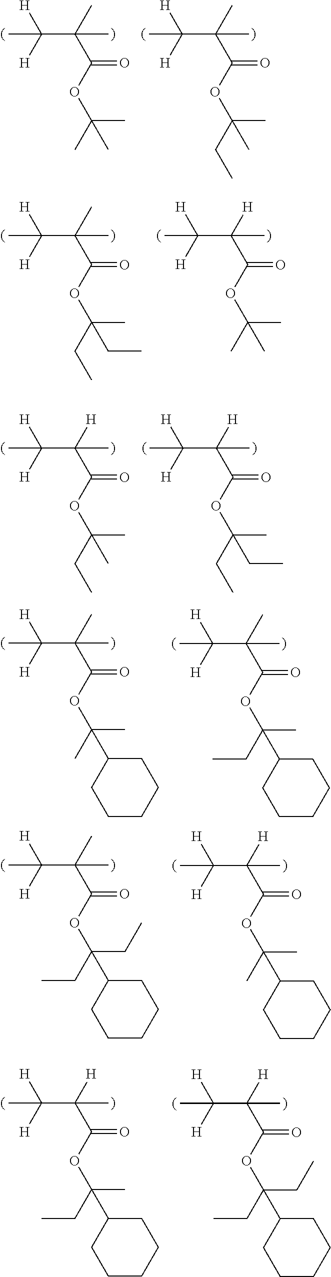

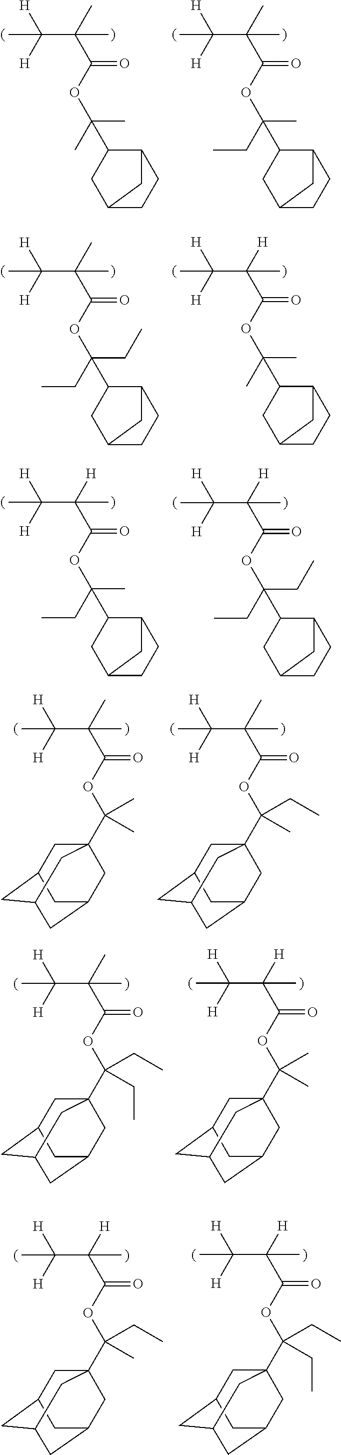

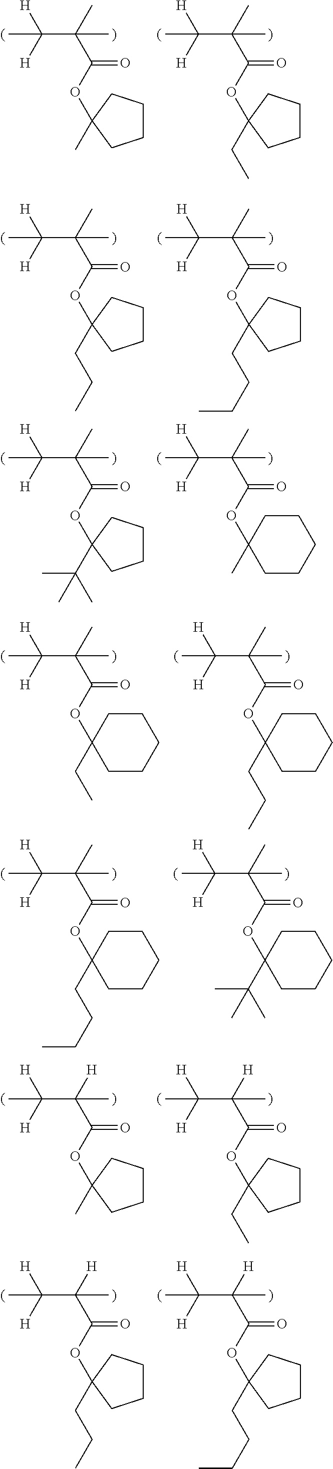

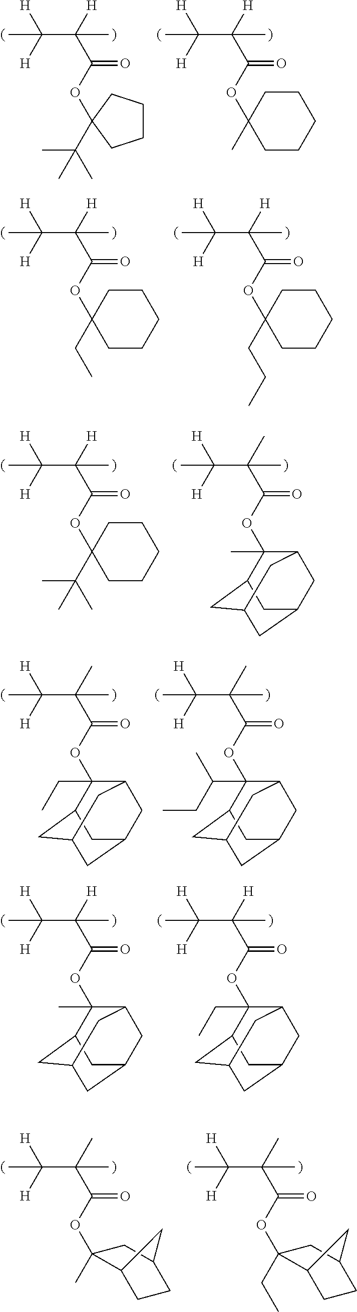

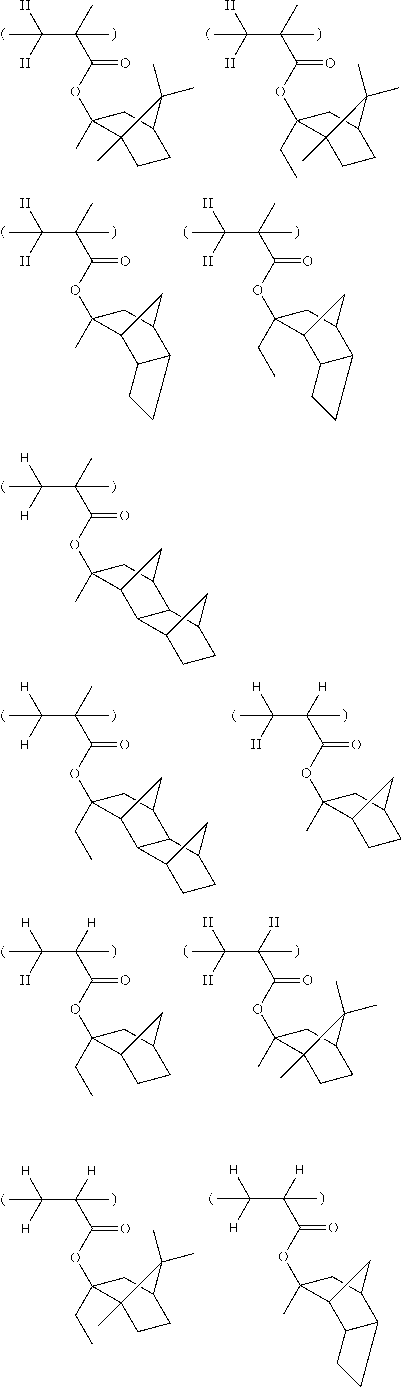

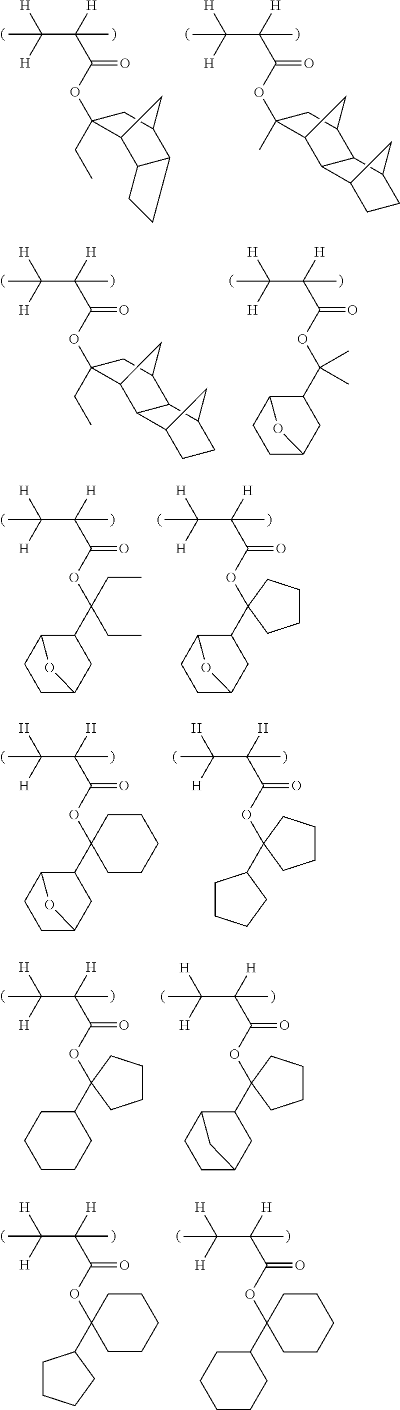

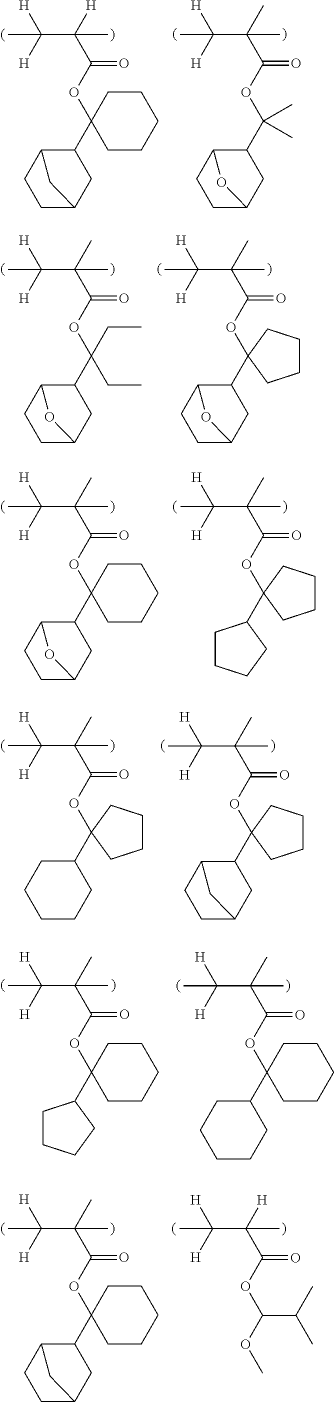

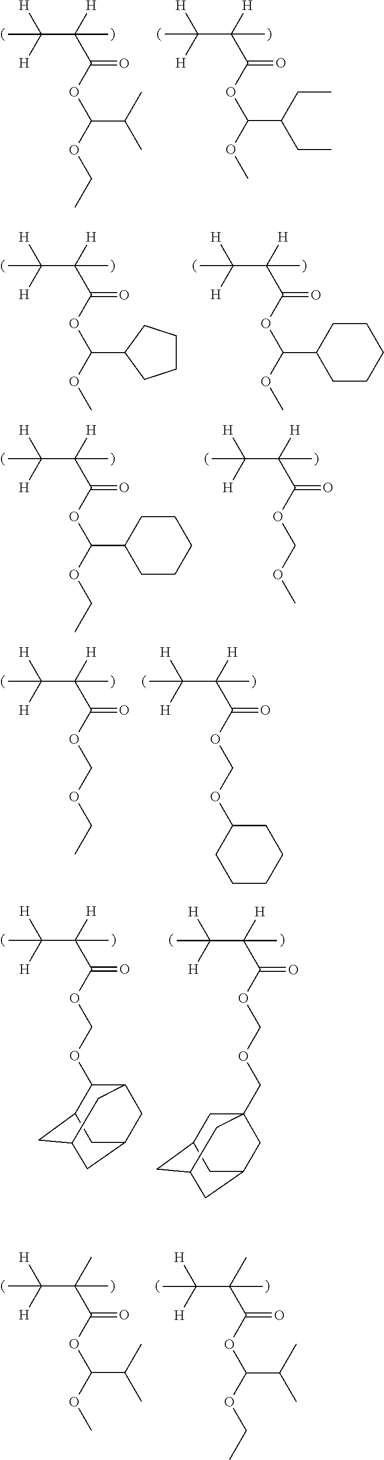

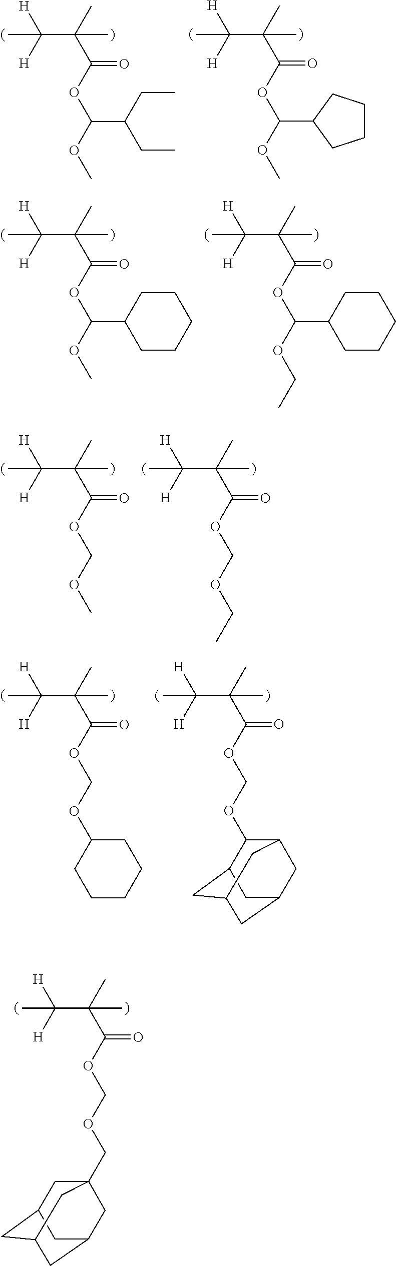

Example of the component (A) base resin having variable dissolution rate into an alkaline developer includes, in addition to the (meth)acrylate resin represented by the above formula (R-1), the following resins (i) to (iv), though not limited to them.

(i) an α-trifluoromethyl acrylate derivative
(ii) a norbornene derivative-maleic anhydride copolymer
(iii) a hydrogenated ring-opening metathesis polymer
(iv) a vinyl ether-maleic anhydride-(meth)acrylate derivative

Among them, a synthesis method of (iii) a hydrogenated ring-opening metathesis polymer is described specifically in Example of Japanese Patent Laid-Open Publication No. 2003-66612. Specific example of the polymer includes those having the following repeating units, though not limited to them.

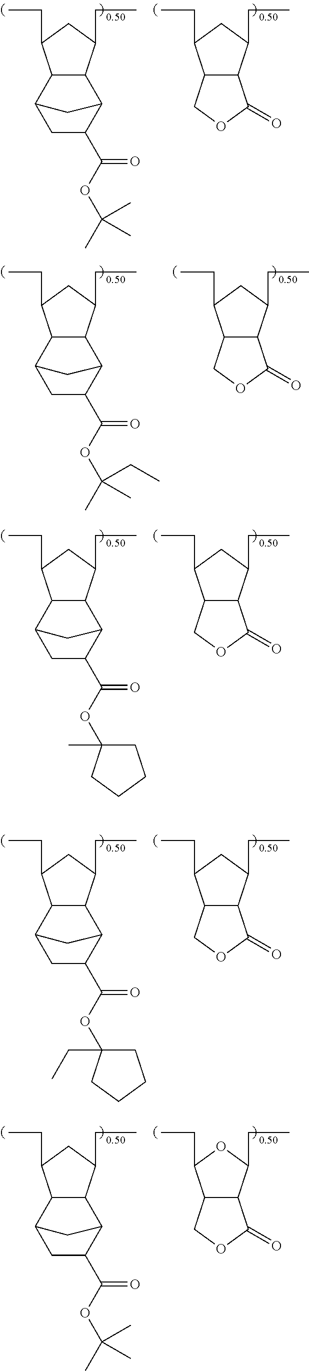

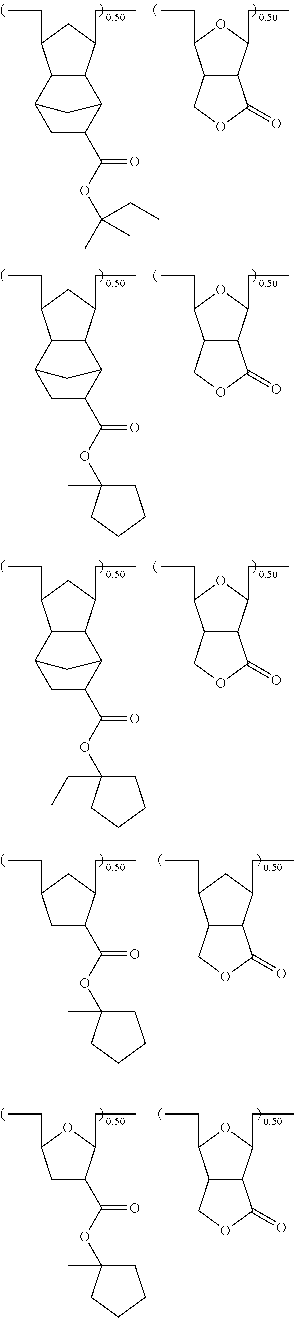

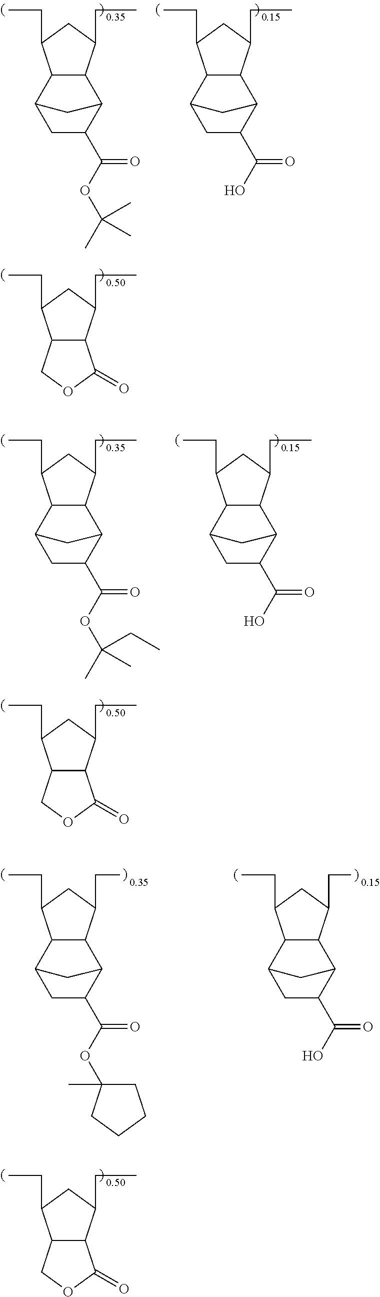

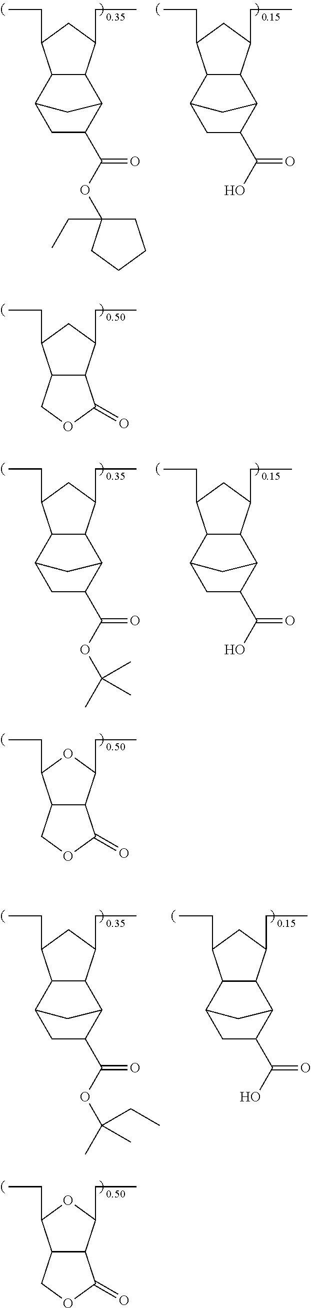

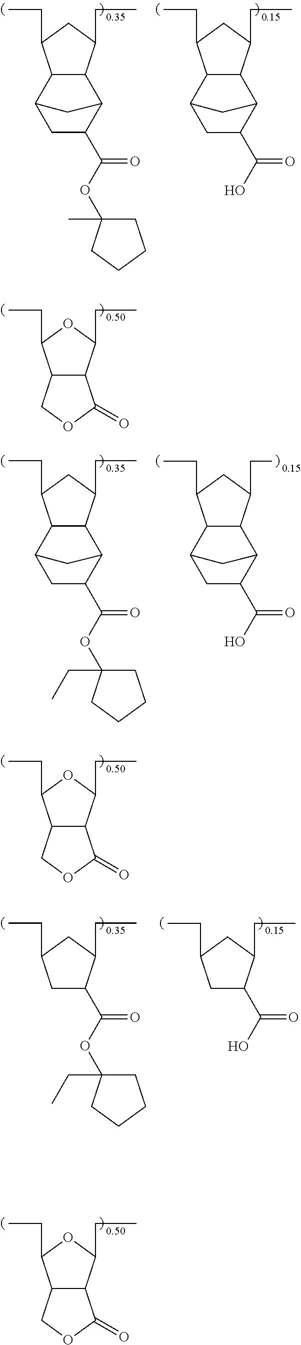

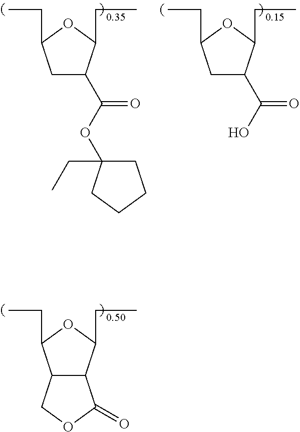

In addition, a repeating unit having a photo sulfonium salt represented by the following general formula (PA) may be contained in the above formula (R-1) by copolymerization;

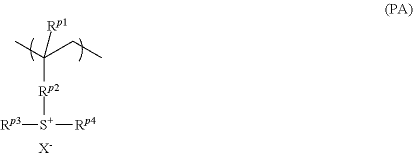

wherein, R^{p1} represents a hydrogen atom or a methyl group; and R^{p2} represents any of a phenylene group, —O—R^{p5}—, and —C(═O)-Q-R^{p5}—. Q represents an oxygen atom or NH; and R^{p5} represents a linear, a branched, or a cyclic alkylene or alkenylene group having 1 to 6 carbon atoms, or a phenylene group, wherein these groups may contain a carbonyl group, an ester bond, or an ether bond. R^{p3} and R^{p4} may be the same or different with each other and represents a linear, a branched, or a cyclic alkyl group having 1 to 12 carbon atoms and optionally containing a carbonyl group, an ester bond, or an ether bond, or any of an aryl group having 6 to 12 carbon atoms, an aralkyl group having 7 to 20 carbon atoms, and a thiophenyl group. X⁻ represents a non-nucleophilic counter ion.

Further, an indene, a norbornadiene, an acenaphthylene, or a vinyl ether may also be copolymerized.

Meanwhile, as to the polymer (A) that constitutes the base resin, not only one kind but also two or more kinds thereof may be added. Properties of the resist composition may be controlled by using a plurality of the polymers.

In addition, the resist composition of the present invention contains a photo acid generator (B) generating a sulfonic acid represented by the following general formula (1) by responding to a high energy beam such as an ultraviolet beam, a far ultraviolet beam, an electron beam, an X-ray, an excimer laser, a γ-beam, and a synchrotron radiation beam.

R²⁰⁰—CF₂SO₃H (1)

Here, R²⁰⁰ represents a halogen atom, or a linear, branched, or cyclic alkyl or aralkyl group having 1 to 23 carbon atoms, or aryl group; and these groups may optionally contain a carbonyl group, an ether bond, or an ester bond, where a hydrogen atom or hydrogen atoms of the alkyl, aralkyl, or aryl group may be substituted with a halogen atom, a hydroxyl group, a carboxyl group, an amino group, or a cyano group.

Specific examples of the sulfonic acid represented by the general formula (1) include perfluoroalkylsulfonic acids such as trifluoromethanesulfonate, pentafluoroethanesulfonate, nonafluorobutanesulfonate, tridecafluorohexanesulfonate, and heptadecafluorooctanesulfonate; and alkylsulfonic acids or aralkylsulfonic acids where part of hydrogen atoms is substituted with fluorine atoms such as 1,1-difluoro-2-naphthyl-ethanesulfonic acid, 1,1,2,2-tetrafluoro-2-(norbornane-2-yl)-ethanesulfonic acid, 1,1-difluoro-2-(norbornane-2-yl)-ethanesulfonic acid, 1,1-difluoro-2-oxo-2-(5-oxoadamantane-1-yloxy)ethanesulfonic acid, 2-(adamantane-1-ylmethyl)-1,1-difluoro-2-oxoethanesulfonic acid, 1,1-difluoro-2-oxo-2-(5-oxo-3,4-dioxatricyclo[4.2.1.0^{3,7}]nona-2-yloxy)ethaneslfonic acid, 2-(adamantane-1-carbonyloxy)-1,1,3,3,3-pentafluoropropanesulfonic acid, and 2-(pyvaloyloxy)-1,1,3,3,3-pentafluoropropanesulfonic acid.

In particular, a sulfonic acid having a structure represented by the following general formula (6), namely a sulfonic acid that is not a perfluoroalkyl sulufonic acid, is preferable.

R²⁰¹—CF₂SO₃H (6)

Here, R²⁰¹ represents a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group, excluding a perfluoroalkyl group.

The sulfonic acid represented by the above general formula (6) is a partially fluorinated alkane sulfonic acid having a reduced fluorine-substitution rate of the sulfonic acid represented by the general formula (1); and, because the acid generator generating a sulfonic acid like this has very low biological concentration and accumulation, this is preferable in view of a reduced environmental burden.

Specific example of the sulfonic acid represented by the above general formula (6) includes 1,1,2,2-tetrafluoro-2-(tetracyclo[4.4.0.1^{2,5}.1^{7,10}]dodeca-3-ene-8-yl)ethane sulfonic acid, 2-(pivaloyloxy)-1,1,3,3,3-pentafluoropropane sulfonic acid, 2-(adamantane-1-carbonyloxy)-1,1-difluoroethane sulfonic acid, and 2-(5-oxoadamantane-1-carbonyloxy)-1,1-difluoroethane sulfonic acid, in addition to the structure having a part of hydrogen atoms of an alkyl sulfonic acid and an aralkyl sulfonic acid substituted with a fluorine atom, which are shown as specific examples of the sulfonic acid represented by the above general formula (1).

Some of the acid generators generating partially fluorinated alkane sulfonic acids have already been in the public domain; for example, in Japanese Patent Application Publication No. 2004-531749, disclosed are a salt of an α,α-difluoroalkyl sulfonic acid developed from an α,α-difluoroalkene and a sulfur compound, and a photo acid generator generating this sulfonic acid by photo-exposure, or specifically a resist composition containing di(4-tert-butylphenyl)iodonium 1,1-difluoro-1-sulfonate-2-(1-naphtyl)ethylene; and in Japanese Patent Laid-Open Publication No. 2004-2252, Japanese Patent Laid-Open Publication No. 2005-352466, and so on, a resist composition using a photo acid generator generating a partially fluorinated alkane sulfonic acid is disclosed.

However, the acid generators disclosed in the foregoing literatures cannot express an effect to sufficiently improve a resolution by themselves; and thus, as the present invention asserts, a combination thereof with a specific polymer additive (C) mentioned later is necessary.

A more preferable sulfonic acid is the one that has a structure containing an ester group, as represented by the following general formula (7) or (8).

Rf—CH(OCOR²⁰²)—CF₂SO₃H (7)

Here, Rf in the above general formula (7) represents a hydrogen atom or a CF₃ group. R²⁰² represents a linear, a branched, or a cyclic substituted or unsubstituted alkyl group having 1 to 20 carbon atoms, or a substituted or an unsubstituted aryl group having 6 to 14 carbon atoms; more specific example thereof includes a methyl group, an ethyl group, a n-propyl group, a sec-propyl group, a cyclopropyl group, a n-butyl group, a sec-butyl group, an iso-butyl group, a tert-butyl group, a n-pentyl group, a cyclopentyl group, a n-hexyl group, a cyclohexyl group, a n-octyl group, a n-decyl group, a n-dodecyl group, a 1-adamantyl group, a 2-adamantyl group, a bicyclo[2.2.1]heptene-2-yl group, a phenyl group, a 4-methoxyphenyl group, a 4-tert-butylphenyl group, a 4-biphenyl group, a 1-naphthyl group, a 2-naphthyl group, a 10-anthranyl group, and a 2-furanyl group. Among these R²⁰² groups, a tert-butyl group, a cyclohexyl group, a 1-adamantyl group, a phenyl group, a 4-tert-butylphenyl group, a 4-methoxyphenyl group, a 4-biphenyl group, a 1-naphtyl group, a 2-naphthyl group, and so on are preferably used; or a tert-butyl group, a cyclohexyl group, a phenyl group, and a 4-tert-butylphenyl group are used more preferably. Examples of the alkyl group and the aryl group having an substituting group include a 2-carboxyethyl group, a 2-(methoxycarbonyl)ethyl group, a 2-(cyclohexyloxycarbonyl)ethyl group, a 2-(1-adamantylmethyloxycarbonyl)ethyl group, a 2-carboxycyclohexyl group, a 2-(methoxycarbonyl)cyclohexyl group, a 2-(cyclohexyloxycarbonyl)cyclohexyl group, a 2-(1-adamantylmethyloxycarbonyl)cyclohexyl group, a 2-carboxyphenyl group, a 2-carboxynaphtyl group, a 4-oxocyclohexyl group, a 4-oxo-1-adamantyl group, and the like.

More specific examples of the sulfonic acid represented by the above general formula (7) are shown below.

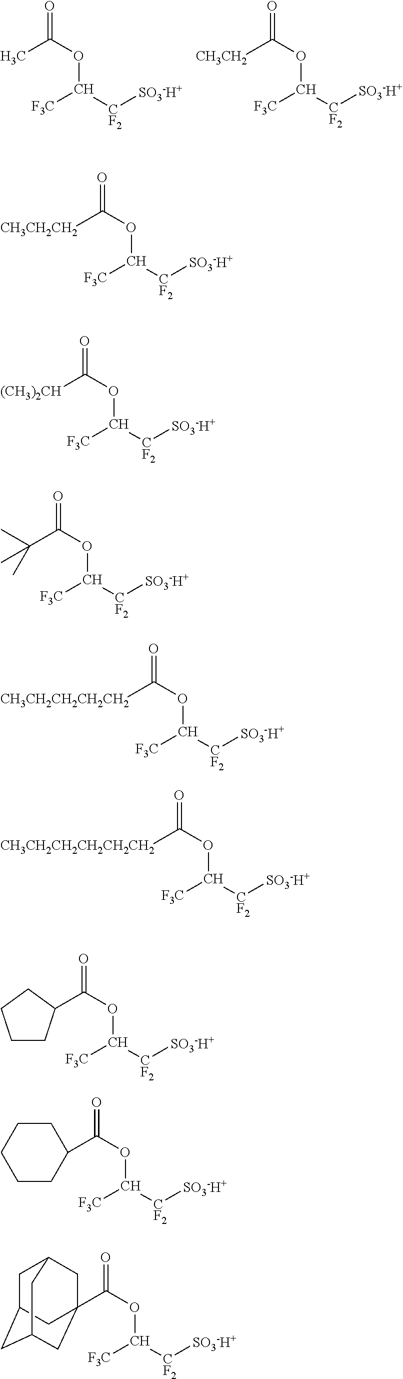

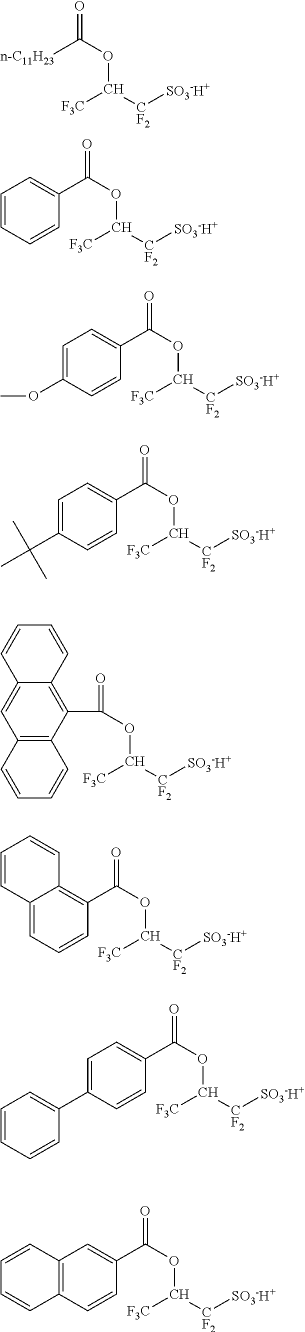

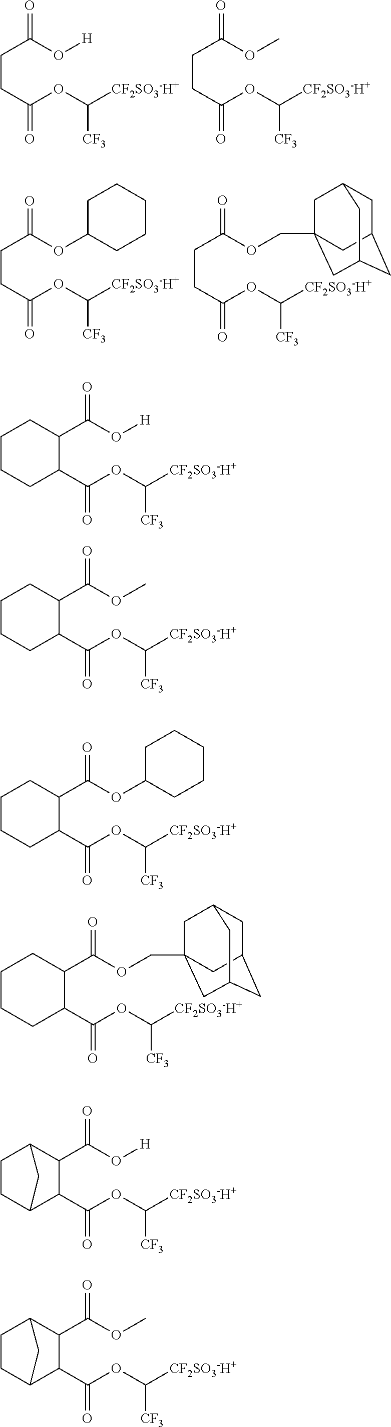

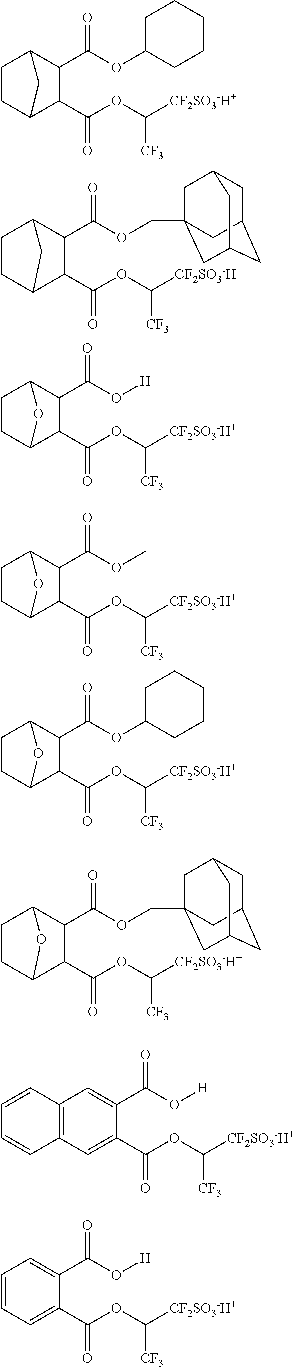

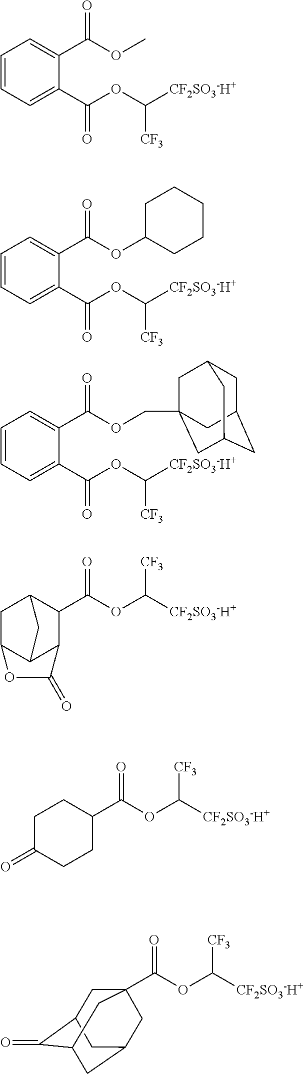

Those having the trifluoromethyl group at the 2^{nd} position of these specifically shown sulfonic acids substituted with a hydrogen atom (Rf in the above general formula (7) is a hydrogen atom) can be used similarly to the above examples.

R²⁰³—OOC—CF₂SO₃H (8)

Here, R²⁰³ represents a linear, a branched, or a cyclic substituted or unsubstituted alkyl group having 1 to 20 carbon atoms, or a substituted or an unsubstituted aryl group having 6 to 14 carbon atoms.

More specific examples thereof include a methyl group, an ethyl group, a n-propyl group, a sec-propyl group, a cyclopropyl group, a n-butyl group, a sec-butyl group, an iso-butyl group, a tert-butyl group, a n-pentyl group, a cyclopentyl group, a n-hexyl group, a cyclohexyl group, a n-octyl group, a n-decyl group, a n-dodecyl group, a 1-adamantyl group, a 2-adamantyl group, a 1-adamantylmethyl group, a 1-(3-hydroxymethyl)adamantylmethyl group, a 4-oxo-1-adamantyl group, a 1-(hexahydro-2-oxo-3,5-methano-2H-cyclopenta[b]furane-6-yl group, 1-(3-hydroxy)adamantylmethyl group, and the like.

More specific examples of the sulfonic acid represented by the above general formula (8) are shown below.

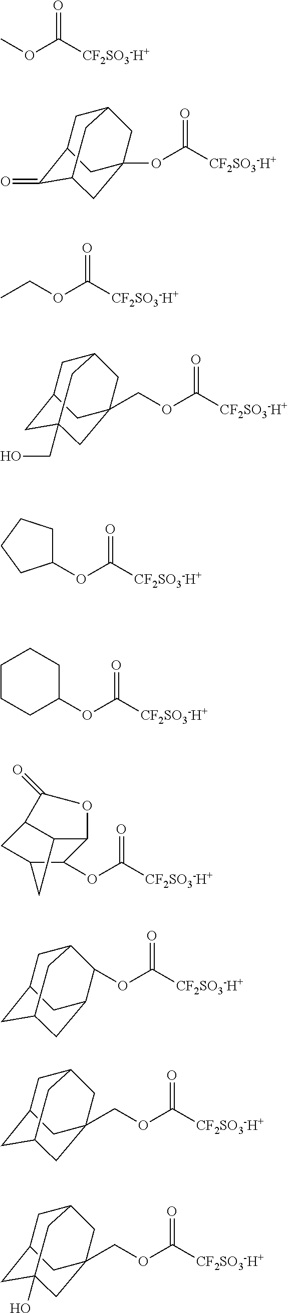

The photo acid generators (B) generating the sulfonic acid represented by the above general formula (1) used for a chemically amplifying resist composition are the compounds typified by a sulfonium salt, an iodonium salt, an oxime sulfonate, and a sulfonyl oxyimide, though not limited to them.

Anions of the sulfonium salts mentioned above are the foregoing sulfonate anions; and specific example of the cations thereof includes triphenyl sulfonium, 4-hydroxyphenyl diphenyl sulfonium, bis(4-hydroxyphenyl)phenyl sulfonium, tris(4-hydroxyphenyl) sulfonium, (4-tert-butoxyphenyl) diphenyl sulfonium, bis(4-tert-butoxyphenyl)phenyl sulfonium, tris(4-tert-butoxyphenyl) sulfonium, (3-tert-butoxyphenyl) diphenyl sulfonium, bis(3-tert-butoxyphenyl)phenyl sulfonium, tris(3-tert-butoxyphenyl) sulfonium, (3,4-di-tert-butoxyphenyl) diphenyl sulfonium, bis(3,4-di-tert-butoxyphenyl)phenyl sulfonium, tris(3,4-di-tert-butoxyphenyl) sulfonium, diphenyl (4-thiophenoxyphenyl) sulfonium, (4-tert-butoxycarbonylmethyloxyphenyl) diphenyl sulfonium, tris(4-tert-butoxycarbonylmethyloxyphenyl) sulfonium, (4-tert-butoxyphenyl) bis(4-dimethylaminophenyl) sulfonium, tris(4-dimethylaminophenyl) sulfonium, 2-naphtyl diphenyl sulfonium, dimethyl 2-naphthyl sulfonium, 4-hydroxyphenyl dimethyl sulfonium, 4-methoxyphenyl dimethyl sulfonium, trimethyl sulfonium, 2-oxocyclohexyl cyclohexyl methyl sulfonium, trinaphthyl sulfonium, tribenzyl sulfonium, diphenyl methyl sulfonium, dimethyl phenyl sulfonium, 2-oxo-2-phenylethyl thiacyclopentanium, diphenyl 2-thienyl sulfonium, 4-n-butoxynaphtyl-1-thiacyclopentanium, 2-n-butoxynaphtyl-1-thiacyclopentanium, 4-methoxynaphtyl-1-thiacyclopentanium, and 2-methoxynaphtyl-1-thiacyclopentanium. More preferable example thereof includes triphenyl sulfonium, 4-tert-butylphenyl diphenyl sulfonium, 4-tert-butoxyphenyl diphenyl sulfonium, tris(4-tert-butylphenyl) sulfonium, and (4-tert-butoxycarbonylmethyloxyphenyl) diphenyl sulfonium.

Further, example thereof includes 4-(methacryloyloxy)phenyl diphenyl sulfonium, 4-(acryloyloxy)phenyl diphenyl sulfonium, 4-(methacryloyloxy)phenyl dimethyl sulfonium, and 4-(acryloyloxy)phenyl dimethyl sulfonium. These polymerizable sulfonium cations can be referred to Japanese Patent Laid-Open Publication No. H04-230645, Japanese Patent Laid-Open Publication No. 2005-84365, and so on; and these polymerizable sulfonium salts can be used as the monomers of the constituting components in the afore-mentioned polymer.

Anions of the iodonium salts are the afore-mentioned sulfonate anions; and specific example of the cations thereof includes bis(4-methylphenyl) iodonium, bis(4-ethylphenyl) iodonium, bis(4-tert-butylphenyl) iodonium, bis(4-(1,1-dimethylpropyl)phenyl) iodonium, 4-methoxyphenyl phenyl iodonium, 4-tert-butoxyphenyl phenyl iodonium, 4-acryloyloxyphenyl phenyl iodonium, and 4-methacryloyloxyphenyl phenyl iodonium; and among them, bis(4-tert-butylphenyl) iodonium is preferably used.

The N-sulfonyl oxyimide compound is formed by a sulfonate ester bond between the afore-mentioned sulfonic acid and an N-hydroxyimide; and specific examples of the imide skeleton excluding the sulfonate moiety are shown below. The imide skeletons can be referred to Japanese Patent Laid-Open Publication No. 2003-252855.

Meanwhile, bonding sites with the sulfonate moiety are shown by the dotted lines.

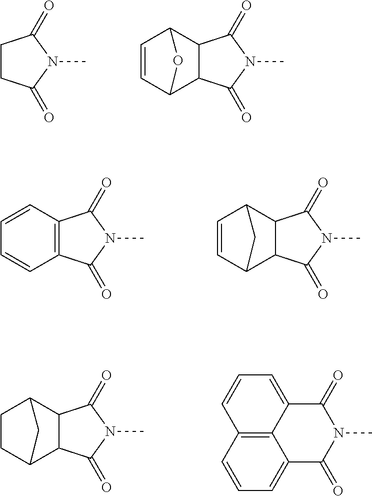

The oxime sulfonate compound is formed by a sulfonate ester bond between the afore-mentioned sulfonic acid and an oxime; more specific oxime sulfonate skeletons are shown below. Meanwhile, bonding sites with the sulfonate moiety are shown by the dotted lines. These oxime sulfonate skeletons are described in many publications such as Japanese Patent No. 2906999.

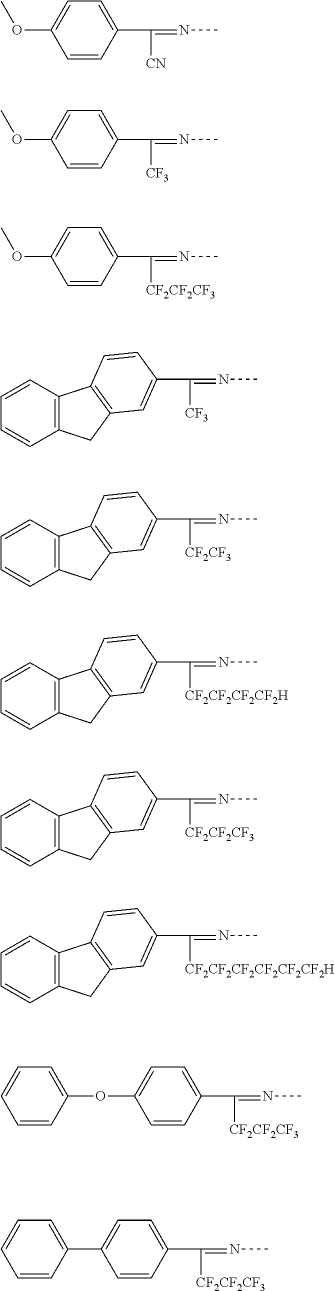

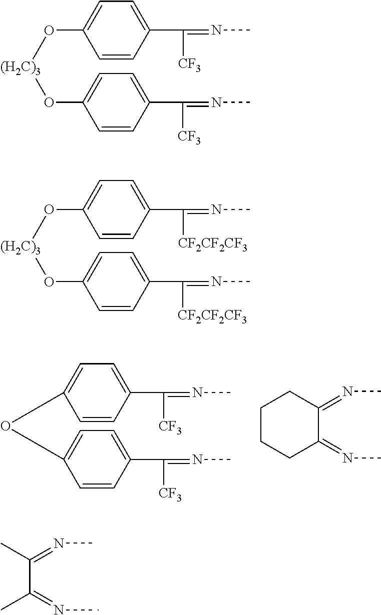

Here, a salt of the sulfonic acid represented by the above general formula (7) and a photo acid generator can be synthesized with reference to Japanese Patent Laid-Open Publication No. 2007-145797, Japanese Patent Laid-Open Publication No. 2009-7327, and so on.

Because a salt of the sulfonic acid represented by the above general formula (7) has an ester part in its molecular structure, a small acyl group to a bulky acyl group, a benzoyl group, a naphthoyl group, an anthrayl group, and so on can be introduced thereinto easily; and thus, an allowance of the molecular design thereof can be made wider. In addition, the photo acid generators generating these sulfonic acids can be used without problems in steps of coating, pre-exposure baking, exposure, post-exposure baking, and development in the device manufacturing process. Further, not only elution thereof into water during an ArF immersion exposure can be prevented, but also a defect can be suppressed because an effect of water remained on a wafer is small. The ester part is hydrolyzed by an alkali during resist effluent treatment after manufacturing of a device thereby changeable to a lower molecular weight compound with low accumulation; and in addition, because of a low fluorination rate, burning efficiency thereof is high in waste disposal.

A photo acid generator generating the sulfonic acid represented by the above general formula (8) of the present invention can be synthesized by an acid-catalyzed dehydration condensation of sodium difluorosulfoacetate with a corresponding alcohol, as described in Japanese Patent Laid-Open Publication No. 2006-257078 or by a reaction with a corresponding alcohol in the presence of 1,1′-carbonyl diimidazole to obtain a sodium sulfonate; and then this sulfonate can be transformed to a sulfonium salt or to an iodonium salt by heretofore known methods. In order to transform to an imide sulfonate or to an oxime sulfonate, the afore-mentioned sulfonate is transformed by heretofore known methods to a sulfonyl halide or a sulfonic acid anhydride, which are then reacted with a corresponding hydroxyimide or a corresponding oxime.

Similarly to the sulfonic acid represented by the above general formula (7), the sulfonic acid represented by the above general formula (8) has an ester part in its molecular structure; and thus, an allowance of the molecular design thereof can be made wider. In addition, photo acid generators generating these sulfonic acids can be used without problems in steps of coating, pre-exposure baking, exposure, post-exposure baking, and development in the device manufacturing process. Further, not only elution thereof into water during an ArF immersion exposure can be prevented, but also a defect can be suppressed because an effect of water remained on a wafer is small. The ester part is hydrolyzed by an alkali during resist effluent treatment after manufacturing of a device, thereby changeable to a lower molecular weight compound with low accumulation; and in addition, because of a low fluorination rate, burning efficiency thereof is high in waste disposal.

Amount of the photo acid generator (B) to be added into the resist composition of the present invention is 0.1 to 20 parts by mass, or preferably 0.1 to 15 parts by mass, relative to 100 parts by mass of the base polymer (polymer (A) that is a resin component in the resist composition of the present invention, and as appropriate, other resin component contained therein) in the resist composition, though the amount is arbitrary. If the photo acid generator (B) is contained with the amount as mentioned above, there is no fear of problems of resolution deterioration and foreign matters during development and resist removal.

The photo acid generator (B) can be used singly or as a mixture of two or more kinds thereof. In addition, if a photo acid generator having a low transmittance at the wavelength of an exposure light is used, transmittance within a resist film can be controlled by the adding amount thereof.

Further, in addition to the afore-mentioned photo acid generator (B), another photo acid generator generating an acid by responding to an active light beam or a radial ray may be contained therein. This photo acid generator may be any compound, provided that the compound generates an acid by exposure to a high energy beam; and thus, any of heretofore known photo acid generators used in a conventional resist composition, especially in a chemically amplifying resist composition, may be used. Suitable photo acid generators are acid generators with a type of a sulfonium salt, an iodonium salt, an N-sulfonyl oxyimide, an oxime-O-sulfonate, and so on. Details of them are described in Japanese Patent Laid-Open Publication No. 2009-269953 and so on.

The resist composition of the present invention contains, in addition to the afore-mentioned polymer (A) that becomes a base resin whose alkaline-solubility changes by the acid and the afore-mentioned photo acid generator (B) generating the specific sulfonic acid, a polymer (polymer additive (C)) represented by the following general formula (2) as an additive.

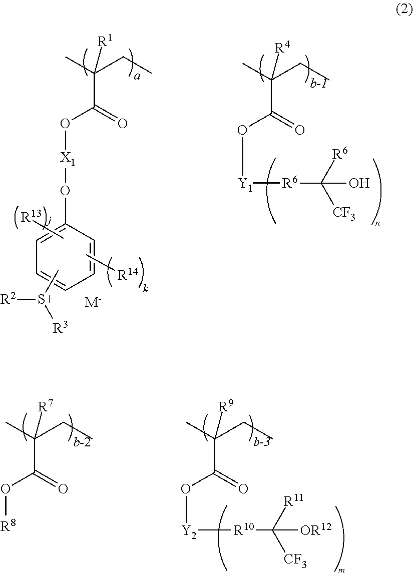

Each of R¹, R⁴, R⁷, and R⁹ independently represents a hydrogen atom or a methyl group. X₁ represents a linear or a branched alkylene group having 1 to 10 carbon atoms. Each of R² and R³ independently represents any of linear, branched, and cyclic substituted or unsubstituted alkyl, alkenyl, and oxoalkyl groups having 1 to 10 carbon atoms and optionally containing a heteroatom; or any of substituted or unsubstituted aryl, aralkyl, and aryl oxoalkyl groups having 6 to 20 carbon atoms; or R² and R³ may be bonded to form a ring together with the sulfur atom in the formula. R⁵ and R¹⁰ represent a linear, a branched, or a cyclic alkylene group having 1 to 20 carbon atoms, wherein one or plurality of the hydrogen atoms in these groups may be substituted with a fluorine atom. R⁶ represents any of a hydrogen atom, a fluorine atom, a methyl group, a trifluoromethyl group, and a difluoromethyl group; or R⁵ and R⁶ may form an aliphatic ring having 5 to 12 carbon atoms together with the carbon atom to which these groups are bonded, wherein these rings may contain an ether bond, a fluorine-substituted alkylene group, or a trifluoromethyl group. Similarly, R¹¹ represents any of a hydrogen atom, a fluorine atom, a methyl group, a trifluoromethyl group, and a difluoromethyl group; or R¹⁰ and R¹¹ may form an aliphatic ring having 5 to 12 carbon atoms together with the carbon atom to which these groups are bonded, wherein these rings may contain an ether bond, a fluorine-substituted alkylene group, or a trifluoromethyl group. Each of n and m independently represents 1 or 2. In the case of n=1 and m=1, each of Y₁ and Y₂ independently represents a single bond, or a linear, a branched, or a cyclic alkylene group having 1 to 10 carbon atoms and optionally containing a carbonyl group, an ether bond, and an ester bond; and in the case of n=2 and m=2, Y₁ and Y₂ represent a trivalent connecting group having a form that one hydrogen atom is removed from the alkylene group shown by Y₁ and Y₂ of the case of n=1 and m=1 mentioned above. R⁸ represents a linear, a branched, or a cyclic alkyl group, having 1 to 20 carbon atoms, substituted by at least one fluorine atom, and optionally containing an ether bond, an ester bond, or a sulfonamide group. R¹² represents an acid-labile group. Each of R¹³ and R¹⁴ independently represents a linear or a branched alkyl group having 1 to 5 carbon atoms optionally containing a heteroatom. Each of j and k independently represents 0 or 1; and M⁻ will be described later in detail.

A polymerizable monomer to give a repeating unit “a” in the above general formula (2) is a salt composed of a sulfonium cation having a polymerizable group represented by the following general formula (9) and an anion M⁻ described later;

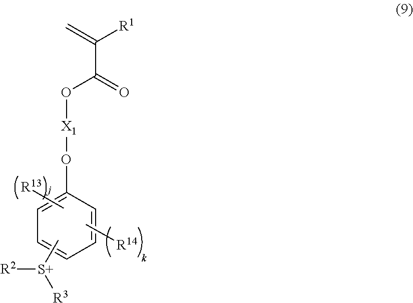

wherein, R¹ to R³, X₁, R¹³, R¹⁴, j, and k represent the same meanings as before.

Here, specific examples of the cation represented by the general formula (9) are shown below.

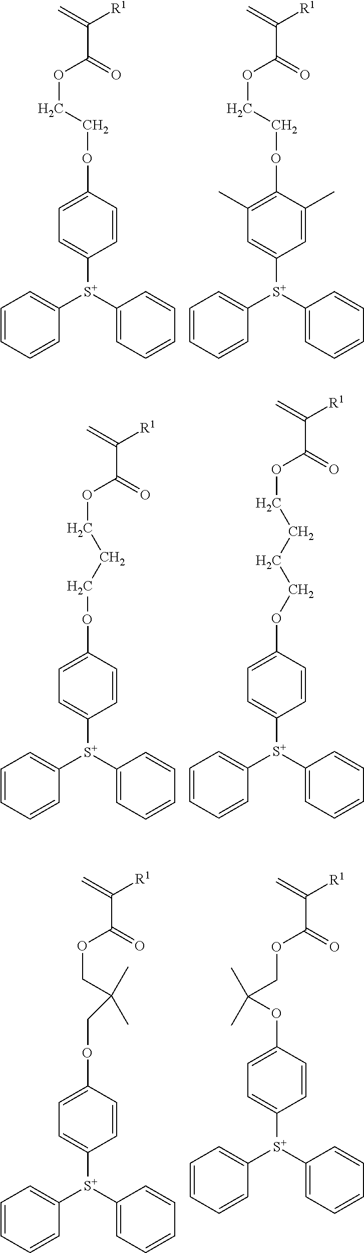

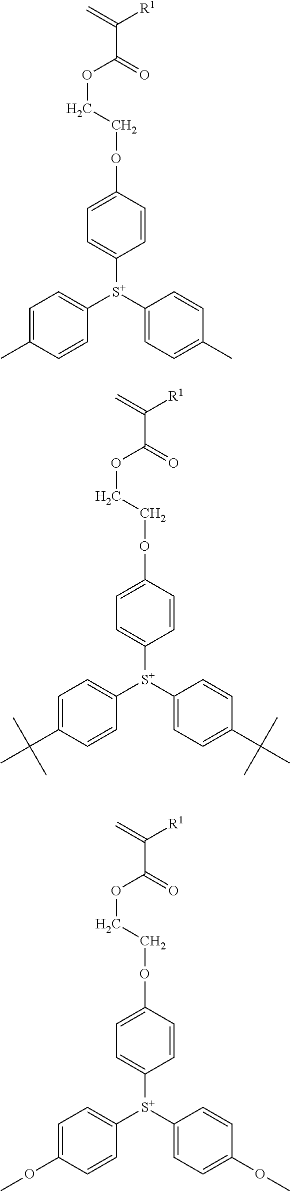

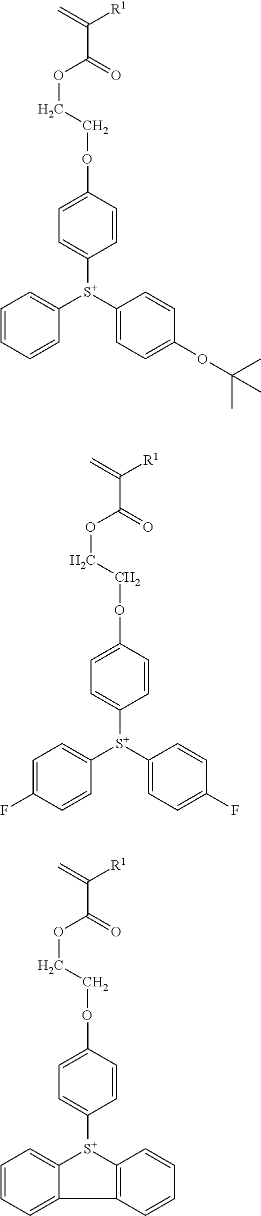

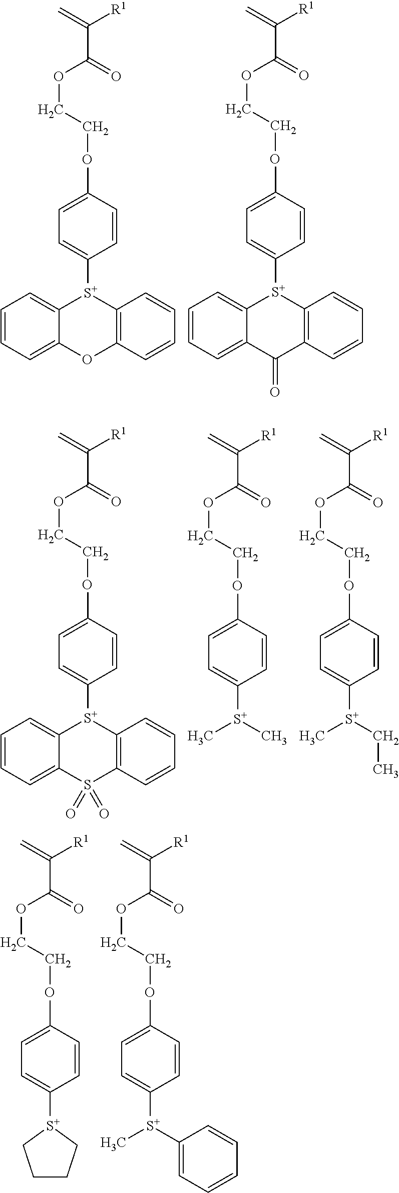

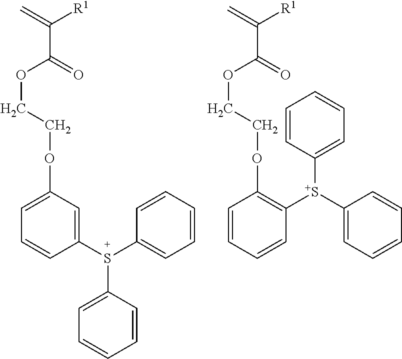

In the formulae, R¹ represents the same meaning as before.

Further, a counter anion M⁻ in the above general formula (2) represents any of an alkane sulfonate ion represented by the following general formula (3), an arene sulfonate ion represented by the following general formula (4), and a carboxylate ion represented by the following general formula (5);

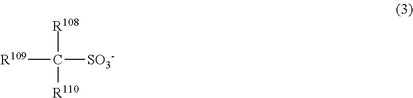

wherein, each of R¹⁰⁸, R¹⁰⁹, and R¹¹⁰ independently represents a hydrogen atom or a halogen atom excluding a fluorine atom; or any of linear, branched, and cyclic alkyl, alkenyl, and aralkyl groups having 1 to 20 carbon atoms and optionally containing a carbonyl group, an ether bond, and an ester bond, or an aryl group, wherein one or a plurality of the hydrogen atoms of these groups may be substituted with a halogen atom, a hydroxyl group, a carboxyl group, an amino group, or a cyano group. Further, two or more of R¹⁰⁸, R¹⁰⁹ and R¹¹⁰ may be bonded with each other to form a ring.

R¹¹¹—SO₃⁻ (4)

wherein, R¹¹¹ represents an aryl group having 1 to 20 carbon atoms. One or a plurality of the hydrogen atoms of the aryl group may be substituted with a halogen atom, a hydroxyl group, a carboxyl group, an amino group, or a cyano group, and further with a linear, a branched, or a cyclic alkyl group having 1 to 20 carbon atoms.

R¹¹²—COO⁻ (5)

wherein, R¹¹² represents any of linear, branched, and cyclic alkyl, alkenyl, and aralkyl groups having 1 to 20 carbon atoms and optionally containing a carbonyl group, an ether bond, and an ester bond, or an aryl group, wherein one or a plurality of the hydrogen atoms of these groups may be substituted with a halogen atom, a hydroxyl group, a carboxyl group, an amino group, or a cyano group.

Specific examples of the alkane sulfonate anion represented by the general formula (3) include a methanesulfonate, ethanesulfonate, propanesulfonate, butanesulfonate, pentanesulfonate, hexanesulfonate, cyclohexanesulfonate, octanesulfonate, 10-camphorsulfonate, and the following groups.

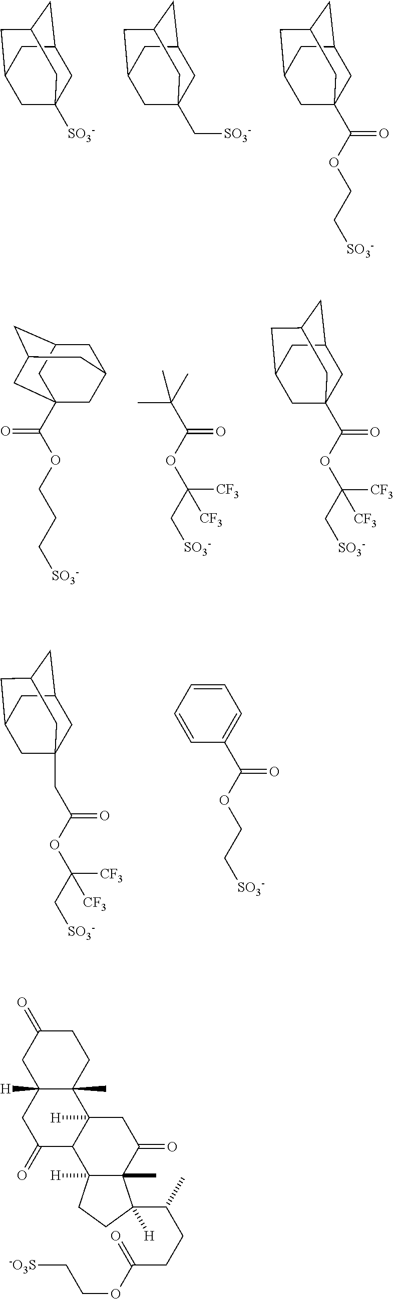

Specific example of the arene sulfonate anion represented by the above general formula (4) includes benzene sulfonate, 4-toluene sulfonate, 2-toluene sulfonate, xylene sulfonates substituted at arbitrary positions, trimethylbenzene sulfonate, mesitylene sulfonate, 4-methoxybenzene sulfonate, 4-ethylbenzene sulfonate, 2,4,6-triisopropylbenzene sulfonate, 1-naphthalene sulfonate, 2-naphthalene sulfonate, anthraquinone-1-sulfonate, anthraquinone-2-sulfonate, 4 (4-methylbenzenesulfonyloxy)benzene sulfonate, 3,4-bis(4-methylbenzenesulfonyloxy)benzene sulfonate, 6-(4-methylbenzenesulfonyloxy)naphthalene-2-sulfonate, 4-phenyloxybenzene sulfonate, 4-diphenylmethylbenzene sulfonate, 2,4-dinitrobenzene sulfonate, and dodecylbenzene sulfonate.

Specific example of the carboxylate anion represented by the above general formula (5) includes a formate anion, an acetate anion, a propionate anion, a butyrate anion, an isobutyrate anion, a valerate anion, an isovalerate anion, a pivalate anion, a hexanoate anion, an ocatanoate anion, a cyclohexanecarboxylate anion, a cyclohexylacetate anion, a laurate anion, a myristate anion, a palmitate anion, a stearate anion, a phenylacetate anion, a diphenylacetate anion, a phenoxyacetate anion, a mandelate anion, a benzoylformate anion, a cinnamate anion, a dihydrocinnamate anion, a benzoate anion, a methylbenzoate anion, a salicylate anion, a naphthalenecarboxylate anion, an anthracenecarboxylate anion, an anthraquinonecarboxylate anion, a hydroxyacetate anion, a pivalate anion, a lactate anion, a methoxyacetate anion, a 2-(2-methoxyethoxy)acetate anion, a 2-(2-(2-methoxyethoxy)ethoxy)acetate anion, a diphenolate anion, a monochloroacetate anion, a dichloroacetate anion, a trichloroacetate anion, a trifluoroacetate anion, a pentafluoropropionate anion, and a heptafluorobutyrate anion; and in addition, also included are monoanions of dicarboxylic acids such as succinic acid, tartaric acid, glutaric acid, pimelic acid, sebacic acid, phthalic acid, isophthalic acid, terephthalic acid, naphthalenedicarboxylic acid, cyclohexanedicarboxylic acid, and cyclohexenedicarboxylic acid.

Then, illustrative example of the monomer to give the repeating unit having an α-trifluoromethyl alcohol group, represented by (b-1) in the above general formula (2), includes the following compounds.

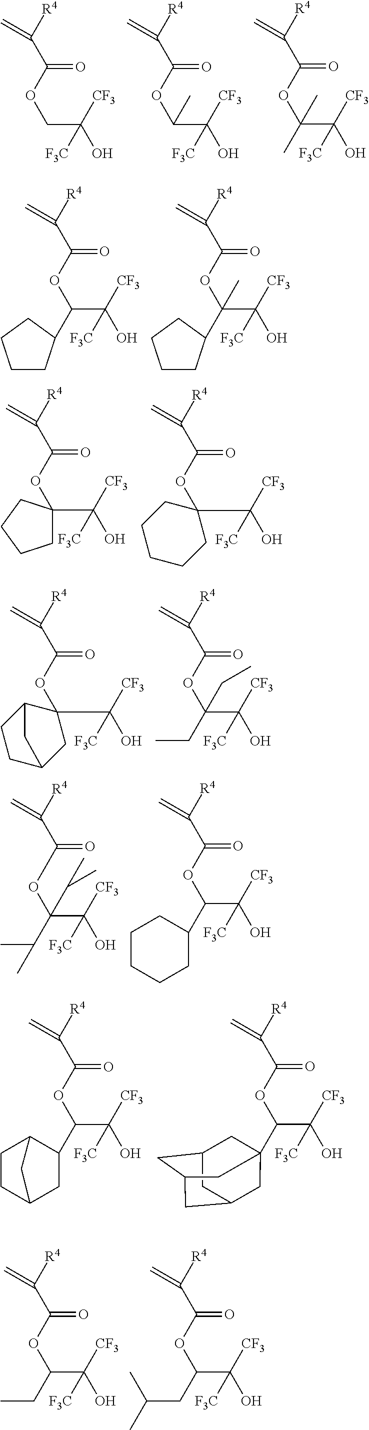

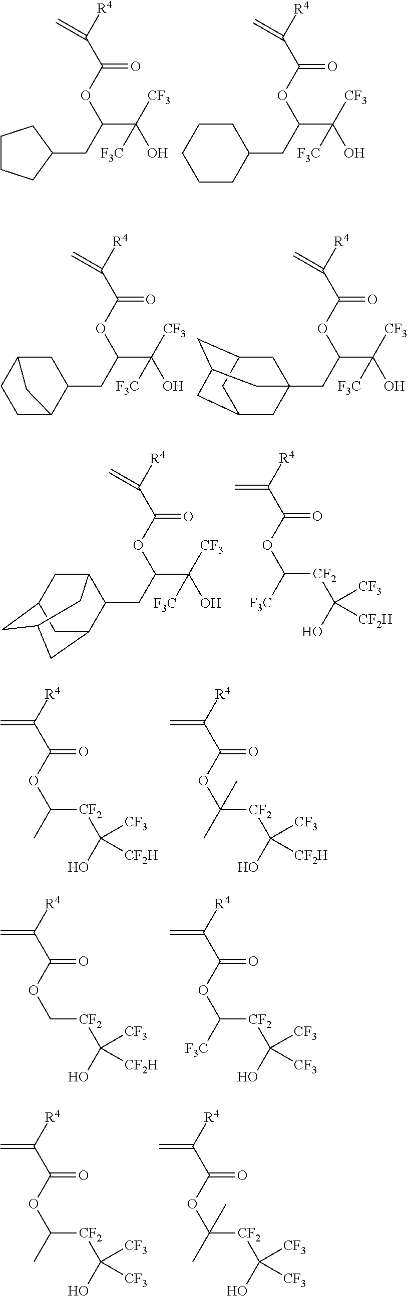

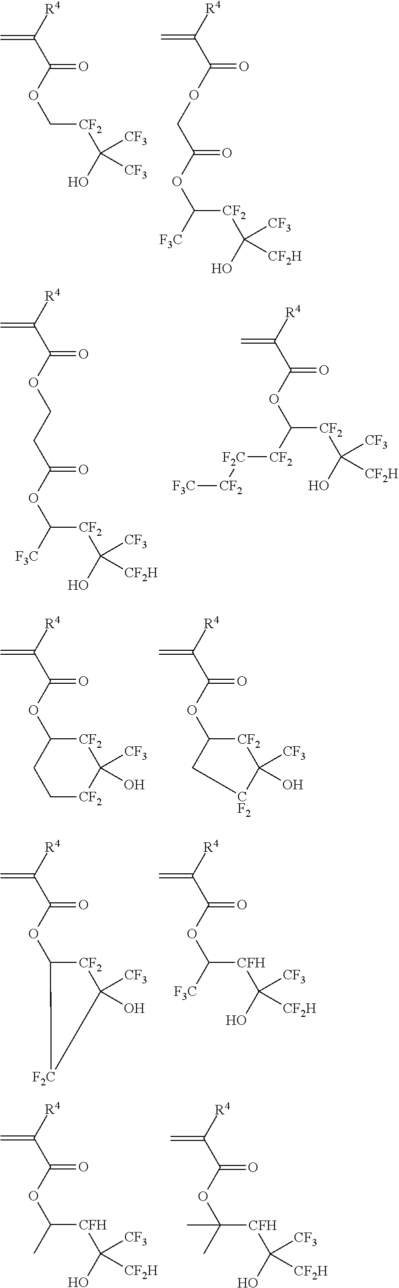

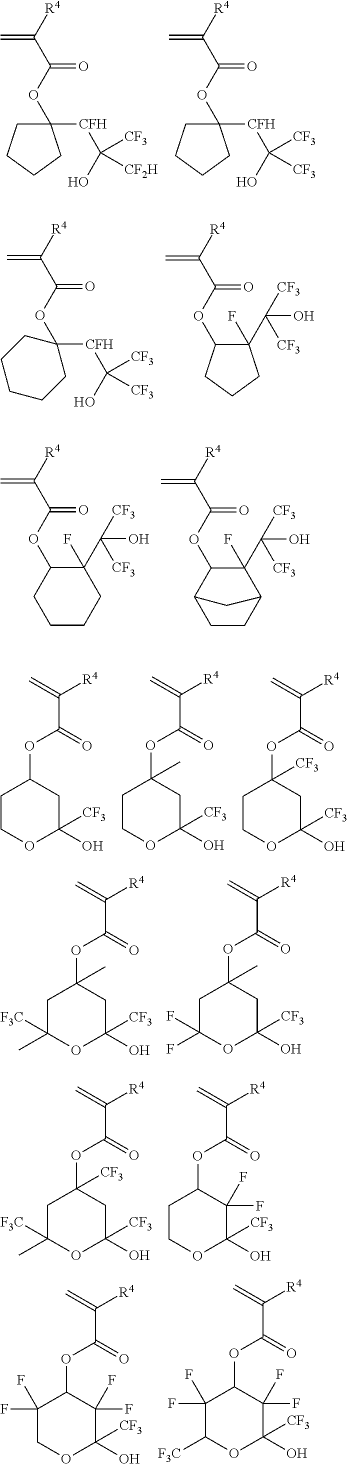

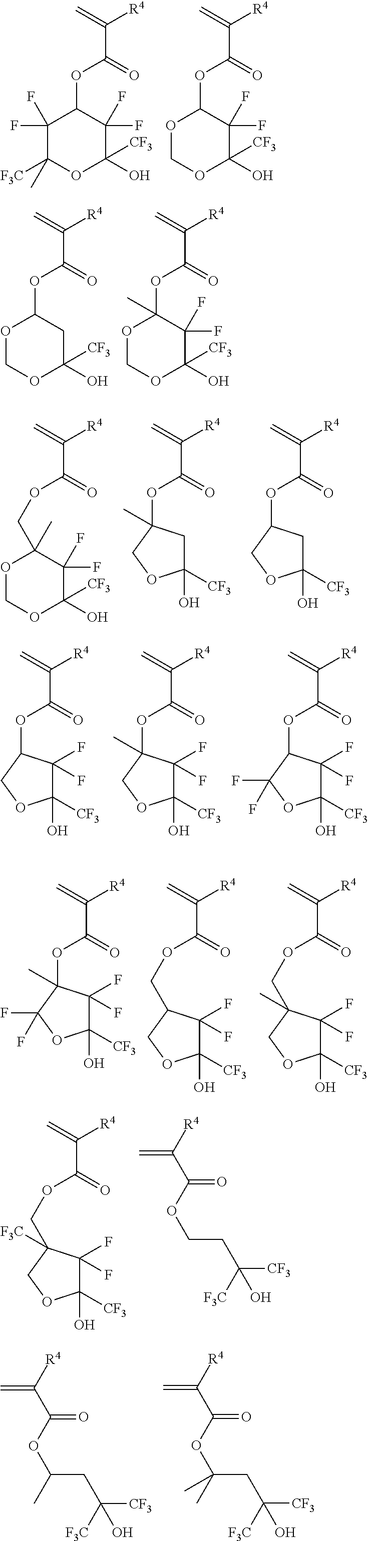

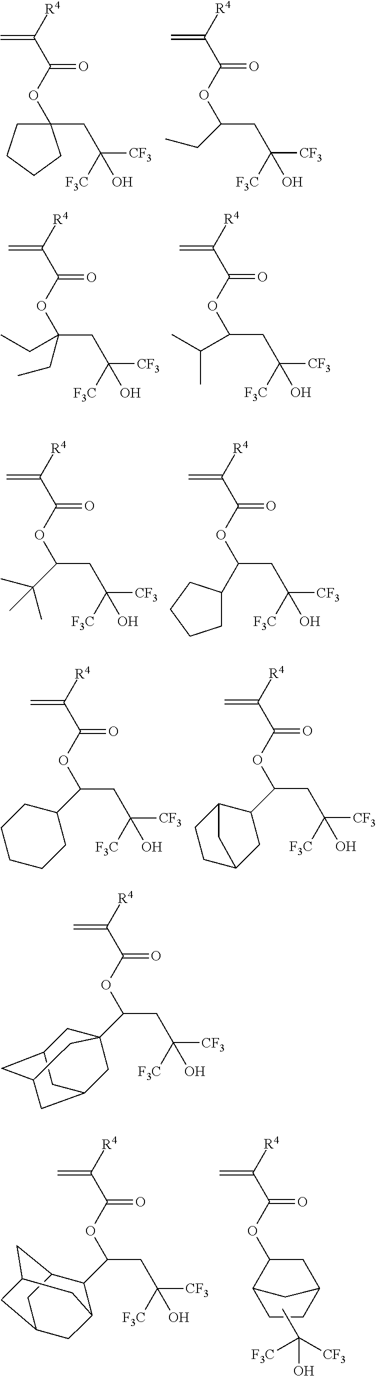

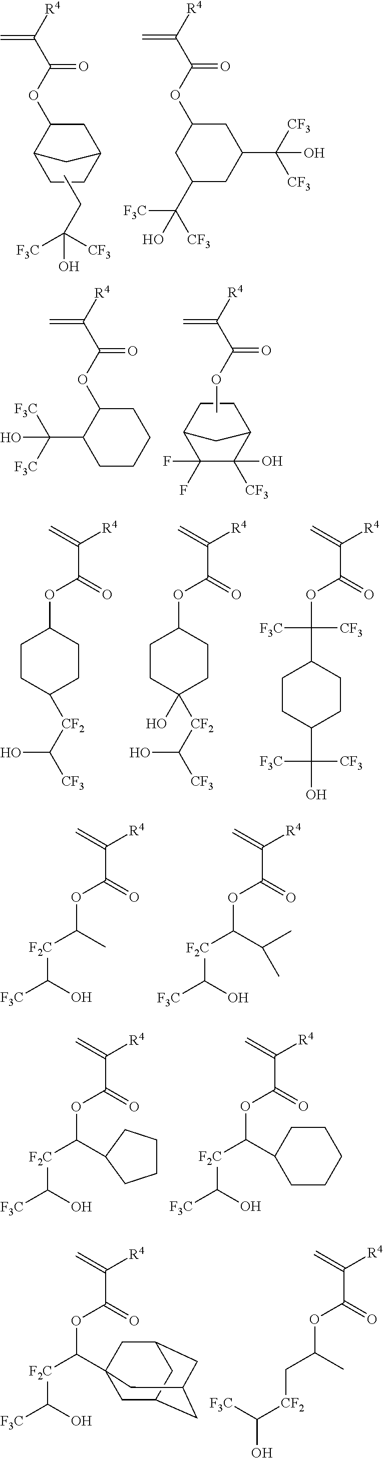

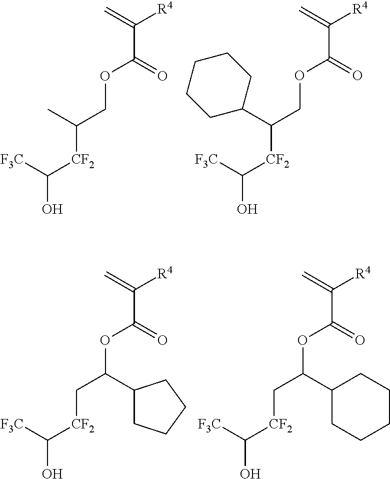

In the formulae, R⁴ represents the same meaning as before.

Specific example of the monomer to give the repeating unit (b-2) shown in the above general formula (2) includes the following compounds.

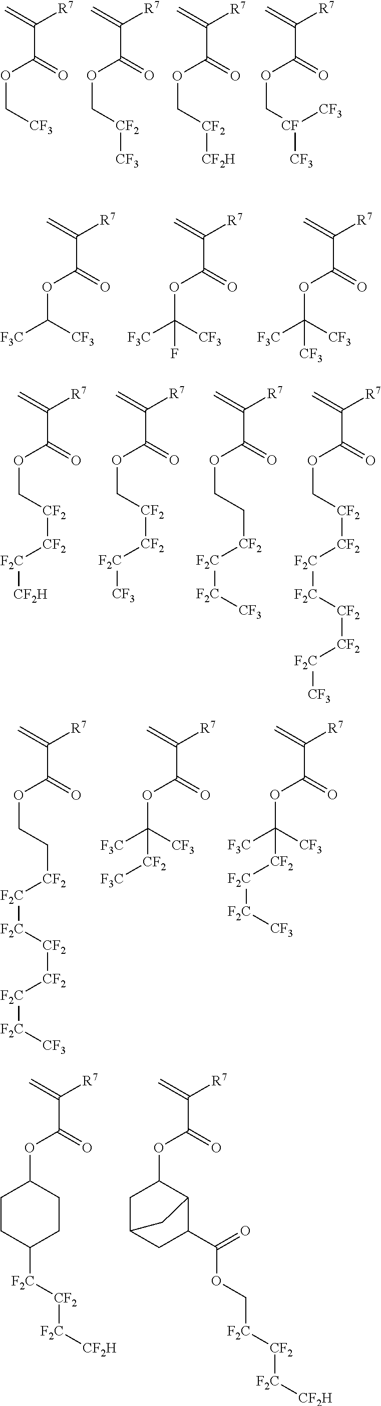

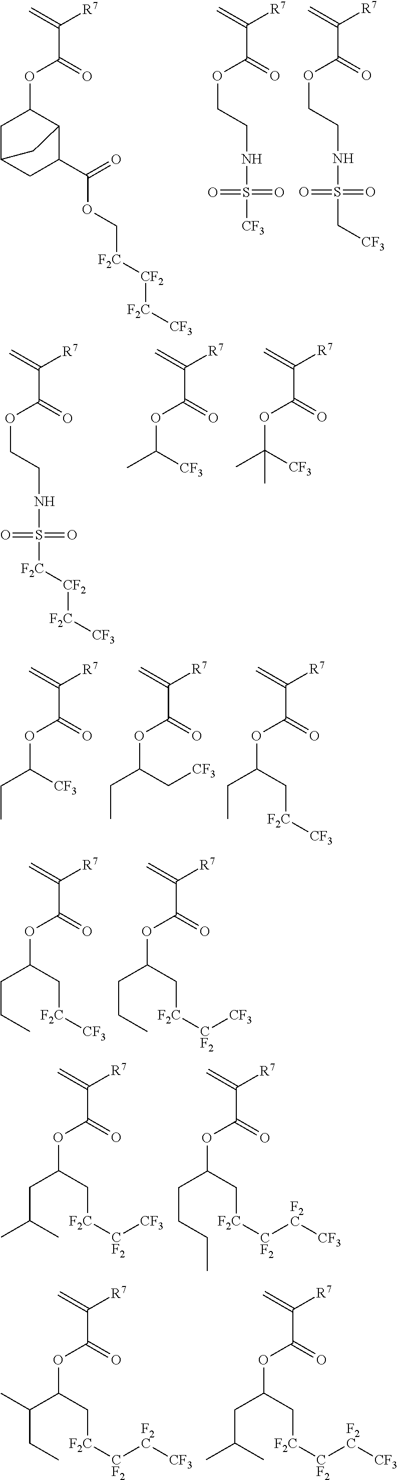

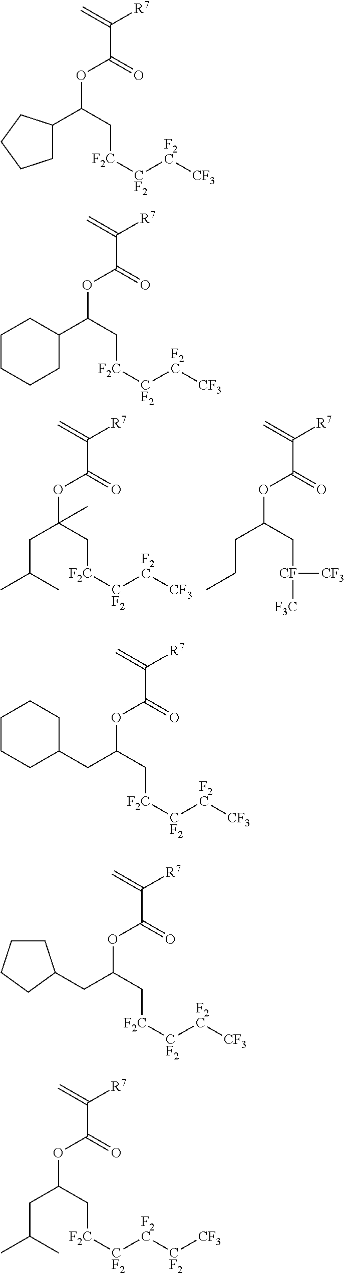

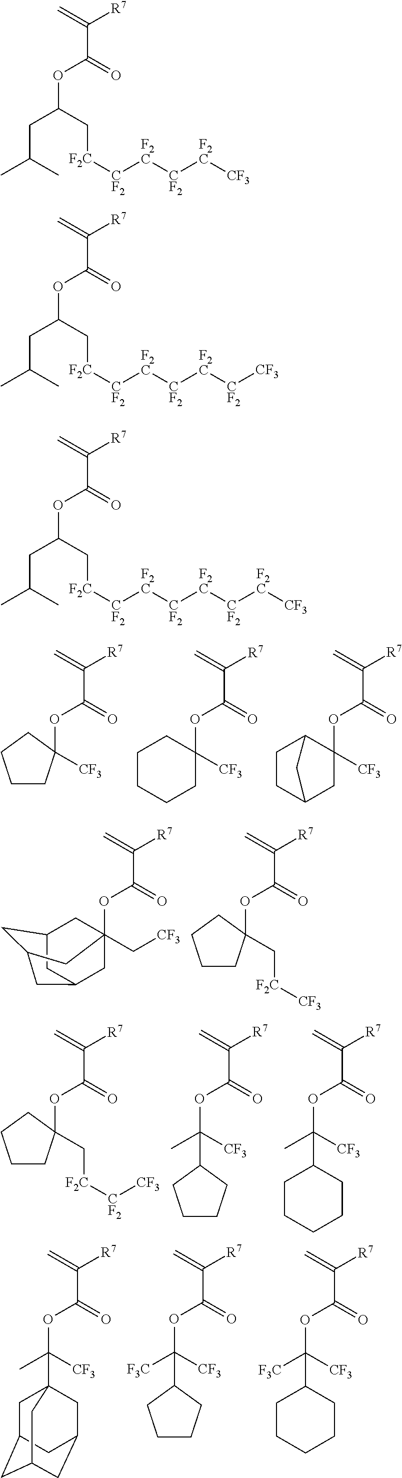

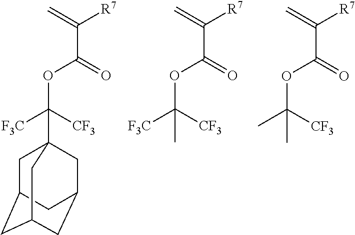

In the formulae, R⁷ represents the same meaning as before.

Specific example of the monomer to give the repeating unit (b-3) shown in the above general formula (2) includes the following compounds having a structure that the trifluoromethyl alcohol represented by the repeating unit (b-1) of the above general formula (2) is protected by an acid-labile group R¹². Here, various kinds of the acid-labile group R¹² can be used; specifically, a group similar to the acid-labile group R⁰¹⁰ in the afore-mentioned polymer (A) of the base polymer can be mentioned; though, an alkoxymethyl group shown as the specific example (L1) of R⁰¹⁰ is particularly preferable.

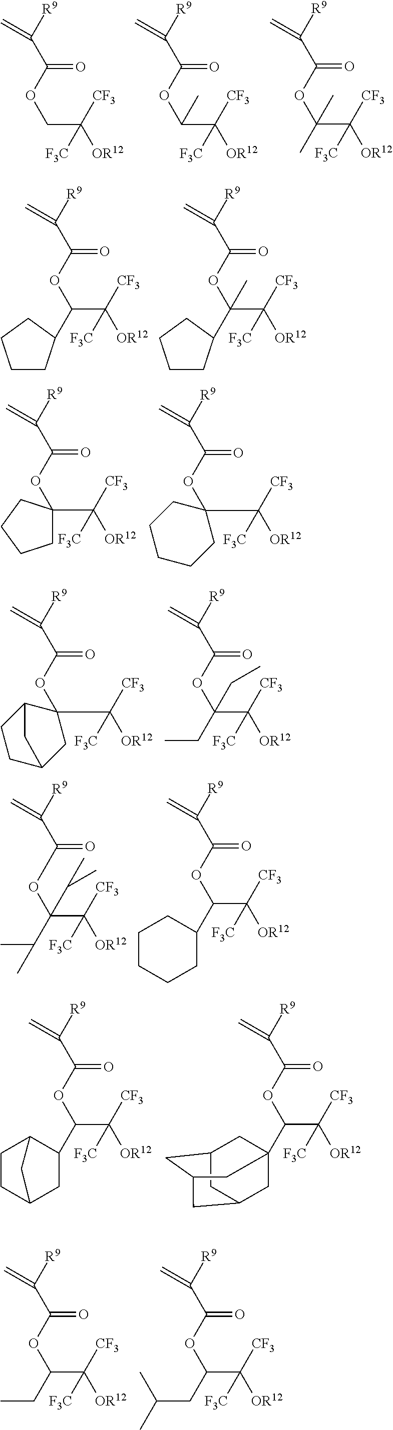

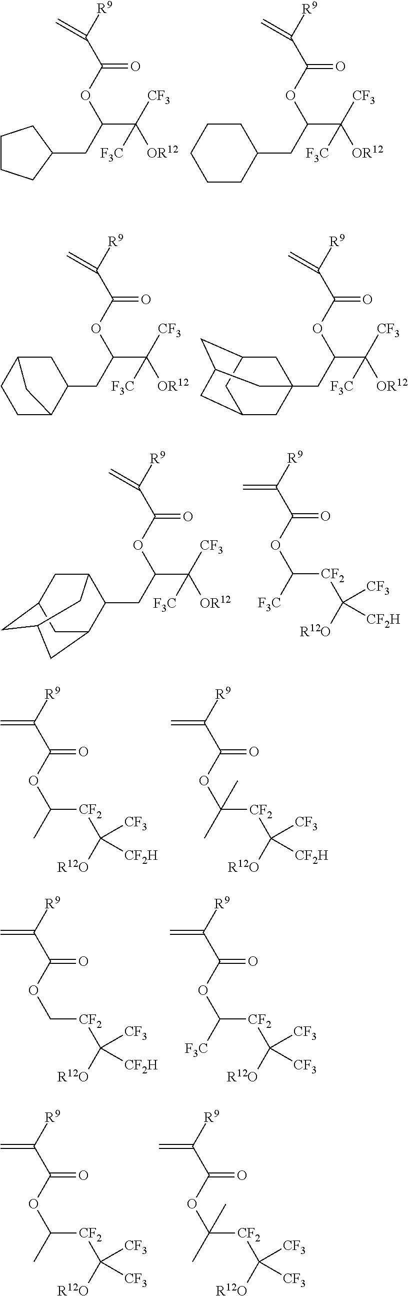

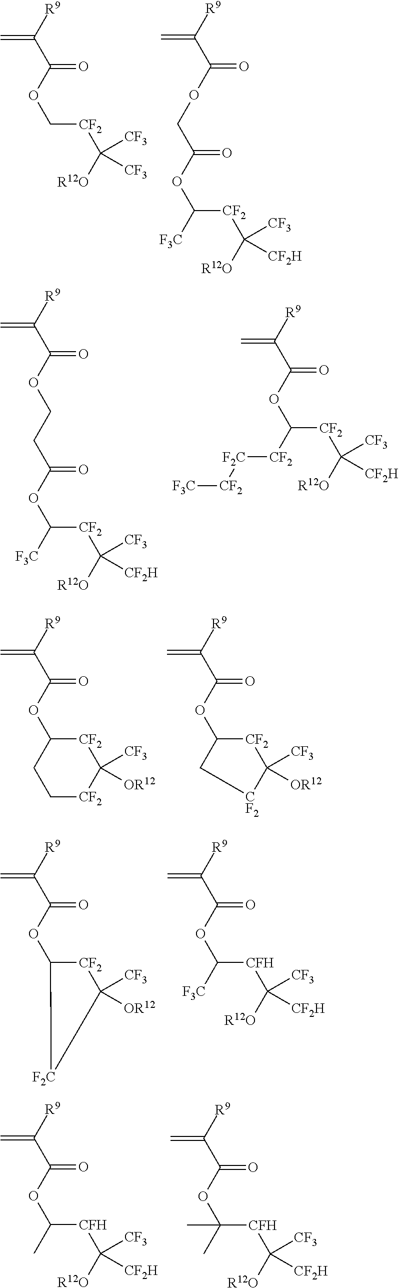

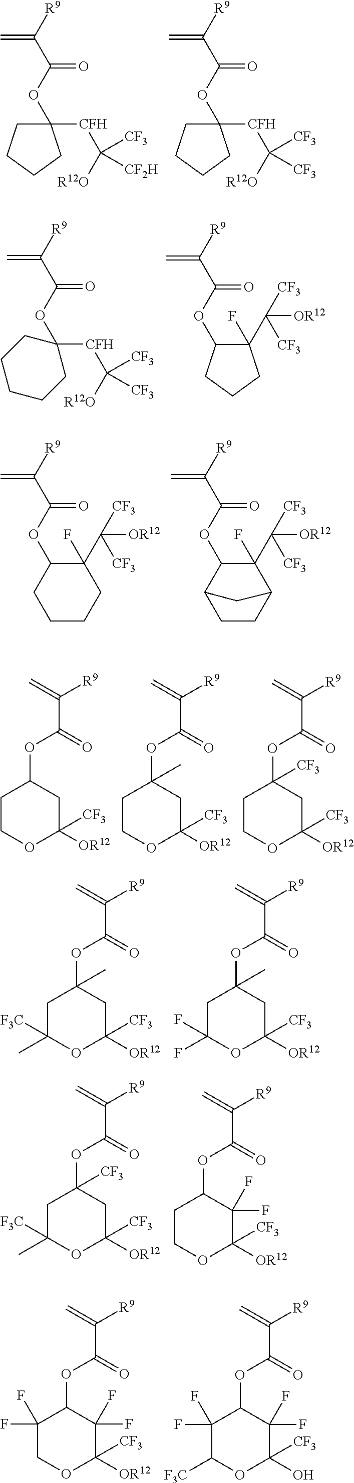

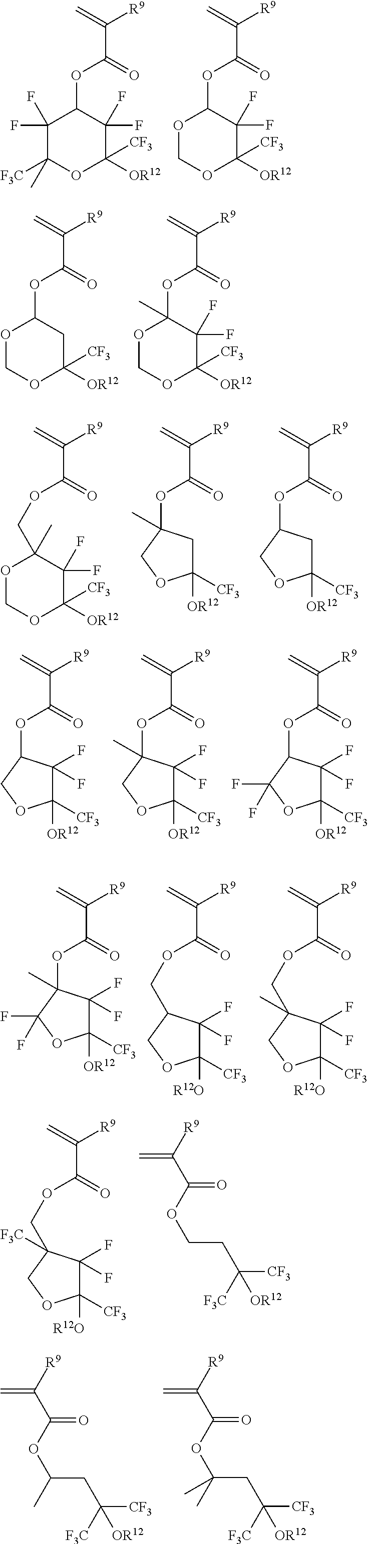

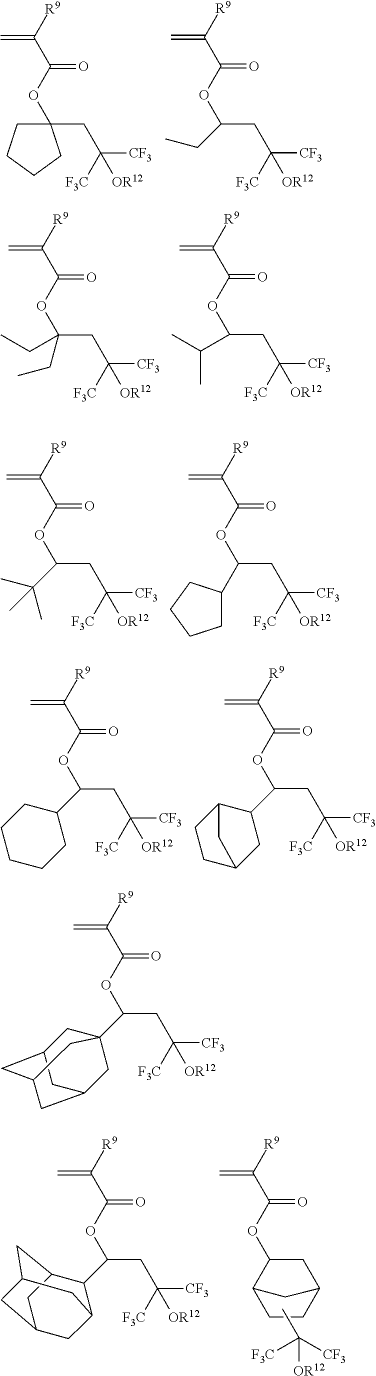

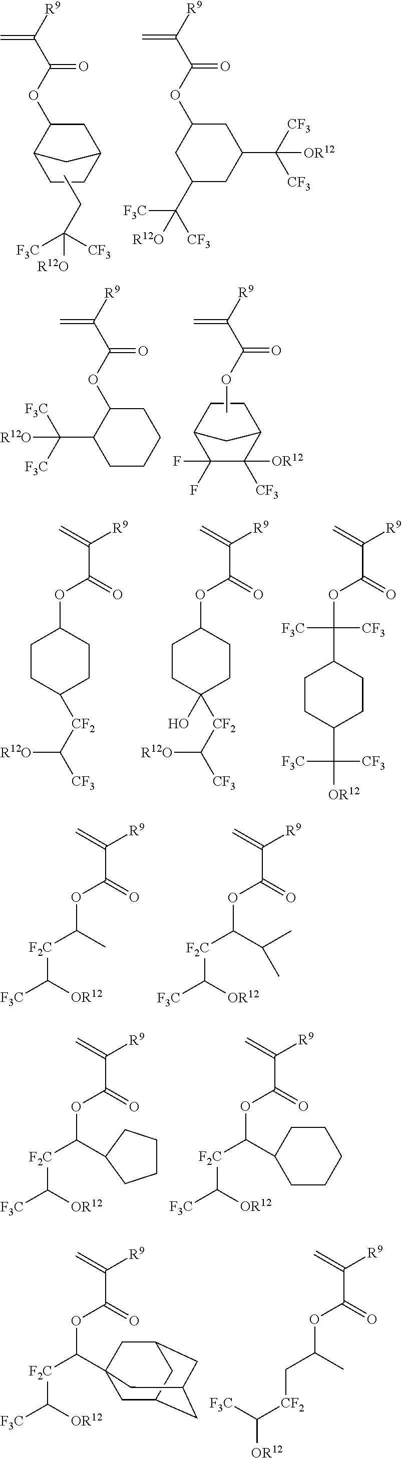

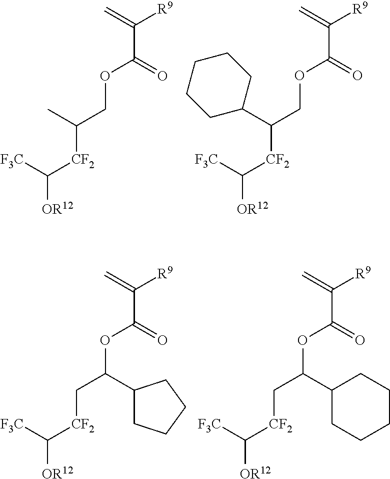

In the formulae, R⁹ represents the same meaning as before.

The polymer additive (C) contained in the resist composition of the present invention comprises the repeating unit shown by “a” in the above general formula (2), the essential component therein, and any one or more of the repeating units represented by (b-1), (b-2), and (b-3); and in addition, a repeating unit “c” having a carboxyl group may be copolymerized with an aim to control an alkaline-solubility, wherein specific examples of the repeating unit “c” may be shown below.

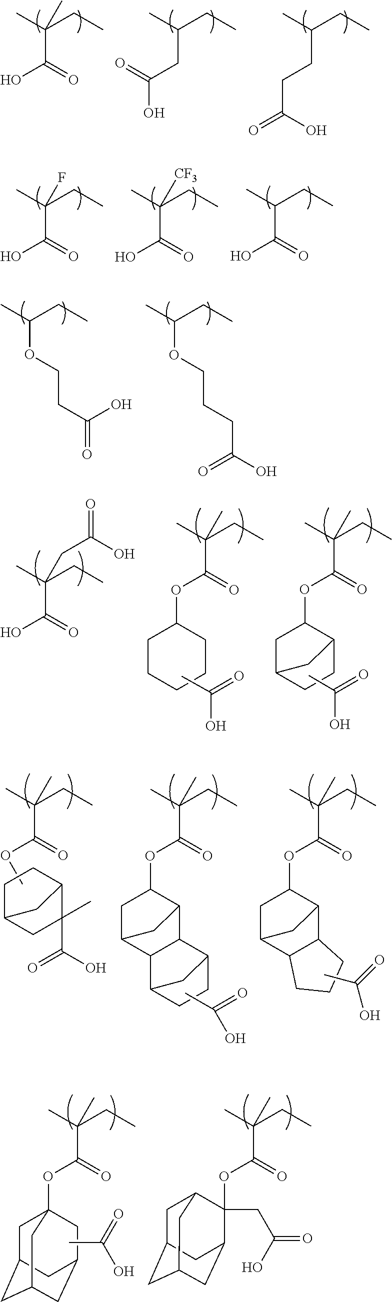

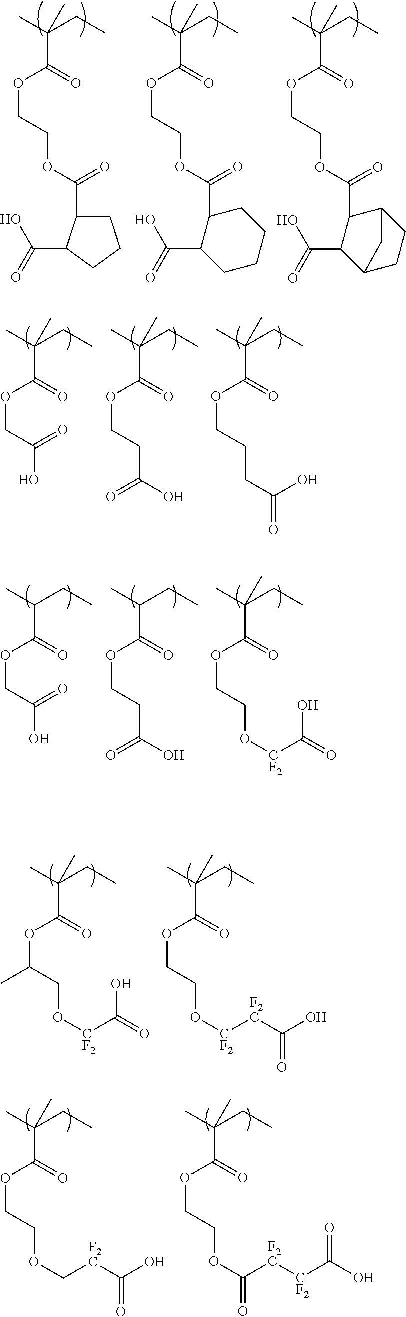

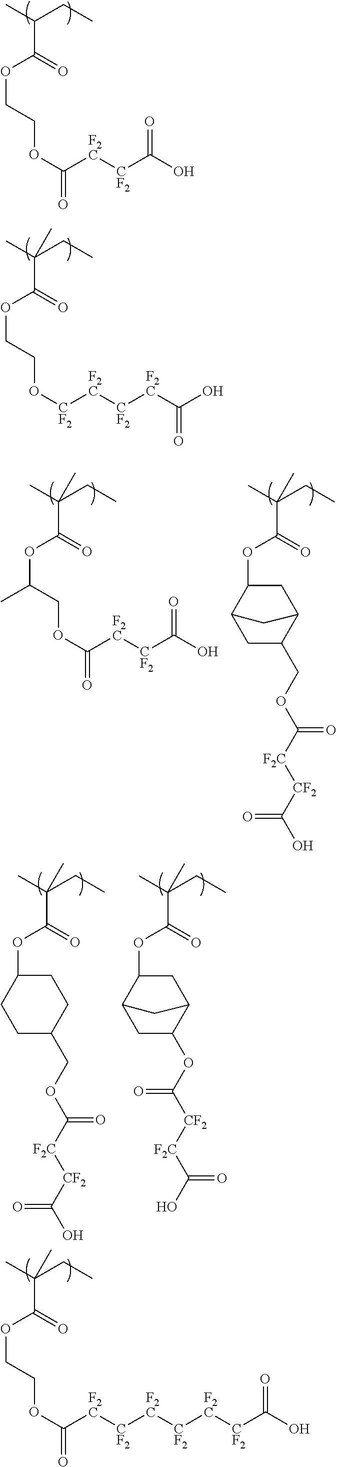

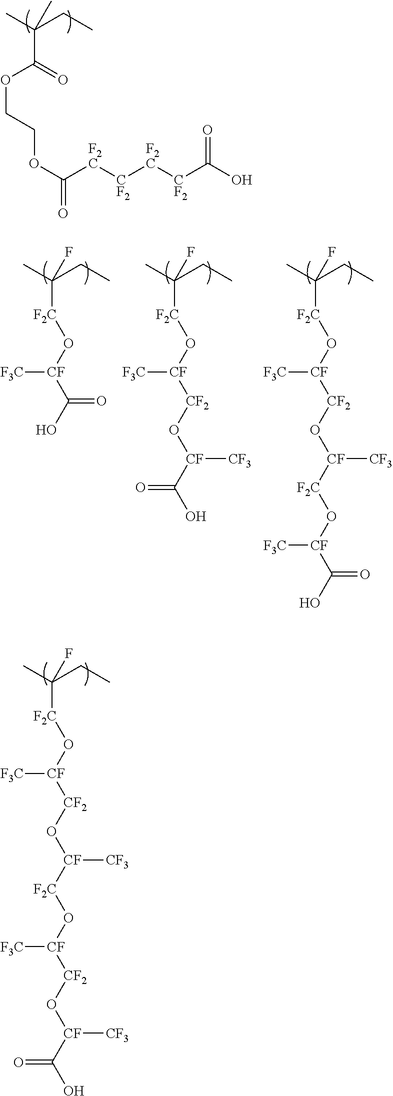

In addition, to improve a compatibility with the resist base polymer and to suppress a film loss of the resist surface, the polymer additive (C) may be copolymerized with a repeating unit “d” having a lactone adhesive group and a repeating unit “e” having an acid-labile group. Examples of the repeating unit “d” having a lactone adhesive group and the repeating unit “e” having an acid-labile group are similar to those used in the polymer (A) of the base resin; and specific examples thereof are those shown as examples of the repeating units of the composition ratios b1′ and d1′ in the above formula (R-1).

A polystyrene-equivalent weight-average molecular weight of the polymer additive (C) represented by the above general formula (2) and contained in the resist composition of the present invention, as measured by a gel permeation chromatography (GPC), is 1,000 to 100,000, or preferably 2,000 to 30,000, though not limited to them. If the molecular weight is 1,000 or more, a sufficient barrier performance to water during an immersion exposure can be expressed so that elution of the photoresist composition into water can be sufficiently suppressed. If the molecular weight is 100,000 or less, a dissolution rate of the polymer into an alkaline developer is sufficiently fast so that there is less chance of attaching a resin residue onto a substrate at the time when patterning is done by using a photoresist film containing this polymer.

The polymer additive (C) represented by the above general formula (2) may be added into a resist composition by blending, at an arbitrary ratio, two or more polymers copolymerized with different copolymer ratios, molecular weights, and kinds of the monomers therein.

The copolymer ratios of the repeating units “a”, (b-1), (b-2), and (b-3) in mole-equivalent in the above general formula (2) are 0<a<1.0, 0≦(b-1)<1.0, 0≦(b-2)<1.0, 0≦(b-3)<1.0, 0<(b-1)+(b-2)+(b-3)<1.0, and 0.5≦a+(b-1)+(b-2)+(b-3)1.0, or preferably 0<a<0.9, 0≦(b-2)<0.9, 0≦(b-1)+(b-2)≦0.9, 0.1<(b-3)<0.9, and 0.6≦a+(b-1)+(b-2)+(b-3)≦1.0.

When the foregoing repeating units “c”, “d”, and “e” are copolymerized with the repeating units represented by the above general formula (2), the ratios thereof can be made 0≦c≦0.5, in particular 0≦c≦0.4; in particular 0≦d≦0.4; and 0≦e≦0.5, in particular 0≦e≦0.4, wherein a+(b-1)+(b-2)+(b-3)+c+d+e=1.

Meanwhile, for example, the case of a+(b-1)+(b-2)+(b-3)=1 means that total of “a”, (b-1), (b-2), and (b-3) is 100% by mole relative to total of the entire repeating units in a polymer containing the repeating units “a”, (b-1), (b-2), and (b-3); and the case of a+(b-1)+(b-2)+(b-3)<1 means that total of “a”, (b-1), (b-2), and (b-3) is less than 100% by mole relative to total of the entire repeating units, and thereby suggesting that there is a repeating unit other than “a”, (b-1), (b-2), and (b-3).

The blending amount of the polymer additive (C) into the resist composition is 0.01 to 50 parts by mass, or preferably 0.1 to 10 parts by mass, relative to 100 parts by mass of the polymer (A) that becomes a base resin of the resist composition. If the blending amount is 0.01 or more parts by mass, a receding contact angle of water with the photoresist film surface is sufficiently high. While, if the blending amount is 50 or less parts by mass, dissolution rate of the photoresist film into an alkaline developer is so slow that height of the formed fine pattern may be secured sufficiently.

It is preferable that the resist composition of the present invention further contains any one or more of an organic solvent, a basic compound, a crosslinking agent, and a surfactant.

In the present invention, any organic solvent may be used, provided that a base resin, an acid generator, other additives, and so on can be dissolved thereinto. Example of the organic solvent-includes ketones such as cyclohexanone and methyl-2-n-amyl ketone; alcohols such as 3-methoxy butanol, 3-methyl-3-methoxy butanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl piruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone; and these can be used singly or as a mixture of two or more of them, though not limited to them. In the present invention, from a viewpoint of excellent solubility of an acid generator of the resist components, among these organic solvents, diethylene glycol dimethyl ether, 1-ethoxy-2-propanol, propylene glycol monomethyl ether acetate, and a mixture of them are preferably used.

The amount of the organic solvent to be used is preferably 200 to 3,000 parts by mass, or in particular 400 to 2,500 parts by mass, relative to 100 parts by mass of the polymer (A) that becomes a base resin in the resist composition.

In addition, into the resist composition of the present invention may be added one, or two or more nitrogen-containing organic compounds as a basic compound. As to the nitrogen-containing organic compound, a compound being capable of suppressing a diffusion rate of an acid generated from an acid generator into a resist film is suitable. By blending the nitrogen-containing organic compound, a diffusion rate of the acid in a resist film is suppressed thereby improving resolution, suppressing sensitivity change after exposure, reducing dependency on a substrate and an environment, and improving exposure margin, pattern profile, and so on.

The basic compound useful as mentioned above includes primary, secondary, and tertiary aliphatic amines, mixed amines, aromatic amines, heterocyclic amines, nitrogen-containing compounds having a carboxyl group, nitrogen-containing compounds having a sulfonyl group, nitrogen-containing compounds having a hydroxyl group, nitrogen-containing compounds having a hydroxyphenyl group, alcoholic nitrogen-containing compounds, amides, imides, carbamates, ammonium salts, and the like. Specifically, those nitrogen-containing organic compounds described in Japanese Patent Laid-Open Publication No. 2009-269953 can be mentioned as the examples of it.

Meanwhile, the afore-mentioned basic compounds may be used singly or as a mixture of two or more kinds of them. Blending amount of the basic compound is preferably 0.001 to 8 parts by mass, or in particular 0.01 to 5 parts by mass, relative to 100 parts by mass of the base resin. If the blending amount is 0.001 or more parts by mass, a blending effect can be obtained easily; and if it is 8 or less parts by mass, an appropriate sensitivity can be secured.

Into the resist composition of the present invention may be added a usually used surfactant to improve coating properties; and for it, reference can be made to the defined component (E) in Japanese Patent Laid-Open Publication No. 2009-269953. Reference can also be made to Japanese Patent Laid-Open Publication Nos. 2008-122932, 2010-134012, 2010-107695, 2009-276363, 2009-192784, 2009-191151, and 2009-98638; and a usual surfactant as well as an alkaline-soluble surfactant can be used. As to the amount of the surfactant to be added, the range of the amount not adversely affecting effects of the present invention can be taken as the usual amount.

In addition to the foregoing, a polymer-type surfactant described in Japanese Patent Laid-Open Publication No. 2007-297590 may be added thereinto; and the adding amount thereof is 0.001 to 20 parts by mass, or preferably 0.01 to 10 parts by mass, relative to 100 parts by mass of the base resin in the resist composition.

Into the resist composition of the present invention may be added, as appropriate, a crosslinking agent usually used for application to a negative-type resist and so on. A crosslinking agent containing in its molecular structure two or more hydroxymethyl groups, alkoxymethyl groups, epoxy groups, or vinyl ether groups may be used, while a substituted glycol uril derivative, a urea derivative, hexamethoxymethyl melamine, and so on may be used preferably.

Illustrative examples thereof include N,N,N′,N′-tetramethoxymethyl urea and hexamethyl melamine, tetrahydroxymethyl-substituted glycol urils and tetraalkoxymethyl-substituted glycol urils such as tetramethoxymethyl glycol uril, substituted or unsubstituted bishydroxymethyl phenols, and a condensation product of a phenolic compound such as bisphenol A and epichlorohydrin or the like.

Example of the especially preferable crosslinking agent includes a 1,3,4,6-tetraalkoxymethyl glycol uril such as 1,3,4,6-tetramethoxymethyl glycol uril or 1,3,4,6-tetrahydroxymethyl glycol uril, 2,6-dihydroxymethyl p-cresol, 2,6-dihydroxymethyl phenol, 2,2′,6,6′-tetrahydroxymethyl bisphenol A, 1,4-bis-[2-(2-hydroxypropyl)]-benzene, N,N,N′,N′-tetramethoxymethyl urea, and hexamethoxymethyl melamine. Amount of the agent to be added is arbitrary, though preferably 1 to 25 parts by mass, or more preferably 5 to 20 parts by mass, relative to 100 parts by mass of the base resin in the resist composition. These may be used singly or as a mixture of two or more kinds of them.

In the present invention, provided is a patterning process onto a substrate by using the afore-mentioned resist composition of the present invention, wherein the process includes at least a step of forming a resist film by applying the resist composition of the present invention onto a substrate, a step of exposing to a high energy beam after heat treatment, a step of developing by using a developer, and the like.

In addition to these steps, development may be carried out after the post-exposure heat treatment; and it is obvious that various other steps including a step of etching, a step of resist removal, and a step of rinsing may be carried out.

Specifically, patterning is carried out according to the procedure described below, though patterning of the present invention is not limited to this.

Patterning by using the resist composition of the present invention may be effected by use of a heretofore known lithography technology; for example, application thereof onto a substrate for manufacturing of an integrated circuit (such as Si, SiO₂, SiN, SiON, TiN, WSi, BPSG, SOG, and an organic antireflective film) or a substrate for manufacturing of a mask circuit (such as Cr, CrO, CrON, and MoSi) is done by such a method as spin coating so as to give a film thickness of 0.05 to 2.0 μm, and then this is followed by pre-baking on a hot plate at 60 to 150° C. for 1 to 10 minutes, or preferably at 80 to 140° C. for 1 to 5 minutes.

Thereafter, a mask to form an intended pattern is held over the resist film and then exposed to a high energy beam such as a far ultraviolet beam, an excimer laser, an X-ray, and an electron beam with an exposure dose of 1 to 200 mJ/cm², or preferably 10 to 100 mJ/cm². Alternatively, an electron beam is irradiated without intervention of a patterning mask for direct drawing.

The step of exposing to a high energy beam may be effected not only by a usual exposure method but also, especially in the present invention, by an immersion exposure wherein the exposure is done through a liquid such as water that is inserted between a projection lens and the substrate formed with the resist film (immersion method). In this case, it is also possible to use, for example, a top coat that is not soluble in water.

Then, a post-exposure bake (PEB) is done on a hot plate at 60 to 150° C. for 1 to 5 minutes, or preferably 80 to 140° C. for 1 to 3 minutes. Thereafter, development is done by using a developer of an aqueous solution of an alkaline material such as tetramethyl ammonium hydroxide (TMAH) with its concentration of 0.1 to 5% by mass or preferably 2 to 3% by mass, for 0.1 to 3 minutes or preferably 0.5 to 2 minutes, by a conventional method such as a dip method, a puddle method, and a spray method to form an intended pattern onto a substrate.

Meanwhile, the resist composition of the present invention is the most suitably used for fine patterning, especially by a high energy beam having the wavelength of −180 to 250 nm, such as a far ultraviolet beam, an excimer laser, an X-ray, and an electron beam. When a high energy beam with the foregoing wavelength range is used in the step of exposure, an intended pattern can be obtained.

The top coats not soluble in water as mentioned above used to prevent elution of the resist film from occurring and to improve water-sliding properties of the film surface can be classified roughly into two types. One is a type that the top coat needs to be removed prior to the alkaline development by an organic solvent not dissolving the resist film (organic-solvent-removal type), and the other is a type that the top coat soluble into an alkaline developer is removed simultaneously with removal of a soluble part of the resist film to an alkaline developer (alkaline-soluble type).

In the latter type, preferably used is a material obtained by dissolving, as a base, a polymer, having a 1,1,1,3,3,3-hexafluoro-2-propanol residue and especially being not soluble in water but soluble in an alkaline developer, into an alcohol solvent having 4 or more carbon atoms, an ether solvent having 8 to 12 carbon atoms, or a mixed solvent of them.

Alternatively, a material obtained by dissolving the surfactant, not soluble in water but soluble in an alkaline developer, into an alcohol solvent having 4 or more carbon atoms, an ether solvent having 8 to 12 carbon atoms, or a mixed solvent of them may be used.

As a measure for patterning, formation of a photoresist film may be followed with rinsing by pure water (post-soak) to extract the acid generator and so on from film surface, or with washing to wash out particles, or with rinsing (post-soak) to remove water remained on the film after exposure.

As mentioned above, a photoresist film formed by using the resist composition of the present invention is difficult to form a mixing layer with a top coat and has high hydrophilicity after development; and thus, there is no defect due to a residue, called a blob, and so on.

In a resist composition for mask blanks, resins based on novolak and hydroxystyrene are mainly used. Those having the hydroxyl group in these resins substituted with an acid-labile group are used as a positive type and those added with a crosslinking agent are used as a negative type. A polymer obtained by copolymerizing hydroxystyrene with a (meth)acryl derivative, styrene, vinyl naphthalene, vinyl anthracene, vinyl pyrene, hydroxyvinyl naphthalene, hydroxyvinyl anthracene, indene, hydroxyindene, acenaphthylene, or a norbornadiene may be used as the base.

When the photoresist composition of the present invention is used as the resist film for mask blanks, this composition is applied onto a mask blanks substrate such as SiO₂, Cr, CrO, CrN, and MoSi to form a resist film. Alternatively, an SOG film and an organic underlayer film may be formed between the photoresist and the blanks substrate to form a three-layered structure. After the resist film is formed, exposure is done with an electron beam drawing instrument. After the exposure, post-exposure bake (PEB) is carried out and then development is done with an alkaline developer for 10 to 300 seconds.

### EXAMPLES

Although Synthetic examples, Examples, and Comparative examples will be shown and the present invention will be explained in detail hereafter, the present invention is not restricted to the following Examples.

### Preparation of Polymers

Polymers (polymer additives) to be added into the resist composition were prepared as following; each monomer was combined and they were copolymerized in isopropy alcohol, and then crystals were separated out in hexane, repeatedly washed with hexane, isolated, and dried to obtain polymer additives PA-1 to PA-50 (Synthesis Examples 1 to 50) having respective compositions shown in Table 1-1 to Table 1-4. Structural formulae of respective repeating units (A1 to A9, B1 to B25, and C1 to C9) that constitute the polymer additives shown in Table 1-1 to Table 1-4 are shown in Table 2-1 to Table 2-5. Composition of each polymer was confirmed by ¹H-NMR, and molecular weight and dispersity thereof were confirmed by a gel permeation chromatography. Meanwhile, PA-1 to PA-46 in Table 1-1 to Table 1-4 are the polymer additives used in the present invention and PA-47 to PA-50 are the polymer additives synthesized as Comparative Examples.

TABLE 1-1

| | Unit 1 | | Unit 2 | | Unit 3 | | Unit 4 | | Unit 5 | | | |
|---|---|---|---|---|---|---|---|---|---|---|---|---|
| Polymer | | composition | | composition | | composition | | composition | | composition | Molecular | |
| additive | | ratio | | ratio | | ratio | | ratio | | ratio | weight | Despersity |

| | | | | | | | | | |
|---|---|---|---|---|---|---|---|---|---|
| Synthesis | PA-1 | A1 | 10 | B2 | 90 | | | 7900 | 1.75 |
| Example 1 | | | | | | | | | |
| Synthesis | PA-2 | A1 | 20 | B2 | 80 | | | 7200 | 1.70 |
| Example 2 | | | | | | | | | |
| Synthesis | PA-3 | A1 | 10 | B2 | 70 | B13 | 20 | 6900 | 1.72 |
| Example 3 | | | | | | | | | |
| Synthesis | PA-4 | A2 | 10 | B2 | 70 | B13 | 20 | 8000 | 1.81 |
| Example 4 | | | | | | | | | |
| Synthesis | PA-5 | A3 | 10 | B2 | 70 | B13 | 20 | 7700 | 1.75 |
| Example 5 | | | | | | | | | |
| Synthesis | PA-6 | A4 | 10 | B2 | 70 | B13 | 20 | 8400 | 1.82 |
| Example 6 | | | | | | | | | |
| Synthesis | PA-7 | A5 | 10 | B2 | 70 | B13 | 20 | 8100 | 1.80 |
| Example 7 | | | | | | | | | |
| Synthesis | PA-8 | A6 | 10 | B2 | 70 | B13 | 20 | 8500 | 1.89 |
| Example 8 | | | | | | | | | |
| Synthesis | PA-9 | A7 | 10 | B2 | 70 | B13 | 20 | 7500 | 1.73 |
| Example 9 | | | | | | | | | |
| Synthesis | PA-10 | A8 | 10 | B2 | 70 | B13 | 20 | 7200 | 1.70 |
| Example | | | | | | | | | |
| 10 | | | | | | | | | |
| Synthesis | PA-11 | A9 | 10 | B2 | 70 | B13 | 20 | 6800 | 1.69 |
| Example | | | | | | | | | |
| 11 | | | | | | | | | |

TABLE 1-2

| | Unit 1 | | Unit 2 | | Unit 3 | | Unit 4 | | Unit 5 | | | |
|---|---|---|---|---|---|---|---|---|---|---|---|---|
| Polymer | | composition | | composition | | composition | | composition | | composition | Molecular | |
| additive | | ratio | | ratio | | ratio | | ratio | | ratio | weight | Despersity |

| | | | | | | | | | |
|---|---|---|---|---|---|---|---|---|---|
| Synthesis | PA-12 | A1 | 10 | B1 | 70 | B13 | 20 | 7800 | 1.78 |
| Example | | | | | | | | | |
| 12 | | | | | | | | | |
| Synthesis | PA-13 | A1 | 10 | B3 | 70 | B13 | 20 | 7000 | 1.68 |
| Example | | | | | | | | | |
| 13 | | | | | | | | | |
| Synthesis | PA-14 | A1 | 10 | B4 | 70 | B13 | 20 | 6900 | 1.69 |
| Example | | | | | | | | | |
| 14 | | | | | | | | | |
| Synthesis | PA-15 | A1 | 10 | B5 | 70 | B13 | 20 | 7100 | 1.80 |
| Example | | | | | | | | | |
| 15 | | | | | | | | | |
| Synthesis | PA-16 | A1 | 10 | B6 | 70 | B13 | 20 | 6800 | 1.67 |
| Example | | | | | | | | | |
| 16 | | | | | | | | | |
| Synthesis | PA-17 | A1 | 10 | B7 | 70 | B13 | 20 | 6500 | 1.73 |
| Example | | | | | | | | | |
| 17 | | | | | | | | | |
| Synthesis | PA-18 | A1 | 10 | B8 | 70 | B13 | 20 | 7400 | 1.85 |
| Example | | | | | | | | | |
| 18 | | | | | | | | | |
| Synthesis | PA-19 | A1 | 10 | B9 | 70 | B13 | 20 | 7300 | 1.84 |
| Example | | | | | | | | | |
| 19 | | | | | | | | | |
| Synthesis | PA-20 | A1 | 10 | B2 | 70 | B11 | 20 | 8800 | 1.85 |
| Example | | | | | | | | | |
| 20 | | | | | | | | | |
| Synthesis | PA-21 | A1 | 10 | B2 | 70 | B12 | 20 | 8900 | 1.86 |
| Example | | | | | | | | | |
| 21 | | | | | | | | | |
| Synthesis | PA-22 | A1 | 10 | B2 | 70 | B14 | 20 | 8700 | 1.79 |
| Example | | | | | | | | | |
| 22 | | | | | | | | | |
| Synthesis | PA-23 | A1 | 10 | B2 | 70 | B15 | 20 | 7200 | 1.76 |
| Example | | | | | | | | | |
| 23 | | | | | | | | | |
| Synthesis | PA-24 | A1 | 10 | B2 | 70 | B16 | 20 | 6900 | 1.79 |
| Example | | | | | | | | | |
| 24 | | | | | | | | | |
| Synthesis | PA-25 | A1 | 10 | B2 | 70 | B17 | 20 | 7000 | 1.77 |
| Example | | | | | | | | | |
| 25 | | | | | | | | | |

TABLE 1-3

| | Unit 1 | | Unit 2 | | Unit 3 | | Unit 4 | | Unit 5 | | | |
|---|---|---|---|---|---|---|---|---|---|---|---|---|
| | | compo- | | compo- | | compo- | | compo- | | compo- | | |
| Polymer | | sition | | sition | | sition | | sition | | sition | Molecular | |
| additive | | ratio | | ratio | | ratio | | ratio | | ratio | weight | Despersity |

| | | | | | | | | | |
|---|---|---|---|---|---|---|---|---|---|
| Synthesis | PA-26 | A4 | 10 | B2 | 60 | B18 | 30 | 8600 | 1.86 |
| Example | | | | | | | | | |
| 26 | | | | | | | | | |
| Synthesis | PA-27 | A4 | 10 | B2 | 60 | B19 | 30 | 6400 | 1.68 |
| Example | | | | | | | | | |
| 27 | | | | | | | | | |
| Synthesis | PA-28 | A4 | 10 | B2 | 60 | B20 | 30 | 8500 | 1.90 |
| Example | | | | | | | | | |
| 28 | | | | | | | | | |
| Synthesis | PA-29 | A4 | 10 | B2 | 60 | B21 | 30 | 9100 | 1.92 |
| Example | | | | | | | | | |
| 29 | | | | | | | | | |
| Synthesis | PA-30 | A4 | 10 | B2 | 60 | B22 | 30 | 7400 | 1.73 |
| Example | | | | | | | | | |
| 30 | | | | | | | | | |
| Synthesis | PA-31 | A4 | 10 | B2 | 60 | B23 | 30 | 8200 | 1.80 |
| Example | | | | | | | | | |
| 31 | | | | | | | | | |
| Synthesis | PA-32 | A4 | 10 | B2 | 60 | B24 | 30 | 8100 | 1.73 |
| Example | | | | | | | | | |
| 32 | | | | | | | | | |
| Synthesis | PA-33 | A4 | 10 | B2 | 60 | B25 | 30 | 8900 | 1.78 |
| Example | | | | | | | | | |
| 33 | | | | | | | | | |
| Synthesis | PA-34 | A2 | 20 | B19 | 80 | | | 6300 | 1.71 |
| Example | | | | | | | | | |
| 34 | | | | | | | | | |
| Synthesis | PA-35 | A2 | 20 | B24 | 80 | | | 6500 | 1.74 |
| Example | | | | | | | | | |
| 35 | | | | | | | | | |

TABLE 1-4

| | | Unit 1 | | Unit 2 | | Unit 3 | | Unit 4 | | Unit 5 | | | |
|---|---|---|---|---|---|---|---|---|---|---|---|---|---|
| | Polymer | | composition | | composition | | composition | | composition | | composition | Molecular | |
| | additive | | ratio | | ratio | | ratio | | ratio | | ratio | weight | Despersity |
| Synthesis | PA-36 | A1 | 10 | B13 | 85 | C1 | 5 | | | | | 8800 | 1.81 |
| Example 36 | | | | | | | | | | | | | |
| Synthesis | PA-37 | A1 | 10 | B15 | 85 | C2 | 5 | | | | | 8900 | 1.86 |
| Example 37 | | | | | | | | | | | | | |
| Synthesis | PA-38 | A1 | 10 | B6 | 50 | C3 | 40 | | | | | 7600 | 1.82 |
| Example 38 | | | | | | | | | | | | | |
| Synthesis | PA-39 | A1 | 10 | B2 | 50 | C4 | 40 | | | | | 8700 | 1.83 |
| Example 39 | | | | | | | | | | | | | |
| Synthesis | PA-40 | A1 | 10 | B2 | 50 | C5 | 40 | | | | | 7900 | 1.80 |
| Example 40 | | | | | | | | | | | | | |
| Synthesis | PA-41 | A1 | 10 | B4 | 50 | C6 | 40 | | | | | 7900 | 1.78 |
| Example 41 | | | | | | | | | | | | | |
| Synthesis | PA-42 | A9 | 10 | B10 | 50 | C7 | 40 | | | | | 6800 | 1.79 |
| Example 42 | | | | | | | | | | | | | |
| Synthesis | PA-43 | A9 | 10 | B10 | 50 | C8 | 40 | | | | | 7100 | 1.81 |
| Example 43 | | | | | | | | | | | | | |
| Synthesis | PA-44 | A4 | 10 | B6 | 40 | B14 | 20 | B19 | 30 | | | 8000 | 1.92 |
| Example 44 | | | | | | | | | | | | | |
| Synthesis | PA-45 | A4 | 5 | B6 | 30 | B14 | 10 | B19 | 15 | C4 | 40 | 7800 | 1.90 |
| Example 45 | | | | | | | | | | | | | |
| Synthesis | PA-46 | A4 | 10 | B2 | 30 | B16 | 20 | C4 | 40 | | | 8300 | 1.87 |
| Example 46 | | | | | | | | | | | | | |
| Synthesis | PA-47 | B2 | 80 | B13 | 20 | | | | | | | 7200 | 1.79 |
| Example 47 | | | | | | | | | | | | | |
| Synthesis | PA-48 | B2 | 60 | B18 | 40 | | | | | | | 8300 | 1.85 |
| Example 48 | | | | | | | | | | | | | |
| Synthesis | PA-49 | B6 | 50 | B14 | 20 | B19 | 30 | | | | | 7900 | 1.89 |
| Example 49 | | | | | | | | | | | | | |
| Synthesis | PA-50 | B2 | 10 | C4 | 60 | C9 | 30 | | | | | 6900 | 1.73 |
| Example 50 | | | | | | | | | | | | | |

TABLE 2-1
A1

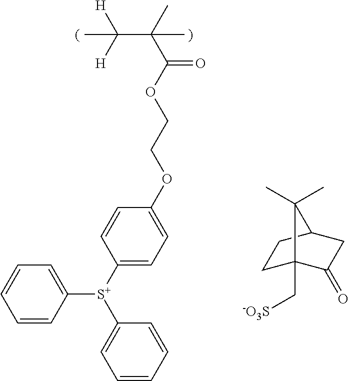

A2

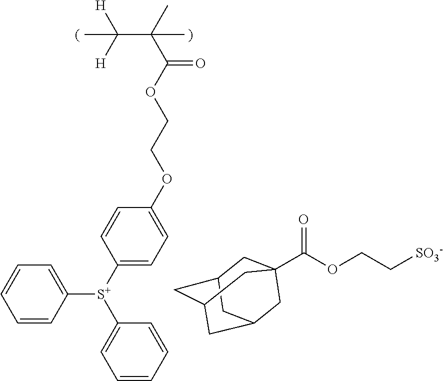

A3

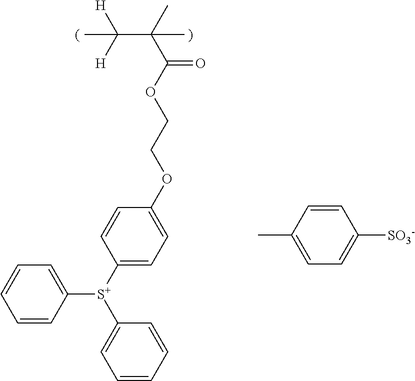

A4

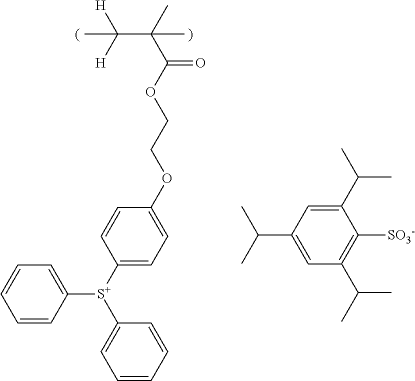

A5

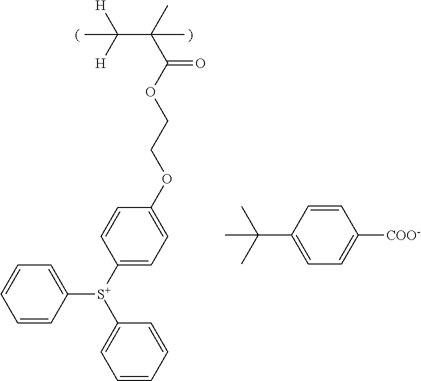

A6

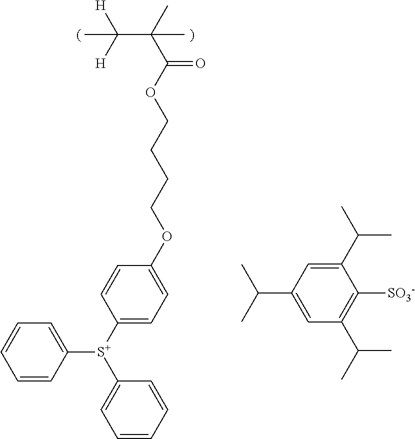

A7

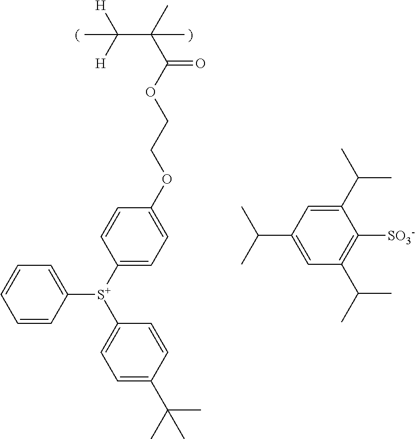

A8

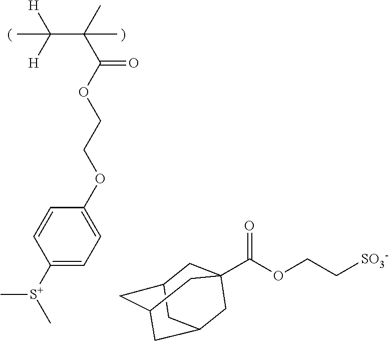

A9

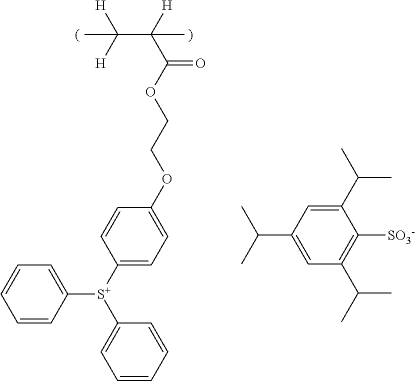

TABLE 2-2
B1

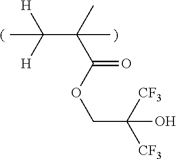

B2

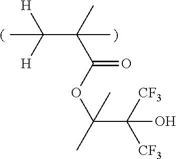

B3

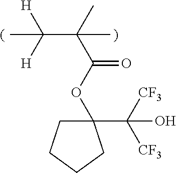

B4

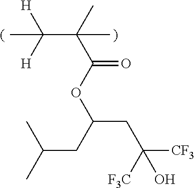

B5

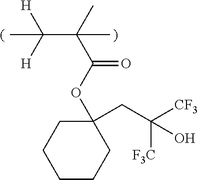

B6

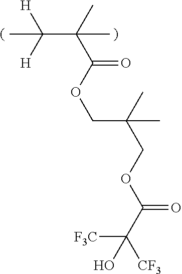

B7

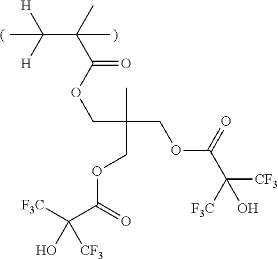

B8

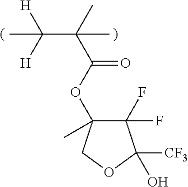

B9

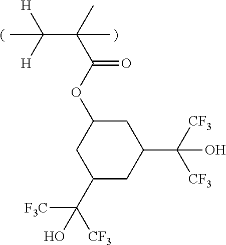

B10

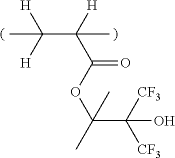

TABLE 2-3
B11

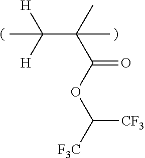

B12

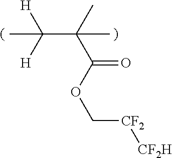

B13

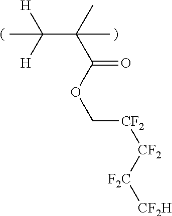

B14

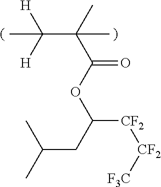

B15

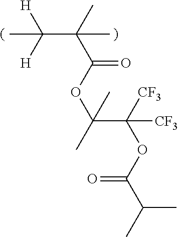

B16

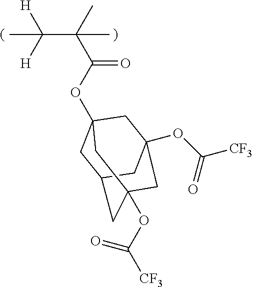

B17

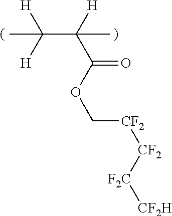

B18

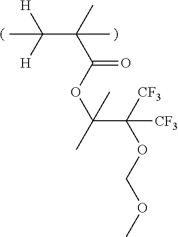

B19

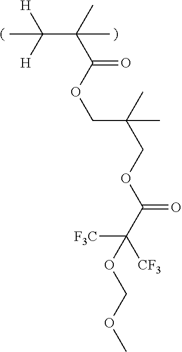

B20

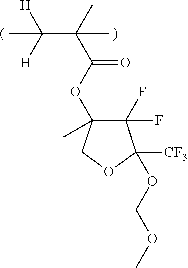

TABLE 2-4
B21

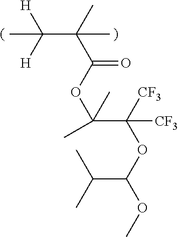

B22

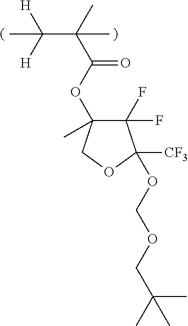

B23

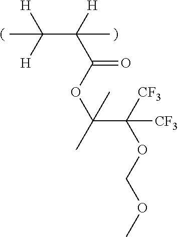

B24

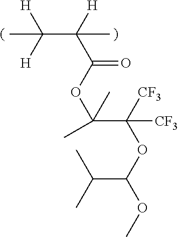

B25

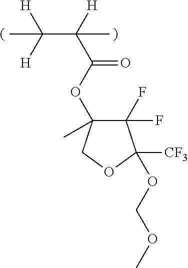

TABLE 2-5
C1

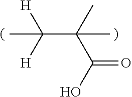

C2

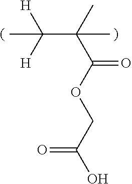

C3

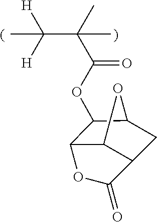

C4

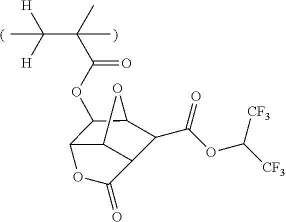

C5

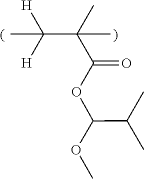

C6

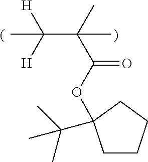

C7

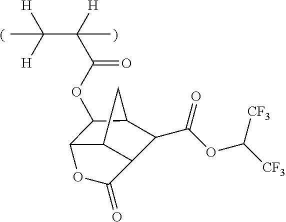

C8

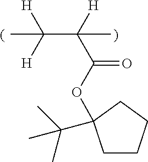

C9

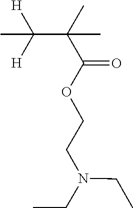

### Preparation of Resist Compositions

A base polymer, a photo acid generator, a quencher, a surfactant, and an organic solvent, in addition to the foregoing polymer additive, were mixed, and then the resulting mixture obtained after dissolution of them was filtered through a filter (pore diameter of 0.2 μm) made of Teflon (registered trade mark) to obtain respective resist compositions (PR-1 to PR-82). Positive-type resists of the present invention (PR-1 to PR-64) are shown in Table 3-1 to Table 3-3, positive-type resists for comparison (PR-65 to PR-70) are shown in Table 4, negative-type resists of the present invention (PR-71 to PR-77) are shown in Table 5, and negative-type resists for comparison (PR-78 to PR-82) are shown in Table 6. Composition, molecular weight, and dispersity of the base polymers in Table 3-1 to Table 6 (Polymer-1 to Polymer-17) are shown in Table 7, and structures of repeating units that constitute the base polymers are shown in Table 8-1 to Table 8-3. Structures of the photo acid generators are shown in Table 9 and structures of the quenchers are shown in Table 10.

Meanwhile, solvents shown in Table 3-1 to Table 6 are as following:

PGMEA: propylene glycol monomethyl ether acetate
GBL: γ-butyrolactone
EL: ethyl lactate

Further, surfactant A shown below (0.1 part by mass) was added into any of the resist compositions shown in Table 3-1 to Table 6.

Surfactant A: 3-methyl-3-(2,2,2-trifluoroethoxymethyl)oxetane/tetrahydrofurane/2,2-dimethyl-1,3-propanediol copolymer (manufactured by OMNOVA Solutions, Inc.) (see the following formula; in the formula, a, b, b′, c, and c′ satisfy the numbers shown below regardless of other descriptions).

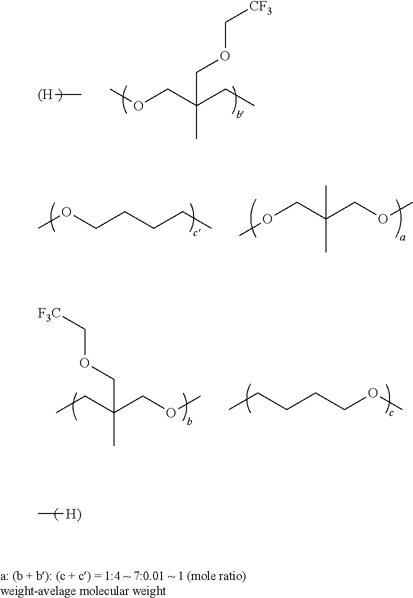

TABLE 3-1

| | | Polymer | Photo acid | | |
|---|---|---|---|---|---|
| | Base polymer | additive | generator | Quencher | Solvent |
| | (parts by | (parts by | (parts by | (parts by | (parts by |
| Resist | mass) | mass) | mass) | mass) | mass) |
| PR-1 | Polymer-4 (100) | PA-1 (5.0) | PAG-2 (12.7) | Q3 (1.6) | PGMEA(2700) |
| | | | | | GBL(300) |
| PR-2 | Polymer-4 (100) | PA-2 (5.0) | PAG-2 (12.7) | Q3 (1.6) | PGMEA(2700) |
| | | | | | GBL(300) |
| PR-3 | Polymer-4 (100) | PA-3 (5.0) | PAG-2 (12.7) | Q3 (1.6) | PGMEA(2700) |
| | | | | | GBL(300) |
| PR-4 | Polymer-4 (100) | PA-4 (5.0) | PAG-2 (12.7) | Q3 (1.6) | PGMEA(2700) |
| | | | | | GBL(300) |
| PR-5 | Polymer-4 (100) | PA-5 (5.0) | PAG-2 (12.7) | Q3 (1.6) | PGMEA(2700) |
| | | | | | GBL(300) |
| PR-6 | Polymer-4 (100) | PA-6 (5.0) | PAG-2 (12.7) | Q3 (1.6) | PGMEA(2700) |
| | | | | | GBL(300) |
| PR-7 | Polymer-4 (100) | PA-7 (5.0) | PAG-2 (12.7) | Q3 (1.6) | PGMEA(2700) |
| | | | | | GBL(300) |
| PR-8 | Polymer-4 (100) | PA-8 (5.0) | PAG-2 (12.7) | Q3 (1.6) | PGMEA(2700) |
| | | | | | GBL(300) |
| PR-9 | Polymer-4 (100) | PA-9 (5.0) | PAG-2 (12.7) | Q3 (1.6) | PGMEA(2700) |
| | | | | | GBL(300) |
| PR-10 | Polymer-4 (100) | PA-10 (5.0) | PAG-2 (12.7) | Q3 (1.6) | PGMEA(2700) |
| | | | | | GBL(300) |
| PR-11 | Polymer-4 (100) | PA-11 (5.0) | PAG-2 (12.7) | Q3 (1.6) | PGMEA(2700) |
| | | | | | GBL(300) |
| PR-12 | Polymer-4 (100) | PA-12 (5.0) | PAG-2 (12.7) | Q3 (1.6) | PGMEA(2700) |
| | | | | | GBL(300) |
| PR-13 | Polymer-4 (100) | PA-13 (5.0) | PAG-2 (12.7) | Q3 (1.6) | PGMEA(2700) |
| | | | | | GBL(300) |
| PR-14 | Polymer-4 (100) | PA-14 (5.0) | PAG-2 (12.7) | Q3 (1.6) | PGMEA(2700) |
| | | | | | GBL(300) |
| PR-15 | Polymer-4 (100) | PA-15 (5.0) | PAG-2 (12.7) | Q3 (1.6) | PGMEA(2700) |
| | | | | | GBL(300) |
| PR-16 | Polymer-4 (100) | PA-16 (5.0) | PAG-2 (12.7) | Q3 (1.6) | PGMEA(2700) |
| | | | | | GBL(300) |
| PR-17 | Polymer-4 (100) | PA-17 (5.0) | PAG-2 (12.7) | Q3 (1.6) | PGMEA(2700) |
| | | | | | GBL(300) |
| PR-18 | Polymer-4 (100) | PA-18 (5.0) | PAG-2 (12.7) | Q3 (1.6) | PGMEA(2700) |
| | | | | | GBL(300) |
| PR-19 | Polymer-4 (100) | PA-19 (5.0) | PAG-2 (12.7) | Q3 (1.6) | PGMEA(2700) |
| | | | | | GBL(300) |
| PR-20 | Polymer-4 (100) | PA-20 (5.0) | PAG-2 (12.7) | Q3 (1.6) | PGMEA(2700) |
| | | | | | GBL(300) |
| PR-21 | Polymer-4 (100) | PA-21 (5.0) | PAG-2 (12.7) | Q3 (1.6) | PGMEA(2700) |
| | | | | | GBL(300) |
| PR-22 | Polymer-4 (100) | PA-22 (5.0) | PAG-2 (12.7) | Q3 (1.6) | PGMEA(2700) |
| | | | | | GBL(300) |
| PR-23 | Polymer-4 (100) | PA-23 (5.0) | PAG-2 (12.7) | Q3 (1.6) | PGMEA(2700) |
| | | | | | GBL(300) |

TABLE 3-2

| | | Polymer | Photo acid | | |
|---|---|---|---|---|---|
| | Base polymer | additive | generator | Quencher | Solvent |
| | (parts by | (parts by | (parts by | (parts by | (parts by |
| Resist | mass) | mass) | mass) | mass) | mass) |
| PR-24 | Polymer-4 (100) | PA-24 (5.0) | PAG-2 (12.7) | Q4 (2.5) | PGMEA(2700) |
| | | | | | GBL(300) |
| PR-25 | Polymer-4 (100) | PA-25 (5.0) | PAG-2 (12.7) | Q3 (1.6) | PGMEA(2700) |
| | | | | | GBL(300) |
| PR-26 | Polymer-4 (100) | PA-26 (5.0) | PAG-2 (12.7) | Q3 (1.6) | PGMEA(2700) |
| | | | | | GBL(300) |
| PR-27 | Polymer-4 (100) | PA-27 (5.0) | PAG-2 (12.7) | Q3 (1.6) | PGMEA(2700) |
| | | | | | GBL(300) |
| PR-28 | Polymer-4 (100) | PA-28 (5.0) | PAG-2 (12.7) | Q3 (1.6) | PGMEA(2700) |
| | | | | | GBL(300) |
| PR-29 | Polymer-4 (100) | PA-29 (5.0) | PAG-2 (12.7) | Q2 (2.0) | PGMEA(2700) |
| | | | | | GBL(300) |
| PR-30 | Polymer-4 (100) | PA-30 (5.0) | PAG-2 (12.7) | Q3 (1.6) | PGMEA(2700) |
| | | | | | GBL(300) |
| PR-31 | Polymer-4 (100) | PA-31 (5.0) | PAG-2 (12.7) | Q3 (1.6) | PGMEA(2700) |
| | | | | | GBL(300) |
| PR-32 | Polymer-4 (100) | PA-32 (5.0) | PAG-2 (12.7) | Q2 (2.0) | PGMEA(2700) |
| | | | | | GBL(300) |
| PR-33 | Polymer-4 (100) | PA-33 (5.0) | PAG-2 (12.7) | Q3 (1.6) | PGMEA(2700) |
| | | | | | GBL(300) |
| PR-34 | Polymer-4 (100) | PA-34 (5.0) | PAG-2 (12.7) | Q3 (1.6) | PGMEA(2700) |
| | | | | | GBL(300) |
| PR-35 | Polymer-4 (100) | PA-35 (5.0) | PAG-2 (12.7) | Q2 (2.0) | PGMEA(2700) |
| | | | | | GBL(300) |
| PR-36 | Polymer-4 (100) | PA-36 (5.0) | PAG-2 (12.7) | Q3 (1.6) | PGMEA(2700) |
| | | | | | GBL(300) |
| PR-37 | Polymer-4 (100) | PA-37 (5.0) | PAG-2 (12.7) | Q3 (1.6) | PGMEA(2700) |
| | | | | | GBL(300) |
| PR-38 | Polymer-4 (100) | PA-38 (5.0) | PAG-2 (12.7) | Q3 (1.6) | PGMEA(2700) |
| | | | | | GBL(300) |
| PR-39 | Polymer-4 (100) | PA-39 (5.0) | PAG-2 (12.7) | Q3 (1.6) | PGMEA(2700) |
| | | | | | GBL(300) |
| PR-40 | Polymer-4 (100) | PA-40 (5.0) | PAG-2 (12.7) | Q2 (2.0) | PGMEA(2700) |
| | | | | | GBL(300) |
| PR-41 | Polymer-4 (100) | PA-41 (5.0) | PAG-2 (12.7) | Q3 (1.6) | PGMEA(2700) |
| | | | | | GBL(300) |
| PR-42 | Polymer-4 (100) | PA-42 (5.0) | PAG-2 (12.7) | Q3 (1.6) | PGMEA(2700) |
| | | | | | GBL(300) |
| PR-43 | Polymer-4 (100) | PA-43 (5.0) | PAG-2 (12.7) | Q3 (1.6) | PGMEA(2700) |
| | | | | | GBL(300) |
| PR-44 | Polymer-4 (100) | PA-44 (5.0) | PAG-2 (12.7) | Q3 (1.6) | PGMEA(2700) |
| | | | | | GBL(300) |
| PR-45 | Polymer-4 (100) | PA-45 (5.0) | PAG-2 (12.7) | Q3 (1.6) | PGMEA(2700) |
| | | | | | GBL(300) |
| PR-46 | Polymer-4 (100) | PA-46 (5.0) | PAG-2 (12.7) | Q4 (2.5) | PGMEA(2700) |
| | | | | | GBL(300) |

TABLE 3-3

| | | Polymer | Photo acid | | |
|---|---|---|---|---|---|
| | Base polymer | additive | generator | Quencher | Solvent |
| | (parts by | (parts by | (parts by | (parts by | (parts by |
| Resist | mass) | mass) | mass) | mass) | mass) |
| PR-47 | Polymer-1 (100) | PA-3 (5.0) | PAG-2 (12.7) | Q3 (1.6) | PGMEA(2700) |
| | | | | | GBL(300) |
| PR-48 | Polymer-2 (100) | PA-3 (5.0) | PAG-2 (12.7) | Q3 (1.6) | PGMEA(2700) |
| | | | | | GBL(300) |
| PR-49 | Polymer-3 (100) | PA-3 (5.0) | PAG-2 (12.7) | Q3 (1.6) | PGMEA(2700) |
| | | | | | GBL(300) |
| PR-50 | Polymer-5 (100) | PA-3 (5.0) | PAG-2 (12.7) | Q3 (1.6) | PGMEA(2700) |
| | | | | | GBL(300) |
| PR-51 | Polymer-6 (100) | PA-3 (5.0) | PAG-2 (12.7) | Q3 (1.6) | PGMEA(2700) |
| | | | | | GBL(300) |
| PR-52 | Polymer-7 (100) | PA-3 (5.0) | PAG-2 (12.7) | Q3 (1.6) | PGMEA(2700) |
| | | | | | GBL(300) |
| PR-53 | Polymer-8 (100) | PA-3 (5.0) | PAG-2 (12.7) | Q3 (1.6) | PGMEA(2700) |
| | | | | | GBL(300) |
| PR-54 | Polymer-9 (100) | PA-3 (5.0) | PAG-2 (12.7) | Q3 (1.6) | PGMEA(2700) |
| | | | | | GBL(300) |
| PR-55 | Polymer-10 (100) | PA-3 (5.0) | PAG-2 (12.7) | Q3 (1.6) | PGMEA(2700) |
| | | | | | GBL(300) |
| PR-56 | Polymer-11 (100) | PA-3 (5.0) | PAG-2 (12.7) | Q3 (1.6) | PGMEA(2700) |
| | | | | | GBL(300) |
| PR-57 | Polymer-12 (100) | PA-3 (5.0) | PAG-2 (12.7) | Q3 (1.6) | PGMEA(2700) |
| | | | | | GBL(300) |
| PR-58 | Polymer-4 (100) | PA-3 (5.0) | PAG-1 (10.9) | Q1 (2.4) | PGMEA(2700) |
| | | | | | GBL(300) |
| PR-59 | Polymer-4 (100) | PA-3 (5.0) | PAG-3 (13.0) | Q3 (1.6) | PGMEA(2700) |
| | | | | | GBL(300) |
| PR-60 | Polymer-4 (100) | PA-3 (5.0) | PAG-4 (17.0) | Q3 (1.6) | PGMEA(2700) |
| | | | | | GBL(300) |
| PR-61 | Polymer-4 (100) | PA-3 (5.0) | PAG-5 (13.8) | Q3 (1.6) | PGMEA(2700) |
| | | | | | GBL(300) |
| PR-62 | Polymer-4 (100) | PA-3 (5.0) | PAG-6 (14.1) | Q3 (1.6) | PGMEA(2700) |
| | | | | | GBL(300) |
| PR-63 | Polymer-4 (100) | PA-3 (5.0) | PAG-7 (17.3) | Q3 (1.6) | PGMEA(2700) |
| | | | | | GBL(300) |
| PR-64 | Polymer-4 (100) | PA-3 (5.0) | PAG-8 (10.5) | Q3 (1.6) | PGMEA(2700) |
| | | | | | GBL(300) |

TABLE 4

| | | Polymer | Photo acid | | |
|---|---|---|---|---|---|
| | Base polymer | additive | generator | Quencher | Solvent |
| | (parts by | (parts by | (parts by | (parts by | (parts by |
| Resist | mass) | mass) | mass) | mass) | mass) |
| PR-65 | Polymer-4 (100) | — | PAG-2 (12.7) | Q3 (1.6) | PGMEA(2700) |
| | | | | | GBL(300) |
| PR-66 | Polymer-4 (100) | PA-47 (5.0) | PAG-2 (12.7) | Q3 (1.6) | PGMEA(2700) |
| | | | | | GBL(300) |
| PR-67 | Polymer-4 (100) | PA-48 (5.0) | PAG-2 (12.7) | Q3 (1.6) | PGMEA(2700) |
| | | | | | GBL(300) |
| PR-68 | Polymer-4 (100) | PA-49 (5.0) | PAG-2 (12.7) | Q3 (1.6) | PGMEA(2700) |
| | | | | | GBL(300) |
| PR-69 | Polymer-4 (100) | PA-50 (5.0) | PAG-2 (12.7) | Q3 (1.6) | PGMEA(2700) |
| | | | | | GBL(300) |
| PR-70 | Polymer-4 (100) | PA-47 (5.0) | PAG-2 (4.5) | Q5 (3.8) | PGMEA(2700) |
| | | | | | GBL(300) |

TABLE 5

| | | | | Quencher or | |
|---|---|---|---|---|---|
| | | Polymer | Photo acid | Closslinking | |
| | Base polymer | additive | generator | agent | Solvent |
| | (parts by | (parts by | (parts by | (parts by | (parts by |
| Resist | mass) | mass) | mass) | mass) | mass) |
| PR-71 | Polymer-16 (100) | PA-1 (5.0) | PAG-1 8.7 | Q3 (1.2) | PGMEA(2100) |
| | | | | Q7 (8.0) | EL(900) |
| PR-72 | Polymer-16 (100) | PA-3 (5.0) | PAG-1 8.7 | Q3 (1.2) | PGMEA(2100) |
| | | | | Q7 (8.0) | EL(900) |
| PR-73 | Polymer-16 (100) | PA-29 (5.0) | PAG-1 8.7 | Q3 (1.2) | PGMEA(2100) |
| | | | | Q7 (8.0) | EL(900) |
| PR-74 | Polymer-13 (100) | PA-3 (5.0) | PAG-1 8.7 | Q3 (1.2) | PGMEA(2100) |
| | | | | Q7 (8.0) | EL(900) |
| PR-75 | Polymer-14 (100) | PA-3 (5.0) | PAG-1 8.7 | Q3 (1.2) | PGMEA(2100) |
| | | | | Q7 (8.0) | EL(900) |
| PR-76 | Polymer-15 (100) | PA-3 (5.0) | PAG-1 8.7 | Q3 (1.2) | PGMEA(2100) |
| | | | | Q7 (8.0) | EL(900) |
| PR-77 | Polymer-17 (100) | PA-3 (5.0) | PAG-1 8.7 | Q3 (1.2) | PGMEA(2100) |
| | | | | Q7 (8.0) | EL(900) |

TABLE 6

| | | | | Quencher or | |
|---|---|---|---|---|---|
| | | Polymer | Photo acid | Closslinking | |
| | Base polymer | additive | generator | agent | Solvent |
| | (parts by | (parts by | (parts by | (parts by | (parts by |
| Resist | mass) | mass) | mass) | mass) | mass) |
| PR-78 | Polymer-16 (100) | PA-47 (5.0) | PAG-1 8.7 | Q3 (1.2) | PGMEA(2100) |
| | | | | Q7 (8.0) | EL(900) |
| PR-79 | Polymer-16 (100) | PA-49 (5.0) | PAG-1 8.7 | Q3 (1.2) | PGMEA(2100) |
| | | | | Q7 (8.0) | EL(900) |
| PR-80 | Polymer-13 (100) | PA-47 (5.0) | PAG-1 8.7 | Q3 (1.2) | PGMEA(2100) |
| | | | | Q7 (8.0) | EL(900) |
| PR-81 | Polymer-14 (100) | PA-47 (5.0) | PAG-1 8.7 | Q3 (1.2) | PGMEA(2100) |
| | | | | Q7 (8.0) | EL(900) |
| PR-82 | Polymer-16 (100) | PA-47 (5.0) | PAG-1 4.4 | Q6 (3.4) | PGMEA(2100) |
| | | | | Q7 (8.0) | EL(900) |

TABLE 7

| | Unit 1 | | Unit 2 | | Unit 3 | | Unit 4 | | Unit 5 | | | |
|---|---|---|---|---|---|---|---|---|---|---|---|---|
| Base | | Composition | | Composition | | Composition | | Composition | | Composition | Molecular | |
| polymer | | ratio | | ratio | | ratio | | ratio | | ratio | weight | dispersity |
| Polymer-1 | ALU-1 | 40 | PU-1 | 15 | LU-4 | 45 | | | | | 6800 | 1.68 |
| Polymer-2 | ALU-3 | 40 | PU-1 | 20 | LU-1 | 40 | | | | | 5900 | 1.70 |
| Polymer-3 | ALU-2 | 45 | LU-2 | 55 | | | | | | | 9900 | 1.80 |
| Polymer-4 | ALU-4 | 50 | LU-1 | 50 | | | | | | | 7400 | 1.79 |
| Polymer-5 | ALU-1 | 20 | ALU-5 | 30 | PU-1 | 10 | LU-1 | 20 | LU-4 | 20 | 8300 | 1.77 |
| Polymer-6 | ALU-5 | 50 | PU-1 | 20 | LU-3 | 30 | | | | | 9100 | 1.93 |
| Polymer-7 | ALU-6 | 55 | LU-1 | 15 | LU-5 | 30 | | | | | 8500 | 1.76 |
| Polymer-8 | ALU-5 | 35 | PU-1 | 15 | LU-4 | 40 | PU-6 | 10 | | | 8400 | 1.75 |
| Polymer-9 | ALU-5 | 35 | PU-1 | 15 | LU-4 | 40 | PU-4 | 10 | | | 8200 | 1.88 |
| Polymer-10 | ALU-7 | 20 | ALU-8 | 30 | PU-1 | 25 | LU-4 | 25 | | | 9000 | 1.84 |
| Polymer-11 | ALU-1 | 10 | ALU-5 | 40 | PU-1 | 25 | LU-6 | 25 | | | 7600 | 1.82 |
| Polymer-12 | ALU-1 | 10 | ALU-5 | 30 | PU-1 | 20 | LU-2 | 30 | LU-7 | 10 | 7700 | 1.81 |
| Polymer-13 | PU-6 | 25 | PU-1 | 75 | | | | | | | 5800 | 1.81 |
| Polymer-14 | PU-5 | 40 | PU-1 | 40 | LU-3 | 20 | | | | | 6300 | 1.79 |
| Polymer-15 | PU-6 | 40 | PU-1 | 40 | PU-7 | 20 | | | | | 7300 | 1.92 |
| Polymer-16 | PU-3 | 40 | PU-1 | 40 | PU-8 | 20 | | | | | 8700 | 1.80 |
| Polymer-17 | PU-3 | 40 | PU-2 | 40 | PU-8 | 20 | | | | | 8900 | 1.78 |

TABLE 8-1
ALU-1

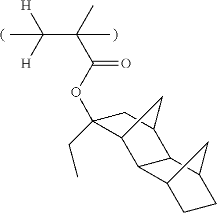

ALU-2

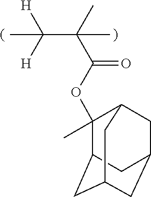

ALU-3

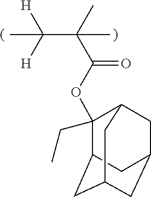

ALU-4

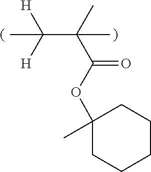

ALU-5

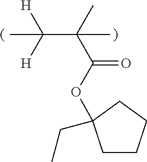

ALU-6

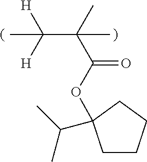

ALU-7

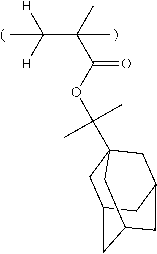

ALU-8

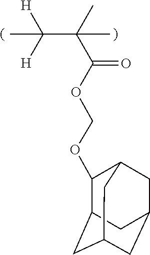

TABLE 8-2
LU-1

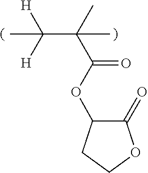

LU-2

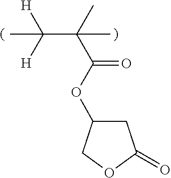

LU-3

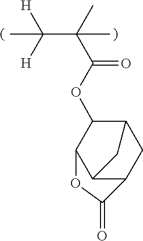

LU-4

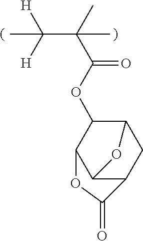

LU-5

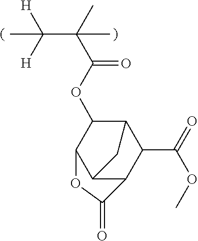

LU-6

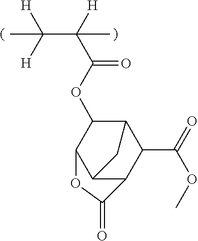

LU-7

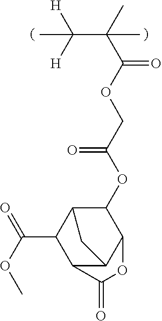

TABLE 8-3
PU-1

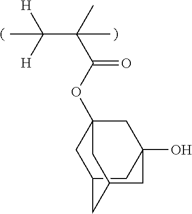

PU-2

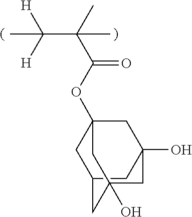

PU-3

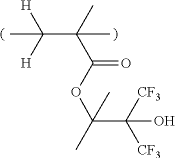

PU-4

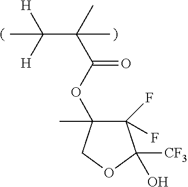

PU-5

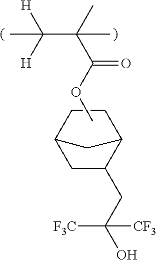

PU-6

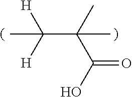

PU-7

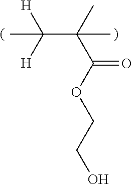

PU-8

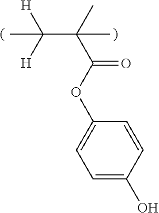

TABLE 9
PAG-1

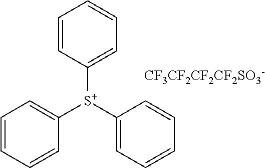

PAG-2

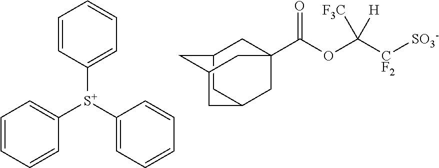

PAG-3

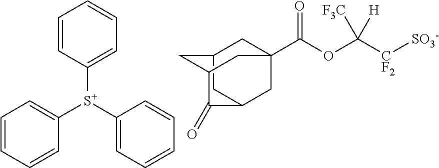

PAG-4

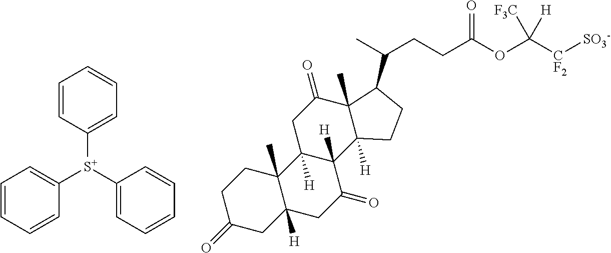

PAG-5

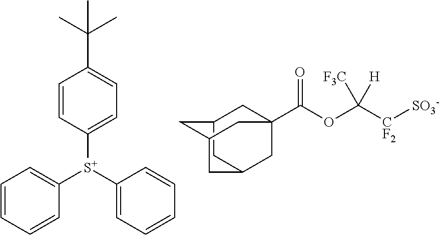

PAG-6

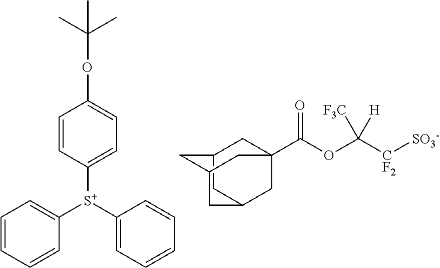

PAG-7

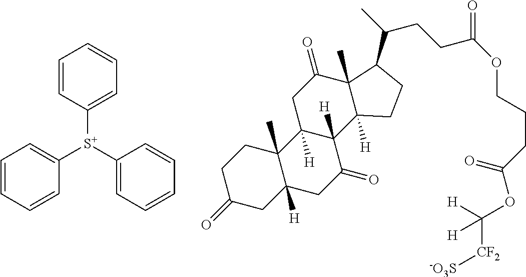

PAG-8

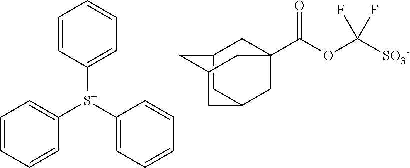

TABLE 10
Q1

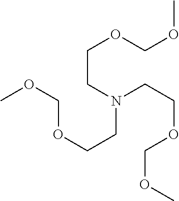

Q2

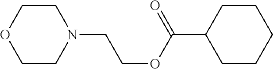

Q3

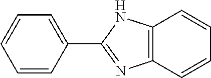

Q4

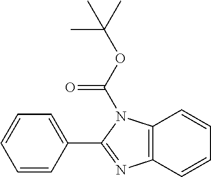

Q5

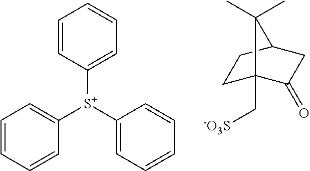

Q6

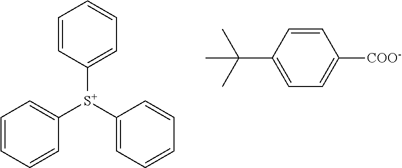

Q7

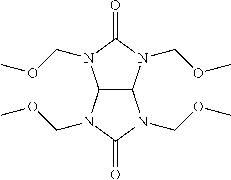

### Preparation of Top Coat Compositions

A base polymer (TC polymer-1, TC polymer-2, and TC polymer-3) and an organic solvent were mixed with a composition shown below, and then the resulting mixture after dissolution was filtered through a filter (pore diameter of 0.2 μm) made of Teflon (registered trade mark) to obtain each of the top coat compositions (TC-1, TC-2, and TC-3).

### TC-1

Mixture Composition: TC polymer-1 (100 parts by mass), organic solvent 1 (2,600 parts by mass), and organic solvent 2 (260 parts by mass)

### TC-2

Mixture Composition: TC polymer-2 (100 parts by mass), organic solvent 1 (2,600 parts by mass), and organic solvent 2 (260 parts by mass)

### TC-3

Mixture Composition: TC polymer-3 (100 parts by mass), organic solvent 1 (2,600 parts by mass), and organic solvent 2 (260 parts by mass)
TC polymer-1, TC polymer-2, and TC polymer-3 (see the Following Structural Formulae)

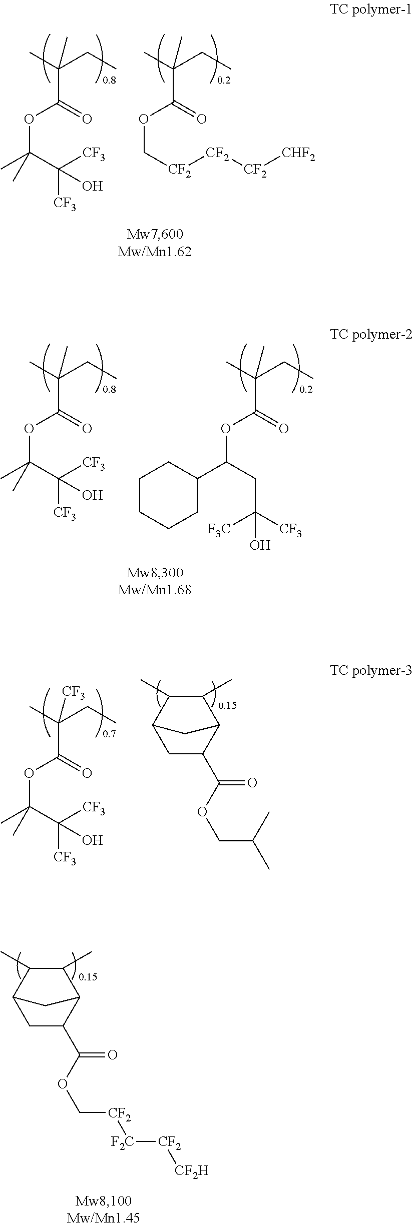

Organic solvent 1: isoamylether
Organic solvent 2: 2-methyl-1-butanol

### Evaluation Example 1

### Evaluation of Lithography Performance of a Positive-Type Resist

A solution of an antireflective film (ARC-29A: manufactured by Nissan Chemical Industries, Ltd.) was applied onto a silicon substrate and baked at 200° C. for 60 seconds to obtain a substrate coated with an antireflective film (film thickness of 100 nm); and then, a resist composition (PR-1 to PR-70) was applied onto this substrate by spin coating and then baked at 100° C. for 60 seconds on a hot plate to obtain a resist film having film thickness of 90 nm. For some resist compositions, the top coat composition (TC-1, TC-2, and TC-3) was applied further onto the resist film and baked at 100° C. for 60 seconds to obtain a top coat having film thickness of 50 nm. This was subjected to an immersion exposure using an ArF excimer laser scanner (NSR-S610C manufactured by Nikon Corporation: NA=1.30, dipole, 6%-attenuated phase shift mask), baked at an arbitrary temperature for 60 seconds (PEB), and then developed by an aqueous solution of 2.38% by mass tetramethyl ammonium hydroxide for 60 seconds.

Evaluation of the resist was made on a 1:1 line and space pattern with a size of 40 nm by observation with an electron microscope; and the exposure dose amount giving 40 nm of the line width was taken as an optimum exposure dose amount (Eop: mJ/cm²). Pattern profiles at the respective optimum exposure dose amounts were compared; and evaluation as to good and not good were judged by the following criteria.

Good: Pattern is of a rectangular shape and the side wall thereof is highly vertical.
Not good: Pattern side wall is of a tapered shape with a steep angle (narrower line size as approaching to surface of the resist film), or a top-rounding shape by a top-loss.

Roughness of the line edge part at the optimum exposure dose amount was quantified by measuring variance of the widths thereof (3σ value was calculated as to 30 measured points), and the values thereby obtained were compared (LWR: nm).

The minimum size to resolve without line fall upon narrowing the line size by increasing the exposure dose amount was taken as fall limit (nm). As the number gets smaller, fall resistance becomes higher and thus more preferable.

### Results of Evaluation Example 1

PEB temperatures and evaluation results of the resist compositions of the present invention shown in the above Table 3-1 to Table 3-3 are shown in the following Table 11-1 to Table 11-4 (Example 1 to Example 71). PEB temperatures and evaluation results of the comparative resist compositions shown in Table 4 are shown in the following Table 12 (Comparative Example 1 to Comparative Example 9).

TABLE 11-1

| | | | | Eop | | | Fall |
|---|---|---|---|---|---|---|---|
| | | Top coat | PEB | (mJ/ | | LWR | limit |
| Example | Resist | composition | (° C.) | cm²) | Profile | (nm) | (nm) |
| Example-1 | PR-1 | not contain | 90 | 29 | Good | 3.0 | 28 |
| Example-2 | PR-2 | not contain | 90 | 30 | Good | 3.3 | 28 |
| Example-3 | PR-3 | not contain | 90 | 31 | Good | 3.0 | 27 |
| Example-4 | PR-4 | not contain | 90 | 30 | Good | 3.0 | 29 |
| Example-5 | PR-5 | not contain | 90 | 30 | Good | 3.3 | 27 |
| Example-6 | PR-6 | not contain | 90 | 28 | Good | 3.1 | 32 |
| Example-7 | PR-7 | not contain | 90 | 29 | Good | 2.9 | 28 |
| Example-8 | PR-8 | not contain | 90 | 31 | Good | 3.0 | 32 |
| Example-9 | PR-9 | not contain | 90 | 32 | Good | 2.9 | 28 |
| Example- | PR-10 | not contain | 90 | 30 | Good | 2.9 | 29 |
| 10 | | | | | | | |
| Example- | PR-11 | not contain | 90 | 31 | Good | 3.3 | 30 |
| 11 | | | | | | | |
| Example- | PR-12 | not contain | 90 | 28 | Good | 2.7 | 29 |
| 12 | | | | | | | |
| Example- | PR-13 | not contain | 90 | 31 | Good | 3.0 | 29 |
| 13 | | | | | | | |
| Example- | PR-14 | not contain | 90 | 30 | Good | 3.0 | 29 |
| 14 | | | | | | | |
| Example- | PR-15 | not contain | 90 | 30 | Good | 2.9 | 31 |
| 15 | | | | | | | |
| Example- | PR-16 | not contain | 90 | 29 | Good | 3.0 | 33 |
| 16 | | | | | | | |
| Example- | PR-17 | not contain | 90 | 33 | Good | 2.9 | 31 |
| 17 | | | | | | | |
| Example- | PR-18 | not contain | 90 | 27 | Good | 3.1 | 32 |
| 18 | | | | | | | |
| Example- | PR-19 | not contain | 90 | 29 | Good | 2.8 | 33 |
| 19 | | | | | | | |
| Example- | PR-20 | not contain | 90 | 29 | Good | 3.1 | 29 |
| 20 | | | | | | | |
| Example- | PR-21 | not contain | 90 | 30 | Good | 2.8 | 29 |
| 21 | | | | | | | |
| Example- | PR-22 | not contain | 90 | 32 | Good | 3.1 | 30 |
| 22 | | | | | | | |
| Example- | PR-23 | not contain | 90 | 33 | Good | 3.0 | 29 |
| 23 | | | | | | | |

TABLE 11-2

| | | | | Eop | | | Fall |
|---|---|---|---|---|---|---|---|
| | | Top coat | PEB | (mJ/ | | LWR | limit |
| Example | Resist | composition | (° C.) | cm²) | Profile | (nm) | (nm) |
| Example- | PR-24 | not contain | 90 | 28 | Good | 2.8 | 30 |
| 24 | | | | | | | |
| Example- | PR-25 | not contain | 90 | 29 | Good | 2.9 | 28 |
| 25 | | | | | | | |
| Example- | PR-26 | not contain | 90 | 30 | Good | 3.2 | 29 |
| 26 | | | | | | | |
| Example- | PR-27 | not contain | 90 | 31 | Good | 3.1 | 32 |
| 27 | | | | | | | |
| Example- | PR-28 | not contain | 90 | 28 | Good | 3.1 | 31 |
| 28 | | | | | | | |
| Example- | PR-29 | not contain | 90 | 28 | Good | 3.1 | 31 |
| 29 | | | | | | | |
| Example- | PR-30 | not contain | 90 | 30 | Good | 2.8 | 31 |
| 30 | | | | | | | |
| Example- | PR-31 | not contain | 90 | 31 | Good | 2.8 | 30 |
| 31 | | | | | | | |
| Example- | PR-32 | not contain | 90 | 30 | Good | 3.0 | 29 |
| 32 | | | | | | | |
| Example- | PR-33 | not contain | 90 | 29 | Good | 2.9 | 32 |
| 33 | | | | | | | |
| Example- | PR-34 | not contain | 90 | 33 | Good | 3.2 | 27 |
| 34 | | | | | | | |
| Example- | PR-35 | not contain | 90 | 27 | Good | 2.7 | 31 |
| 35 | | | | | | | |
| Example- | PR-36 | not contain | 90 | 30 | Good | 2.8 | 30 |
| 36 | | | | | | | |
| Example- | PR-37 | not contain | 90 | 29 | Good | 3.2 | 29 |
| 37 | | | | | | | |
| Example- | PR-38 | not contain | 90 | 30 | Good | 2.8 | 28 |
| 38 | | | | | | | |
| Example- | PR-39 | not contain | 90 | 29 | Good | 3.3 | 32 |
| 39 | | | | | | | |
| Example- | PR-40 | not contain | 90 | 28 | Good | 3.2 | 30 |
| 40 | | | | | | | |
| Example- | PR-41 | not contain | 90 | 29 | Good | 3.0 | 29 |
| 41 | | | | | | | |
| Example- | PR-42 | not contain | 90 | 28 | Good | 3.0 | 30 |
| 42 | | | | | | | |
| Example- | PR-43 | not contain | 90 | 29 | Good | 3.1 | 33 |
| 43 | | | | | | | |
| Example- | PR-44 | not contain | 90 | 32 | Good | 3.0 | 30 |
| 44 | | | | | | | |
| Example- | PR-45 | not contain | 90 | 31 | Good | 2.8 | 30 |
| 45 | | | | | | | |
| Example- | PR-46 | not contain | 90 | 30 | Good | 2.9 | 29 |
| 46 | | | | | | | |

TABLE 11-3

| | | | | Eop | | | Fall |
|---|---|---|---|---|---|---|---|
| | | Top coat | PEB | (mJ/ | | LWR | limit |
| Example | Resist | composition | (° C.) | cm²) | Profile | (nm) | (nm) |
| Example- | PR-47 | not contain | 105 | 25 | Good | 3.4 | 29 |
| 47 | | | | | | | |
| Example- | PR-48 | not contain | 105 | 38 | Good | 3.4 | 32 |
| 48 | | | | | | | |
| Example- | PR-49 | not contain | 110 | 40 | Good | 3.3 | 30 |
| 49 | | | | | | | |
| Example- | PR-50 | not contain | 100 | 35 | Good | 3.1 | 29 |
| 50 | | | | | | | |
| Example- | PR-51 | not contain | 110 | 37 | Good | 3.2 | 30 |
| 51 | | | | | | | |
| Example- | PR-52 | not contain | 90 | 30 | Good | 3.0 | 32 |
| 52 | | | | | | | |
| Example- | PR-53 | not contain | 110 | 34 | Good | 3.3 | 30 |
| 53 | | | | | | | |
| Example- | PR-54 | not contain | 110 | 36 | Good | 3.3 | 29 |
| 54 | | | | | | | |
| Example- | PR-55 | not contain | 110 | 39 | Good | 3.5 | 31 |
| 55 | | | | | | | |
| Example- | PR-56 | not contain | 90 | 38 | Good | 3.4 | 30 |
| 56 | | | | | | | |
| Example- | PR-57 | not contain | 85 | 33 | Good | 3.2 | 29 |
| 57 | | | | | | | |
| Example- | PR-58 | not contain | 90 | 30 | Good | 3.0 | 29 |
| 58 | | | | | | | |
| Example- | PR-59 | not contain | 90 | 32 | Good | 3.0 | 30 |
| 59 | | | | | | | |
| Example- | PR-60 | not contain | 90 | 29 | Good | 2.9 | 33 |
| 60 | | | | | | | |
| Example- | PR-61 | not contain | 90 | 28 | Good | 3.0 | 31 |
| 61 | | | | | | | |
| Example- | PR-62 | not contain | 90 | 29 | Good | 2.8 | 28 |
| 62 | | | | | | | |
| Example- | PR-63 | not contain | 90 | 30 | Good | 2.9 | 32 |
| 63 | | | | | | | |
| Example- | PR-64 | not contain | 90 | 30 | Good | 2.8 | 31 |
| 64 | | | | | | | |

TABLE 11-4

| | | | | Eop | | | Fall |
|---|---|---|---|---|---|---|---|
| | | Top coat | PEB | (mJ/ | | LWR | limit |
| Example | Resist | composition | (° C.) | cm²) | Profile | (nm) | (nm) |
| Example- | PR-3 | TC-1 | 90 | 31 | Good | 3.0 | 27 |
| 65 | | | | | | | |
| Example- | PR-4 | TC-1 | 90 | 30 | Good | 2.9 | 28 |
| 66 | | | | | | | |
| Example- | PR-29 | TC-1 | 90 | 28 | Good | 3.0 | 30 |
| 67 | | | | | | | |
| Example- | PR-41 | TC-1 | 90 | 29 | Good | 3.0 | 29 |
| 68 | | | | | | | |
| Example- | PR-50 | TC-1 | 100 | 35 | Good | 3.2 | 29 |
| 69 | | | | | | | |
| Example- | PR-3 | TC-2 | 90 | 31 | Good | 3.1 | 28 |
| 70 | | | | | | | |
| Example- | PR-3 | TC-3 | 90 | 31 | Good | 3.0 | 28 |
| 71 | | | | | | | |

TABLE 12

| | | Top coat | | Eop | | | Fall |
|---|---|---|---|---|---|---|---|
| Comparative | | compo- | PEB | (mJ/ | | LWR | limit |
| Example | Resist | sition | (° C.) | cm²) | Profile | (nm) | (nm) |
| Comparative | PR-65 | TC-1 | 90 | 29 | Not | 4.1 | 38 |
| Example-1 | | | | | good | | |
| Comparative | PR-66 | not | 90 | 29 | Not | 4.2 | 33 |
| Example-2 | | contain | | | good | | |
| Comparative | PR-67 | not | 90 | 30 | Not | 3.9 | 32 |
| Example-3 | | contain | | | good | | |
| Comparative | PR-68 | not | 90 | 32 | Not | 4.0 | 33 |
| Example 4 | | contain | | | good | | |
| Comparative | PR-69 | TC-1 | 90 | 31 | Good | 4.3 | 40 |
| Example-5 | | | | | | | |
| Comparative | PR-70 | not | 90 | 22 | Not | 3.2 | 33 |
| Example-6 | | contain | | | good | | |
| Comparative | PR-66 | TC-1 | 90 | 28 | Not | 4.4 | 38 |
| Example-7 | | | | | good | | |
| Comparative | PR-66 | TC-2 | 90 | 29 | Not | 4.6 | 39 |
| Example-8 | | | | | good | | |
| Comparative | PR-66 | TC-3 | 90 | 28 | Not | 4.5 | 39 |
| Example-9 | | | | | good | | |

By comparison between the above Table 11-1 to Table 11-4 and Table 12, it is clear that the resist compositions of the present invention are excellent in all of LWR, rectangularity, and fall resistance simultaneously. It can also be seen that the performance is secured even when various kinds of the top coat are applied.

### Evaluation Example 2

### Evaluation of Lithography Performance of a Negative-Type Resist

A solution of an antireflective film (ARC-29A: manufactured by Nissan Chemical Industries, Ltd.) was applied onto a silicon substrate and baked at 200° C. for 60 seconds to obtain a substrate coated with an antireflective film (film thickness of 100 nm); and then, a resist composition (PR-71 to PR-82) was applied onto this substrate by spin coating and then baked at 100° C. for 60 seconds on a hot plate to obtain a resist film having film thickness of 90 nm. This was subjected to an immersion exposure using an ArF excimer laser scanner (NSR-S610C manufactured by Nikon Corporation: NA=1.30, dipole, 6%-attenuated phase shift mask), baked at an arbitrary temperature for 60 seconds (PEB), and then developed by an aqueous solution of 2.38% by mass tetramethyl ammonium hydroxide for 60 seconds.

Evaluation of the resist was made on a 1:1 line and space pattern with a size of 45 nm by observation with an electron microscope; and the exposure dose amount giving 45 nm of the pattern width was taken as an optimum exposure dose amount (Eop: mJ/cm²). Pattern shapes at the respective optimum exposure dose amounts were compared; and evaluation as to good and not good were judged by the following criteria.

Good: Pattern is of a rectangular shape and the side wall thereof is highly vertical.
Not good: Pattern side wall is of a negative profile with a steep angle (wider line size as approaching to surface of the resist film), or a T-top shape by difficult dissolution of the resist film surface.

Roughness of the line edge part at the optimum exposure dose amount was quantified by measuring variance of the widths thereof (3σ value was calculated as to 30 measured points), and the values thereby obtained were compared (LWR: nm).

### Results of Evaluation Example 2

PEB temperatures and evaluation results of the resist compositions of the present invention shown in the above Table 5 are shown in the following Table 13 (Example 72 to Example 78). PEB temperatures and evaluation results of the comparative resist compositions shown in Table 6 are shown in the following Table 14 (Comparative Example 10 to Comparative Example 14).

TABLE 13

| | | PEB | Eop | | LWR |
|---|---|---|---|---|---|
| Example | Resist | (° C.) | (mJ/cm²) | Profile | (nm) |
| Example-72 | PR-71 | 110 | 27 | Good | 3.6 |
| Example-73 | PR-72 | 110 | 27 | Good | 3.6 |
| Example-74 | PR-73 | 110 | 26 | Good | 3.5 |
| Example-75 | PR-74 | 110 | 25 | Good | 3.3 |
| Example-76 | PR-75 | 110 | 27 | Good | 3.4 |
| Example-77 | PR-76 | 110 | 29 | Good | 3.2 |
| Example-78 | PR-77 | 110 | 31 | Good | 3.4 |

TABLE 14

| Comparative | | PEB | Eop | | LWR |
|---|---|---|---|---|---|
| Example | Resist | (° C.) | (mJ/cm²) | Profile | (nm) |
| Comparative | PR-78 | 110 | 29 | Not good | 4.6 |
| Example-10 | | | | | |
| Comparative | PR-79 | 110 | 28 | Not good | 4.9 |
| Example-11 | | | | | |
| Comparative | PR-80 | 110 | 30 | Not good | 5.1 |
| Example-12 | | | | | |
| Comparative | PR-81 | 110 | 29 | Not good | 4.7 |
| Example-13 | | | | | |
| Comparative | PR-82 | 110 | 23 | Not good | 3.8 |
| Example-14 | | | | | |

By comparison between the above Table 13 and Table 14, it is clear that the resist compositions of the present invention are excellent in LWR and rectangularity.

### Evaluation Example 3

### Measurement of Contact Angle and Defect Check

After a resist film was formed on a silicon substrate by the method similar to that of the afore-mentioned Evaluation Example 1, the receding contact angle with regard to 50 μL of a water droplet dispensed on the photoresist film after development was measured with a tilting method (measurement method of a dynamic contact angle wherein the contact angle for a water droplet to start sliding down when a wafer is gradually tilted at a constant rate is measured) by using a contact angle measurement instrument prop Master 500 (manufactured by Kyowa Interface Science Co., Ltd.).

A sample, which was obtained by the following method, was arranged; namely, a top coat (TC-1) was formed on the resist film by a method similar to that of the Evaluation Example 1, and then it was developed by an aqueous solution of 2.38% by mass tetramethyl ammonium hydroxide for 60 seconds. In addition, arranged was a sample similarly developed after formation of the resist film without applying the top coat. Post-development contact angles of these developed samples were measured as to 5 μL of a dispensed water droplet by using a contact angle measurement instrument prop Master 500 (manufactured by Kyowa Interface Science Co., Ltd.) with a static method (method to measure a static contact angle wherein the contact angle is measured with a wafer being kept horizontally).

A resist composition was filtered by microfiltration by using a filter made of high density polyethylene with a size of 0.02 micron, applied onto a silicon substrate formed thereon with an antireflective film having film thickness of 90 nm (the film was formed by applying an antireflective film solution ARC-29A: manufactured by Nissan Chemical Industries, Ltd.), and then baked at 100° C. for 60 seconds to obtain a resist film having film thickness of 90 nm. Thereafter, a top coat composition TC-1 was applied onto it and then baked at 100° C. for 60 seconds. Checkered flag exposure (exposure is made to form alternately an exposed area and an unexposed area of an open frame with an area of 20 mm square on an entire wafer surface) was made by using an ArF excimer laser scanner (NSR—S307E manufactured by Nikon Corporation: NA=0.85, a 0.93, Cr mask), baked at an arbitrary temperature for 60 seconds (PEB), and then developed by a 2.38% by mass TMAH developer for 30 seconds. Then, defect numbers in the unexposed areas of the checkered flag were measured with a pixel size of 0.125 micron by using a defect-checking instrument WinWin-50-1200 (manufactured by Tokyo Seimitsu Co., Ltd.). Further, without applying the top coat, the defect check was done in a manner similar to the above-described method after the resist film is formed. However, the receding contact angle of less than 65 degrees was judged inexposable, because there was a risk of damaging the exposing instrument due to leakage of a large quantity of immersed water from the wafer surface.

### Results of Evaluation Example 3

PES temperature, receding contact angle, and post-development receding contact angle and defect numbers with and without applying the top coat by the foregoing evaluation methods, of PR-3, 4, 29, 41, and 50, among the resist compositions of the present invention shown in Table 3-1 to Table 3-3, are shown in the following Table 15 (Example 79 to Example 83). Among the resist compositions for comparison shown in Table 4, the evaluation results of PR-65, 66, and 69 obtained by the similar methods are shown in Table 16 (Comparative Example 15 to Example 17).

TABLE 15

| | | | | | Post- | | |
|---|---|---|---|---|---|---|---|
| | | | | Post- | development | | |
| | | | | development | receding | | |
| | | | | receding | contact | | |
| | | | Receding | contact | angle | Defect | Defect |
| | | | contact | angle with | without top | number | number |
| | | PEB | angle | top coat | coat | with top | without |
| Example | Resist | (° C.) | (degree) | (degree) | (degree) | coat | top coat |
| Example- | PR-3 | 90 | 70 | 58 | 58 | 24 | 27 |
| 79 | | | | | | | |
| Example- | PR-4 | 90 | 71 | 55 | 56 | 28 | 25 |
| 80 | | | | | | | |
| Example- | PR-29 | 90 | 74 | 57 | 56 | 19 | 20 |
| 81 | | | | | | | |
| Example- | PR-41 | 90 | 77 | 57 | 57 | 32 | 38 |
| 82 | | | | | | | |
| Example- | PR-50 | 100 | 71 | 59 | 58 | 30 | 28 |
| 83 | | | | | | | |

TABLE 16

| | | | | | Post- | | |
|---|---|---|---|---|---|---|---|
| | | | | Post- | development | | |
| | | | | development | contact | | |
| | | | Receding | contact | angle | Defect | Defect |
| | | | contact | angle with | without | number | number |
| Comparative | | PEB | angle | top coat | top coat | with top | without |
| Example | Resist | (° C.) | (degree) | (degree) | (degree) | coat | top coat |
| Comparative | PR-65 | 90 | 59 | 67 | 59 | 1052 | — |
| Example-15 | | | | | | | |
| Comparative | PR-66 | 90 | 70 | 71 | 70 | 1930 | 1783 |
| Example-16 | | | | | | | |
| Comparative | PR-69 | 90 | 60 | 56 | 58 | 32 | — |
| Example-17 | | | | | | | |

From the comparison between Table 15 and Table 16, it is clear that the resist composition of the present invention has a high receding contact angle enabling an immersion exposure even without a top coat, and at the same time, increase of a post-development contact angle can be prevented in any of steps with and without a top coat thereby effectively suppressing a defect appearing in an unexposed area (namely blob defect).

The present invention is not limited to the above-described embodiments. The above-described embodiments are mere examples, and those having the substantially same structure as that described in the appended claims and providing the similar action and effects are included in the scope of the present invention.

For example, though the above has mainly mentioned the cases of using the resist composition of the present invention in immersion lithography, it goes without saying that the composition of the present invention can be used in usual lithography.

What is claimed is:

1. A resist composition, wherein the composition is used in a lithography and comprises at least:
a polymer (A) that becomes a base resin whose alkaline-solubility changes by an acid,
a photo acid generator (B) generating a sulfonic acid represented by the following general formula (1) by responding to a high energy beam, and
a polymer additive (C) represented by the following general formula (2); 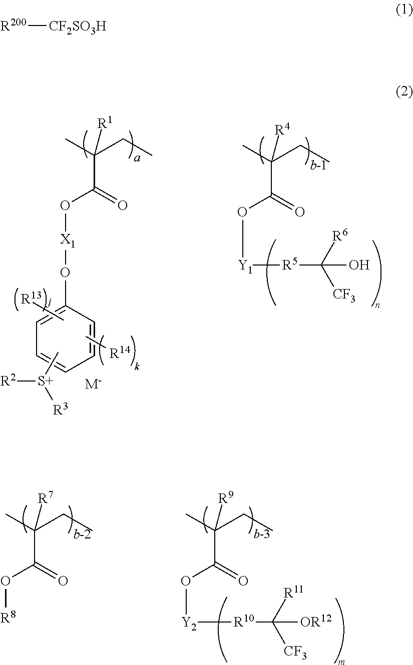
wherein R²⁰⁰ represents a halogen atom; or a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group;
wherein, each of R¹, R⁴, R⁷, and R⁹ independently represents a hydrogen atom or a methyl group. X₁ represents a linear or a branched alkylene group having 1 to 10 carbon atoms. Each of R² and R³ independently represents any of linear, branched, and cyclic substituted or unsubstituted alkyl, alkenyl, and oxoalkyl groups having 1 to 10 carbon atoms and optionally containing a heteroatom; or any of substituted or unsubstituted aryl, aralkyl, and aryl oxoalkyl groups having 6 to 20 carbon atoms; or R² and R³ may be bonded to form a ring together with a sulfur atom in the formula. R⁵ and R¹⁰ represent a linear, a branched, or a cyclic alkylene group having 1 to 20 carbon atoms, wherein one or plurality of the hydrogen atoms in these groups may be substituted with a fluorine atom. R⁶ represents any of a hydrogen atom, a fluorine atom, a methyl group, a trifluoromethyl group, and a difluoromethyl group; or R⁵ and R⁶ may form an aliphatic ring having 5 to 12 carbon atoms together with the carbon atom to which these groups are bonded, wherein these rings may contain an ether bond, a fluorine-substituted alkylene group, or a trifluoromethyl group. Similarly, R¹¹ represents any of a hydrogen atom, a fluorine atom, a methyl group, a trifluoromethyl group, and a difluoromethyl group; or R¹⁰ and R¹¹ may form an aliphatic ring having 5 to 12 carbon atoms together with the carbon atom to which these groups are bonded, wherein these rings may contain an ether bond, a fluorine-substituted alkylene group, or a trifluoromethyl group. Each of n and m independently represents 1 or 2. In the case of n=1 and m=1, each of Y₁ and Y₂ independently represents a single bond, or a linear, a branched, or a cyclic alkylene group having 1 to 10 carbon atoms and optionally containing a carbonyl group, an ether bond, and an ester bond; and in the case of n=2 and m=2, Y₁ and Y₂ represent a trivalent connecting group having a form that one hydrogen atom is removed from the alkylene group shown by Y₁ and Y₂ of the case of n=1 and m=1 mentioned above. R⁸ represents a linear, a branched, or a cyclic alkyl group, having 1 to 20 carbon atoms, substituted by at least one fluorine atom, and optionally containing an ether bond, an ester bond, or a sulfonamide group. R¹² represents an acid-labile group. Each of R¹³ and R¹⁴ independently represents a linear or a branched alkyl group having 1 to 5 carbon atoms and optionally containing a heteroatom. Each of j and k independently represents 0 or 1. M⁻ represents any of an alkane sulfonate ion represented by the following general formula (3), an arene sulfonate ion represented by the following general formula (4), and a carboxylate ion represented by the following general formula (5). Numbers “a”, (b-1), (b-2), and (b-3) satisfy 0<a<1.0, 0≦(b-1)<1.0, 0≦(b-2)<1.0, 0≦(b-3)<1.0, 0<(b-1)+(b-2)+(b-3)<1.0, and 0.5≦a+(b-1)+(b-2)+(b-3)≦1.0; 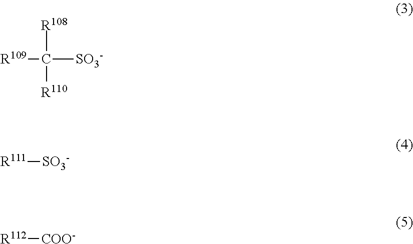
wherein, each of R¹⁰⁸, R¹⁰⁹, and R¹¹⁰ independently represents a hydrogen atom or a halogen atom excluding a fluorine atom; or any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group. Further, two or more of R¹⁰⁸, R¹⁰⁹, and R¹¹⁰ may be bonded with each other to form a ring;
wherein, R¹¹¹ represents an aryl group having 1 to 20 carbon atoms. One or plurality of the hydrogen atoms of the aryl group may be substituted with a halogen atom, a hydroxyl group, a carboxyl group, an amino group, or a cyano group, and further with a linear, a branched, or a cyclic alkyl group having 1 to 20 carbon atoms; and
wherein, R¹¹² represents any of linear, branched, and cyclic alkyl, alkenyl, and aralkyl groups having 1 to 20 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group.

2. The resist composition according to claim 1, wherein the photo acid generator (B) generates a sulfonic acid represented by the following general formula (6);
R²⁰¹—CF₂SO₃H (6)
wherein R²⁰¹ represents a linear, a branched, or a cyclic alkyl or aralkyl group having 1 to 23 carbon atoms and optionally containing a carbonyl group, an ether bond, and an ester bond, or an aryl group, wherein one or plurality of the hydrogen atoms of these groups may be substituted with a halogen atom, a hydroxyl group, a carboxyl group, an amino group, or a cyano group, excluding a perfluoroalkyl group.

3. The resist composition according to claim 1, wherein the photo acid generator (B) generates a sulfonic acid represented by the following general formula (7);
Rf—CH(OCOR²⁰²)—CF₂SO₃H (7)
wherein Rf represents a hydrogen atom or a CF₃ group. R²⁰² represents a linear, a branched, or a cyclic substituted or unsubstituted alkyl group having 1 to 20 carbon atoms, or a substituted or an unsubstituted aryl group having 6 to 14 carbon atoms.

4. The resist composition according to claim 1, wherein the photo acid generator (B) generates a sulfonic acid represented by the following general formula (8);
R²⁰³—OOC—CF₂SO₃H (8)
wherein R²⁰³ represents a linear, a branched, or a cyclic substituted or unsubstituted alkyl group having 1 to 20 carbon atoms, or a substituted or an unsubstituted aryl group having 6 to 14 carbon atoms.

5. The resist composition according to claim 1, wherein the polymer (A) as the base resin has a repeating unit having a structure containing an acid-labile group, and the composition is a positive-type resist composition.

6. The resist composition according to claim 2, wherein the polymer (A) as the base resin has a repeating unit having a structure containing an acid-labile group, and the composition is a positive-type resist composition.

7. The resist composition according to claim 3, wherein the polymer (A) as the base resin has a repeating unit having a structure containing an acid-labile group, and the composition is a positive-type resist composition.

8. The resist composition according to claim 4, wherein the polymer (A) as the base resin has a repeating unit having a structure containing an acid-labile group, and the composition is a positive-type resist composition.

9. The resist composition according to claim 5, wherein the polymer (A) as the base polymer has further a repeating unit having a structure containing a lactone ring, in addition to the repeating unit having a structure containing an acid-labile group.

10. The resist composition according to claim 6, wherein the polymer (A) as the base polymer has further a repeating unit having a structure containing a lactone ring, in addition to the repeating unit having a structure containing an acid-labile group.

11. The resist composition according to claim 7, wherein the polymer (A) as the base polymer has further a repeating unit having a structure containing a lactone ring, in addition to the repeating unit having a structure containing an acid-labile group.

12. The resist composition according to claim 8, wherein the polymer (A) as the base polymer has further a repeating unit having a structure containing a lactone ring, in addition to the repeating unit having a structure containing an acid-labile group.

13. The resist composition according to claim 1, wherein the composition is a negative-type resist composition.

14. The resist composition according to claim 2, wherein the composition is a negative-type resist composition.

15. The resist composition according to claim 3, wherein the composition is a negative-type resist composition.

16. The resist composition according to claim 4, wherein the composition is a negative-type resist composition.

17. The resist composition according to claim 1, wherein the composition further contains any one or more of an organic solvent, a basic compound, a crosslinking agent, and a surfactant.

18. The resist composition according to claim 2, wherein the composition further contains any one or more of an organic solvent, a basic compound, a crosslinking agent, and a surfactant.

19. The resist composition according to claim 3, wherein the composition further contains any one or more of an organic solvent, a basic compound, a crosslinking agent, and a surfactant.

20. The resist composition according to claim 4, wherein the composition further contains any one or more of an organic solvent, a basic compound, a crosslinking agent, and a surfactant.

21. A patterning process, wherein the process is to form a pattern onto a substrate and includes at least a step of forming a resist film by applying the resist composition according to claim 1 onto the substrate, a step of exposing to a high energy beam after heat treatment, and a step of developing by using a developer.

22. The patterning process according to claim 21, wherein wavelength of the high energy beam is made in the range between 180 and 250 nm.

23. The patterning process according to claim 21, wherein a liquid is inserted between a projection lens and the substrate formed with the resist film, and the step of exposing to the high energy beam is carried out by an immersion exposure intervened with the liquid.

24. The patterning process according to claim 22, wherein a liquid is inserted between a projection lens and the substrate formed with the resist film, and the step of exposing to the high energy beam is carried out by an immersion exposure intervened with the liquid.

25. The patterning process according to claim 23, wherein, in the immersion exposure, a top coat is arranged on the resist film.

26. The patterning process according to claim 24, wherein, in the immersion exposure, a top coat is arranged on the resist film.

27. The patterning process according to claim 23, wherein water is used as the liquid.

28. The patterning process according to claim 26, wherein water is used as the liquid.
